(19) United States
(12) Patent Application Publication
(10) Pub. No.: US 2026/0206468 A1
(43) Pub. Date: Jul. 16, 2026

(54) DISPLAY DEVICE AND ELECTRONIC APPARATUS

(71) Applicant: SONY SEMICONDUCTOR SOLUTIONS CORPORATION, KANAGAWA (JP)

(72) Inventors: MASASHI UCHIDA, KANAGAWA (JP); TOMOAKI SUZUKI, KANAGAWA (JP)

(21) Appl. No.: 19/132,699

(22) PCT Filed: Nov. 30, 2023
(86) PCT No.: PCT/JP2023/042870

§ 371 Date: May 23, 2025

(30) Foreign Application Priority Data
Nov. 30, 2022 (JP) 2022-192375

(51) Int. Cl. H10K 59/80; H10K 59/12; H10K 59/35

(52) U.S. Cl. CPC H10K 59/879; H10K 59/1201; H10K 59/351; H10K 59/353

(57) ABSTRACT

Provided is a display device that can improve luminous efficiency. The display device includes a plurality of light-emitting elements and a multilayer body covering the plurality of light-emitting elements. The multilayer body sequentially includes a first layer having a first refractive index n₁, a second layer having a second refractive index n₂ different from the first refractive index n₁, and a third layer having a third refractive index n₃ different from the second refractive index n₂. The second layer includes a plurality of first lens portions and a plurality of second lens portions. The plurality of first lens portions and the plurality of second lens portions are provided on different surfaces of the second layer. The first lens portions are provided in one of the central portion and the peripheral portion of pixels, and the second lens portions are provided in the other of the central portion and the peripheral portion of the pixels.

### TECHNICAL FIELD

The present disclosure relates to a display device and an electronic apparatus including the display device.

### BACKGROUND ART

In a display device, light emitted from a light-emitting element at a wide angle is not extracted from the front, which may cause a decrease in luminous efficiency. Thus, in recent years, a technique for condensing light on an own pixel to improve luminous efficiency has been studied.

For example, in Patent Document 1, a technique of improving a light-emitting component taken out to the front by a structure in which an uneven structure and a hemispherical lens structure are combined is studied.

### CITATION LIST

### Patent Document

Patent Document 1: Japanese Patent Application Laid-Open No. 2012-109230

### SUMMARY OF THE INVENTION

### Problems to Be Solved by the Invention

However, in the technique described in Patent Document 1, since the uneven structure is formed at a central portion of a lens bottom surface, light incident on the central portion of the lens bottom surface may be lost, and the luminance may be reduced.

It is an object of the present disclosure to provide a display device capable of improving luminous efficiency and an electronic apparatus including the display device.

### Solutions to Problems

In order to solve the above problem, a first display device according to the present disclosure includes:
a plurality of light-emitting elements; and
a multilayer body covering the plurality of light-emitting elements, in which
the multilayer body includes, in order, a first layer having a first refractive index n₁, a second layer having a second refractive index n₂ different from the first refractive index n₁, and a third layer having a third refractive index n₃ different from the second refractive index n₂,
the second layer includes a plurality of first lens portions and a plurality of second lens portions,
the plurality of first lens portions and the plurality of second lens portions are provided on different surfaces of the second layer,
the first lens portions are provided in one of a central portion and a peripheral portion of pixels, and the second lens portions are provided in another of the central portion and the peripheral portion of the pixels.

A second display device according to the present disclosure includes:
a plurality of light-emitting elements; and
a multilayer body covering the plurality of light-emitting elements, in which
the multilayer body includes, in order, a first layer having a first refractive index n₁ and a second layer having a second refractive index n₂ different from the first refractive index n₁,
the second layer includes a plurality of first lens portions,
the plurality of first lens portions is provided on a first surface on a side of the first layer, and the first lens portions are located in one of a central portion and a peripheral portion of pixels.

A third display device according to the present disclosure includes:
a plurality of light-emitting elements; and
a multilayer body covering the plurality of light-emitting elements, in which
the multilayer body includes, in order, a second layer having a second refractive index n₂ and a third layer having a third refractive index n₃ different from the second refractive index n₂,
the second layer includes a plurality of second lens portions,
the plurality of second lens portions is provided on a second surface on a side of the third layer, and the second lens portions are located in one of a central portion and a peripheral portion of pixels.

An electronic apparatus according to the present disclosure includes at least one of the first display device, the second display device, or the third display device.

### BRIEF DESCRIPTION OF DRAWINGS

FIG. 1 is a plan view of a display device according to a first embodiment.

FIG. 2 is an enlarged plan view illustrating a part of an effective pixel region.

FIG. 3 is a cross-sectional view taken along line III-III in FIG. 2.

FIG. 4 is an enlarged cross-sectional view illustrating a region RE of FIG. 3.

FIG. 5 is a plan view of a first lens portion and a second lens portion.

FIG. 6 is a manufacturing process diagram of the display device according to the first embodiment.

FIG. 7 is a manufacturing process diagram of the display device according to the first embodiment.

FIG. 8 is a manufacturing process diagram of the display device according to the first embodiment.

FIG. 9 is a manufacturing process diagram of the display device according to the first embodiment.

FIG. 10 is a manufacturing process diagram of the display device according to the first embodiment.

FIGS. 11A and 11B are enlarged cross-sectional views illustrating a part of a display device according to a modification.

FIG. 12 is an enlarged cross-sectional view illustrating a part of a display device according to a modification.

FIG. 13 is a cross-sectional view of a display device according to a modification.

FIG. 14 is a cross-sectional view of a display device according to a modification.

FIG. 15 is a cross-sectional view of a display device according to a modification.

FIG. 16 is a cross-sectional view of a display device according to a modification.

FIG. 17 is a cross-sectional view of a display device according to a modification.

FIG. 18 is a cross-sectional view of a display device according to a modification.

FIG. 19 is a cross-sectional view of a display device according to a modification.

FIG. 20 is a cross-sectional view of a display device according to a modification.

FIG. 21 is a cross-sectional view of a display device according to a modification.

FIG. 22 is a cross-sectional view of a display device according to a modification.

FIG. 23 is a cross-sectional view of a display device according to a modification.

FIG. 24 is a cross-sectional view of a display device according to a modification.

FIG. 25 is a cross-sectional view of a display device according to a modification.

FIG. 26 is a cross-sectional view of a display device according to a modification.

FIG. 27 is a cross-sectional view of a display device according to a modification.

FIG. 28 is a cross-sectional view of a display device according to a modification.

FIG. 29 is a cross-sectional view of a display device according to a modification.

FIG. 30 is a plan view of a first lens portion and a second lens portion.

FIG. 31 is an enlarged plan view illustrating a part of an effective pixel region.

FIG. 32 is an enlarged plan view illustrating a part of an effective pixel region.

FIG. 33 is a plan view of a first lens portion and a second lens portion.

FIG. 34 is a plan view of a first lens portion and a second lens portion.

FIG. 35 is an enlarged plan view illustrating a part of an effective pixel region.

FIG. 36 is an enlarged plan view illustrating a part of an effective pixel region.

FIG. 37 is a plan view of a first lens portion and a second lens portion.

FIG. 38 is a plan view of a first lens portion and a second lens portion.

FIG. 39 is an enlarged plan view illustrating a part of an effective pixel region.

FIG. 40 is an enlarged plan view illustrating a part of an effective pixel region.

FIG. 41 is a plan view of a first lens portion and a second lens portion.

FIG. 42 is an enlarged plan view illustrating a part of an effective pixel region.

FIG. 43 is an enlarged cross-sectional view illustrating a part of a display device.

FIG. 44 is an enlarged cross-sectional view illustrating a part of a display device.

FIGS. 45A, 45B, and 45C are conceptual diagrams illustrating a relationship among a normal line LN passing through a center of a light-emitting unit, a normal line LN′ passing through a center of a lens member, and a normal line LN″ passing through a center of a wavelength selection unit.

FIG. 46 is a conceptual diagram illustrating a relationship among the normal line LN passing through the center of the light-emitting unit, the normal line LN′ passing through the center of the lens member, and the normal line LN″ passing through the center of the wavelength selection unit.

FIGS. 47A and 47B are conceptual diagrams illustrating a relationship among the normal line LN passing through the center of the light-emitting unit, the normal line LN′ passing through the center of the lens member, and the normal line LN″ passing through the center of the wavelength selection unit.

FIG. 48 is a conceptual diagram illustrating a relationship among the normal line LN passing through the center of the light-emitting unit, the normal line LN′ passing through the center of the lens member, and the normal line LN″ passing through the center of the wavelength selection unit.

FIG. 49A is a schematic cross-sectional view for describing a first example of a resonator structure. FIG. 49B is a schematic cross-sectional view for describing a second example of the resonator structure.

FIG. 50A is a schematic cross-sectional view for describing a third example of the resonator structure. FIG. 50B is a schematic cross-sectional view for describing a fourth example of the resonator structure.

FIG. 51A is a schematic cross-sectional view for describing a fifth example of the resonator structure. FIG. 51B is a schematic cross-sectional view for describing a sixth example of the resonator structure.

FIG. 52 is a schematic cross-sectional view for describing a seventh example of the resonator structure.

FIG. 53A is a front view of a digital still camera. FIG. 53B is a rear view of the digital still camera.

FIG. 54 is a perspective view of a head-mounted display.

FIG. 55 is a perspective view of a television apparatus.

FIG. 56 is a perspective view of a see-through head-mounted display.

FIG. 57 is a perspective view of a smartphone.

FIG. 58A is a diagram illustrating an internal state of a vehicle as viewed from a rear side to a front side of the vehicle. FIG. 58B is a diagram illustrating an internal state of the vehicle as viewed from an oblique rear side to an oblique front side of the vehicle.

FIG. 59 is a schematic diagram of an optical system including the display device according to the first embodiment.

FIG. 60 is a schematic diagram of an optical system including a display device according to a second embodiment.

FIG. 61 is an enlarged plan view illustrating a part of an effective pixel region of a display device according to the second embodiment.

FIG. 62 is a cross-sectional view taken along line LXII-LXII in FIG. 61.

FIG. 63 is an enlarged plan view illustrating a part of an effective pixel region of a display device according to a third embodiment.

FIG. 64 is a cross-sectional view taken along line LXIV-LXIV in FIG. 63.

FIG. 65 is an enlarged plan view illustrating a part of an effective pixel region of a display device according to a fourth embodiment.

FIG. 66 is a cross-sectional view taken along line LXVI-LXVI in FIG. 65.

FIG. 67 is an enlarged plan view illustrating a part of an effective pixel region of a display device according to a fifth embodiment.

FIG. 68 is a cross-sectional view taken along line LXVIII-LXVIII in FIG. 67.

FIG. 69 is a schematic view of an optical system including a display device according to a modification.

FIG. 70 is an enlarged plan view illustrating a part of an effective pixel region of a display device according to a modification.

FIG. 71 is an enlarged plan view illustrating a part of an effective pixel region of a display device according to a modification.

FIG. 72 is an enlarged plan view illustrating a part of an effective pixel region of a display device according to a modification.

FIG. 73 is an enlarged plan view illustrating a part of an effective pixel region of a display device according to a modification.

FIG. 74A is a cross-sectional view of an OLED layer having a single-layer light-emitting unit. FIG. 74B is a cross-sectional view of an OLED layer having two light-emitting units.

FIG. 75 is a cross-sectional view of a first example of a leak suppression structure.

FIG. 76 is a cross-sectional view of a second example of the leak suppression structure.

FIG. 77 is a cross-sectional view of a third example of the leak suppression structure.

FIG. 78 is a cross-sectional view of a fourth example of the leak suppression structure.

FIG. 79 is a cross-sectional view of a fifth example of the leak suppression structure.

FIG. 80 is a cross-sectional view of a sixth example of the leak suppression structure.

FIG. 81 is a cross-sectional view of a seventh example of the leak suppression structure.

FIG. 82 is a cross-sectional view of a groove illustrated in FIG. 81.

FIG. 83 is a cross-sectional view of an eighth example of the leak suppression structure.

FIG. 84 is a cross-sectional view of a ninth example of the leak suppression structure.

FIG. 85 is a plan view for describing arrangement of a first electrode and a third electrode.

### MODE FOR CARRYING OUT THE INVENTION

Embodiments of the present disclosure will be described in the following order, with reference to the drawings. Note that the same or corresponding portions will be denoted by the same reference signs in all the drawings of the following embodiments.
1. Description of overall display device according to present disclosure
2. First embodiment (Example of display device)
3. Second embodiment (Example of display device)
4. Third embodiment (Example of display device)
5. Fourth embodiment (Example of display device)
6. Fifth embodiment (Example of display device)
7. Modifications
8. Relationship among normal lines passing through centers of light-emitting unit, lens member, and wavelength selection unit
9. Example of resonator structure
10. Example of leak suppression structure
11. Application examples (examples of electronic apparatus)

### 1. Description of Overall Display Device According to Present Disclosure

In the present disclosure, a second layer included in a multilayer body may include a plurality of first lens portions and a plurality of second lens portions, and the plurality of first lens portions and the plurality of second lens portions may be provided on different surfaces of the second layer. For example, the plurality of first lens portions may be provided on a first surface, and the plurality of second lens portions may be provided on a second surface.

The first lens portion may be provided in one of a central portion and a peripheral portion of a pixel, and the second lens portion may be provided in the other of the central portion and the peripheral portion of the pixel. For example, the first lens portion may be provided in the central portion of the pixel, and the second lens portion may be provided in the peripheral portion of the pixel, or the first lens portion may be provided in the peripheral portion of the pixel, and the second lens portion may be provided in the central portion of the pixel.

In the present disclosure, the “peripheral portion of the pixel” represents a portion having a predetermined width from a peripheral edge toward an inside of the pixel. Furthermore, the “central portion of the pixel” represents an inner portion of the peripheral portion of the pixel. The peripheral portion of the pixel may be, for example, in a range equal to or more than 1 μm in an in-plane direction from a geometric center of the pixel. The central portion of the pixel may be, for example, in a range less than 1 μm in the in-plane direction from a geometric center of the pixel.

The first lens portion may include at least one annular first protrusion, and preferably includes a plurality of annular first protrusions from the viewpoint of improving luminous efficiency. The plurality of annular first protrusions may be concentric prism lens arrays or Fresnel lens arrays. The second lens portion may include at least one annular second protrusion, and preferably includes a plurality of annular second protrusions from the viewpoint of improving luminous efficiency. The plurality of annular second protrusions may be concentric prism lens arrays or Fresnel lens arrays.

A cross-sectional shape of a unit lens constituting a concentric prism lens array may be a triangular shape, or may be a shape in which one side or two sides of a triangular shape are curved. The curve may be a convex curve or a concave curve. The curved sides may have an arcuate or parabolic shape.

In the present disclosure, considering that a display device is provided in an optical system of an eyewear device such as a VR device, an MR device, or an AR device, the multilayer body is preferably configured to be capable of condensing incident light from a light-emitting element toward an optical axis of the optical system.

As described above, in order to condense the incident light from the light-emitting element toward the optical axis of the optical system, the multilayer body is preferably configured so that the pixel located further outward of the effective pixel region is able to direct the incident light from the light-emitting element further inward of the effective pixel region. More specifically, it is preferable that at least one feature of a width of a formation region of the first lens portion, a shift amount of a center of the first lens portion with reference to a center of the light-emitting region of the pixel, a shape of the first lens portion, or a height of the first lens portion is changed from the center of the effective pixel region toward an outer periphery, and the pixel located further outward of the effective pixel region is able to direct the incident light from the light-emitting element further inward of the effective pixel region due to the change.

Specifically, a change in the width of the formation region of the first lens portion is preferably that a width of a portion located on a center side of the effective pixel region in the formation region of the first lens portion becomes narrower from the center of the effective pixel region toward the outer periphery.

Specifically, a change in the shift amount of the center of the first lens portion with reference to the center of the light-emitting region of the pixel is preferably as follows. Preferably, the plurality of first lens portions include a first lens portion in which the center of the first lens portion is shifted in a direction from the outer periphery of the effective pixel region toward the center with reference to the center of the light-emitting region of the pixel, and the shift amount between the center of the light-emitting region of the pixel and the center of the first lens portion increases from the center of the effective pixel region toward the outer periphery.

Preferably, at least one feature of a shift amount of a center of the second lens portion with reference to a center of the light-emitting region of the pixel, a width of a formation region of the second lens portion, a shape of the second lens portion, or a height of the second lens portion is changed from the center of the effective pixel region toward an outer periphery, and the pixel located further outward of the effective pixel region is able to direct the incident light from the light-emitting element further inward of the effective pixel region due to the change.

Specifically, the change in the shift amount of the center of the second lens portion with reference to the center of the light-emitting region of the pixel is preferably as follows. Preferably, the plurality of second lens portions include a second lens portion in which the center of the second lens portion is shifted in a direction from the outer periphery of the effective pixel region toward the center with reference to the center of the light-emitting region of the pixel, and the shift amount between the center of the light-emitting region of the pixel and the center of the second lens portion increases from the center of the effective pixel region toward the outer periphery.

Specifically, a change in the width of the formation region of the second lens portion is preferably that a width of the formation region of the second lens portion becomes narrower from the outer periphery toward the center of the effective pixel region, and the center of the second lens portion is shifted in a direction from the outer periphery toward the center of the effective pixel region with reference to the center of the light-emitting region of the pixel by the amount of the width of the formation region of the second lens portion becoming narrower.

In the present disclosure, considering that the display device is provided in an optical system such as an eyewear device such as a VR device, an MR device, or an AR device, the multilayer body is preferably configured to be capable of spreading incident light from the light-emitting element with respect to an optical axis of the optical system.

As described above, in order to spread the incident light from the light-emitting element with respect to the optical axis of the optical system, the multilayer body is preferably configured so that the pixel located further outward of the effective pixel region is able to direct the incident light from the light-emitting element further outward of the effective pixel region. More specifically, it is preferable that at least one feature of the width of the formation region of the first lens portion, the shift amount of the center of the first lens portion with reference to the center of the light-emitting region of the pixel, the shape of the first lens portion, or the height of the first lens portion is changed from the center of the effective pixel region toward the outer periphery, and the pixel located further outward of the effective pixel region is configured to be able to direct the incident light from the light-emitting element further outward of the effective pixel region due to the change.

Specifically, the change in the width of the formation region of the first lens portion is preferably that a width of a portion located on an outer peripheral side of the effective pixel region in the formation region of the first lens portion becomes narrower from the center of the effective pixel region toward the outer periphery.

Specifically, a change in the shift amount of the center of the first lens portion with reference to the center of the light-emitting region of the pixel is preferably as follows. Preferably, the plurality of first lens portions include a first lens portion in which the center of the first lens portion is shifted in a direction from the center of the effective pixel region toward the outer periphery with reference to the center of the light-emitting region of the pixel, and a shift amount between the center of the light-emitting region of the pixel and the center of the first lens portion increases from the center of the effective pixel region toward the outer periphery.

Preferably, at least one feature of the shift amount of the center of the second lens portion with reference to the center of the light-emitting region of the pixel, the width of the formation region of the second lens portion, the shape of the second lens portion, or the height of the second lens portion is changed from the center of the effective pixel region toward the outer periphery, and the pixel located further outward of the effective pixel region is configured to be able to direct the incident light from the light-emitting element further outward of the effective pixel region due to the change.

Specifically, the change in the shift amount of the center of the second lens portion with reference to the center of the light-emitting region of the pixel is preferably as follows. Preferably, the plurality of second lens portions include a second lens portion in which the center of the second lens portion is shifted in a direction from the center of the effective pixel region toward the outer periphery with reference to the center of the light-emitting region of the pixel, and the shift amount between the center of the light-emitting region of the pixel and the center of the second lens portion increases from the center of the effective pixel region toward the outer periphery.

Specifically, a change in the width of the formation region of the second lens portion is preferably that the width of the formation region of the second lens portion becomes narrower from the center of the effective pixel region toward the outer periphery, and the center of the second lens portion is shifted in a direction from the center of the effective pixel region toward the outer periphery with reference to the center of the light-emitting region of the pixel by the amount of the width of the formation region of the second lens portion becoming narrower.

In the present disclosure, a “pixel” is a minimum unit constituting an image. For example, in a case where one pixel includes a plurality of subpixels, one subpixel may be referred to as a “pixel” in the present disclosure. The plurality of subpixels may include three subpixels, four subpixels, or other number of subpixels. The three subpixels are, for example, a red subpixel, a green subpixel, and a blue subpixel. The four subpixels may be, for example, a red subpixel, a green subpixel, a blue subpixel, and a white subpixel, or may be a red subpixel, a green subpixel, a blue subpixel, and a blue subpixel. The red subpixel is a subpixel that can emit red light. The green subpixel is a subpixel that can emit green light. The blue subpixel is a subpixel that can emit blue light. The white subpixel is a subpixel that can emit white light.

In the present disclosure, “a member a contains X” may indicate that the member a contains X as a main component, the member a is substantially constituted by X, or the member a is constituted by X. Here, “the member a contains X as a main component” may indicate that the content of X in the member a is 50 mass % or more and 100 mass % or less, 60 mass % or more and 100 mass % or less, 70 mass % or more and 100 mass or less, 80 mass or more and 100 mass % or less, 90 mass % or more and 100 mass % or less, 95 mass % or more and 100 mass % or less, or 99 mass % or more and 100 mass % or less.

In the present disclosure, “a multilayer body covering a plurality of light-emitting elements” is a concept including not only a state in which the multilayer body directly covers a top of the plurality of light-emitting elements without another member interposed therebetween, but also a state in which the multilayer body covers the top of the plurality of light-emitting elements with another member interposed therebetween. Here, the other member may include, for example, at least one selected from a group including a protective layer, a flattening layer, and a color filter.

In the present disclosure, “on a target A” in expressions such as “a target B is located on a target A”, “the target B is provided on the target A”, and “the target B provided on the target A” indicates a relative positional relationship between the target A and the target B, and is a concept including not only a state in which the target B is directly located on the target A without a target C interposed therebetween but also a state in which the target B is located on the target A with the target C interposed therebetween.

### 2. First Embodiment

### Configuration of Display Device 101

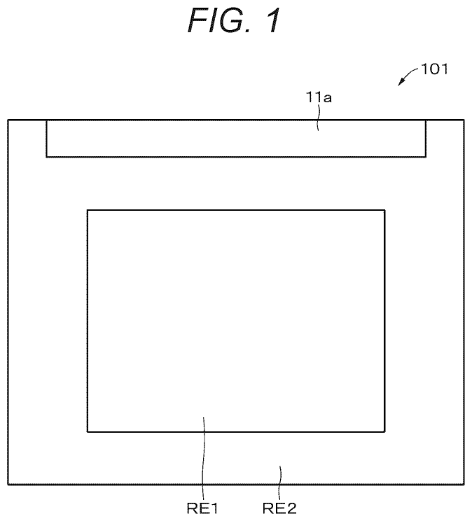

FIG. 1 is a plan view of a display device 101 according to a first embodiment. The display device 101 includes an effective pixel region RE1 and a peripheral region RE2 provided around the effective pixel region RE1.

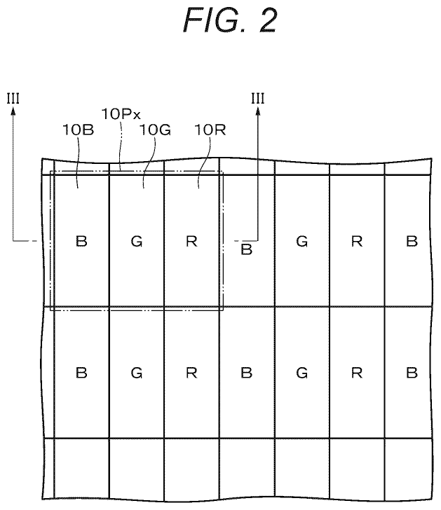

FIG. 2 is an enlarged plan view illustrating a part of the effective pixel region RE1. A plurality of subpixels 10R, 10G, and 10B is two-dimensionally arranged in a prescribed arrangement pattern in the effective pixel region RE1. FIG. 2 illustrates an example in which the prescribed arrangement pattern is a stripe array. The prescribed arrangement pattern is not limited to a stripe array, and may be a mosaic array, a square array, a delta array, or an array other than these. A pad 11a, a video display driver (not illustrated), and the like are provided in the peripheral region RE2. A flexible printed circuit (FPC) board (not illustrated) may be connected to the pad 11a.

The subpixel 10R can emit red light (first light). The subpixel 10G can emit green light (second light). The subpixel 10B can emit blue light (third light). In FIG. 2, sections denoted by symbols “R”, “G”, and “B” represent the subpixel 10R, the subpixel 10G, and the subpixel 10B, respectively. Although the outlines of the subpixel 10R, the subpixel 10G, and the subpixel 10B are illustrated in FIG. 2, there is not always a clear boundary among the adjacent subpixels 10R, 10G, and 10B.

In the following description, the subpixels 10R, 10G, and 10B may be collectively referred to as subpixels 10 in a case where they are collectively referred to without being particularly distinguished. One pixel (one pixel) 10Px is, for example, constituted by a plurality of adjacent subpixels 10R, 10G, and 10B. However, the configuration of one pixel 10Px is not limited to this example, and for example, one pixel 10Px may be constituted by a plurality of adjacent subpixels 10R, 10G, 10B, and 10B.

Examples of the shape of the subpixel 10 include a quadrangular shape such as a rectangular shape in a plan view, a hexagonal shape, a circular shape, an elliptical shape, and the like, but are not limited to these shapes. Herein, it is assumed that the rectangular shape includes a square shape. Note that FIG. 2 illustrates an example in which the subpixel 10 have a rectangular shape in plan view. The upper limit of the size of the subpixel 10 is preferably less than or equal to 10 μm, more preferably less than or equal to 8 μm, still more preferably less than or equal to 5 μm, less than or equal to 4 μm, or less than or equal to 3.5 μm. The lower limit of the size of the subpixel 10 is, for example, greater than or equal to 1 μm.

The display device 101 may be a top-emitting OLED display device. The display device 101 may be a microdisplay. The display device 101 may be provided in an eyewear device such as a virtual reality (VR) device, a mixed reality (MR) device, an augmented reality (AR) device, an electronic viewfinder (EVF), a small projector, or the like.

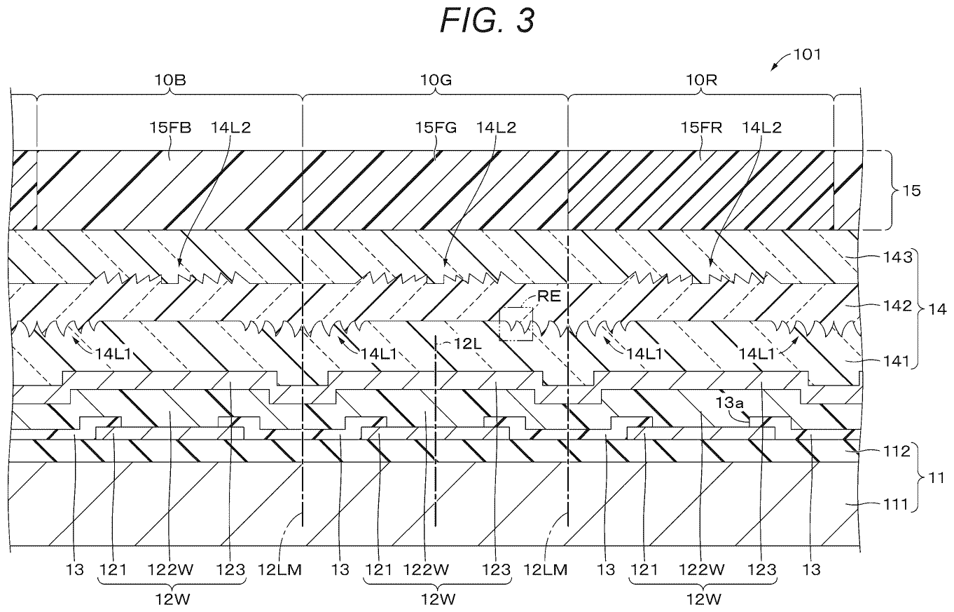

FIG. 3 is a cross-sectional view taken along line III-III in FIG. 2. The display device 101 includes a drive substrate 11, a plurality of light-emitting elements 12W, an insulating layer 13, a multilayer body 14, and a color filter 15.

Herein, of both surfaces of each layer constituting the display device 101, a surface on a bottom side (side opposite to a display surface) of the display device 101 may be referred to as first surface, and a surface on a top side (display surface side) of the display device 101 may be referred to as second surface. Herein, a peripheral edge portion of the first surface refers to a region extending inward from a peripheral edge of the first surface by a predetermined width, and a peripheral edge portion of the second surface refers to a region extending inward from a peripheral edge of the second surface by a predetermined width. Herein, the plan view refers to a plan view when an object is viewed from a direction perpendicular to the first surface or the second surface of the object.

### (Drive Substrate 11)

The drive substrate 11 is a so-called backplane and can drive a plurality of light-emitting elements 12W. The drive substrate 11 includes, for example, a substrate 111 and an insulating layer 112 in sequence.

A plurality of drive circuits (not illustrated), a plurality of wirings (none of which are illustrated), and the like are provided on a second surface of the substrate 111. The substrate 111 may include, for example, a semiconductor substrate in which a transistor or the like is easily formed, or may include glass substrate or resin substrate having low moisture and oxygen permeability. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

The insulating layer 112 may be provided on the second surface of the substrate 111, and cover and planarize a plurality of drive circuits, a plurality of wirings, and the like. The insulating layer 112 may insulate the plurality of drive circuits, the plurality of wirings, and the like provided on the second surface of the substrate 111 from the plurality of light-emitting elements 12W. The wiring may be connected to the pad 11a.

The insulating layer 112 may be an organic insulating layer, an inorganic insulating layer, or a multilayer body thereof. The organic insulating layer includes, for example, at least one selected from a group including polyimide resin, acrylic resin, novolac resin, and the like. The inorganic insulating layer includes, for example, at least one selected from a group including silicon oxide (SiOₓ), silicon nitride (SiNₓ), silicon oxynitride (SiOₓN_{y}), and the like.

The insulating layer 112 includes a plurality of contact portions (not illustrated) therein. The contact portions electrically connect the light-emitting elements 12W and wirings. The contact portion contains, for example, at least one metal selected from a group including copper (Cu), titanium (Ti), and the like.

### (Light-Emitting Element 12W)

The light-emitting element 12W can emit white light under the control of a drive circuit or the like. The light-emitting element 12W is an OLED element. The OLED element may be a micro-OLED (M-OLED) element. The light-emitting element 12W is included in each color of the subpixels 10R, 10G, and 10B.

The plurality of light-emitting elements 12W is two-dimensionally arranged on a second surface of the drive substrate 11 in a prescribed arrangement pattern. The prescribed arrangement pattern is as described for the prescribed arrangement pattern of the plurality of subpixels 10. The light-emitting element 12W includes a first electrode 121, an OLED layer 122W, and a second electrode 123 in sequence on the second surface of the drive substrate 11.

### (First Electrode 121)

The first electrode 121 is provided on a first surface side of the OLED layer 122W. The first electrode 121 is an individual electrode individually provided in the plurality of light-emitting elements 12W in the effective pixel region RE1. That is, the first electrode 121 is divided between the light-emitting elements 12W adjacent in the in-plane direction of the second surface of the drive substrate 11 in the effective pixel region RE1. The first electrode 121 may have a flat shape. The first electrode 121 is an anode. When a voltage is applied between the first electrode 121 and the second electrode 123, holes are injected from the first electrode 121 into the OLED layer 122W.

The first electrode 121 may include, for example, a metal layer, or may include a metal layer and a transparent conductive oxide layer. In a case where the first electrode 121 includes a metal layer and a transparent conductive oxide layer, the transparent conductive oxide layer is preferably provided adjacent to the OLED layer 122W from the viewpoint of placing a layer with a high work function adjacent to the OLED layer 122W.

The metal layer also functions as a reflection layer that reflects light emitted from the OLED layer 122W. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

An underlayer (not illustrated) may be provided adjacent to a first surface of the metal layer. The underlayer may be able to improve the crystalline orientation of the metal layer at the time of formation of the metal layer. The underlayer includes, for example, at least one metal element selected from a group including titanium (Ti) and tantalum (Ta). The underlayer may include the at least one metal element described above as a constituent element of an alloy.

The transparent conductive oxide layer includes a transparent conductive oxide. The transparent conductive oxide includes, for example, at least one selected from a group including indium-containing transparent conductive oxide (hereinafter referred to as “indium-based transparent conductive oxide”), tin-containing transparent conductive oxide (hereinafter referred to as “tin-based transparent conductive oxide”), and zinc-containing transparent conductive oxide (hereinafter referred to as “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO), or fluorine-doped indium oxide (IFO). Among these transparent conductive oxides, the indium tin oxide (ITO) is particularly preferable. This is because the indium tin oxide (ITO) has a particularly low barrier for hole injection into the OLED layer 122W in terms of work function, and accordingly, the drive voltage of the display device 101 can be significantly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (OLED Layer 122W)

The OLED layer 122W can emit white light. The OLED layer 122W is disposed between a plurality of first electrodes 121 and one second electrode 123. The OLED layer 122W is connected between the light-emitting elements 12W adjacent in the in-plane direction of the second surface of the drive substrate 11 in the effective pixel region RE1, and is a layer common to the plurality of light-emitting elements 12W in the effective pixel region RE1. The OLED layer 122W are examples of the organic-containing layer in the claims.

The OLED layer 122W may each include a multilayer body including the corresponding organic light-emitting layer, and in this case, a part of the multilayer body (for example, an electron injection layer) may be an inorganic layer. The OLED layer 122W may be an OLED layer including a single-layer light-emitting unit, an OLED layer including a two-layer light-emitting unit (tandem structure), or an OLED layer having a structure other than these structures. The OLED layer including a single-layer light-emitting unit has, for example, a configuration in which a hole injection layer, a hole transport layer, a red light-emitting layer, a light-emitting separation layer, a blue light-emitting layer, a green light-emitting layer, an electron transport layer, and an electron injection layer are stacked in this order from the first electrodes 121 toward the second electrode 123. The OLED layer including a two-layer light-emitting unit has a configuration where a hole injection layer, a hole transport layer, a blue light-emitting layer, an electron transport layer, a charge generation layer, a hole transport layer, a yellow light-emitting layer, an electron transport layer, and an electron injection layer are stacked in this order from the first electrode 121 toward the second electrode 123, for example.

The hole injection layer can enhance the efficiency of hole injection into each light-emitting layer, and suppress leakage. The hole transport layer can enhance the efficiency of hole transport to each light-emitting layer. The electron injection layer can enhance the efficiency of electron injection into each light-emitting layer. The electron transport layer can enhance the efficiency of electron transport to each light-emitting layer. The light-emitting separation layer is a layer for regulating injection of carriers into each light-emitting layer, and light-emitting balance of each color is adjusted by injecting electrons or holes into each light-emitting layer via the light-emitting separation layer. The charge generation layer can supply electrons to one of the two light-emitting layers between which the charge generation layer is sandwiched and holes to the other light-emitting layer.

In response to application of an electric field to each of the red light-emitting layer, the green light-emitting layer, the blue light-emitting layer, and the yellow light-emitting layer, recombination occurs between holes injected from the first electrodes 121 or the charge generation layer and electrons injected from the second electrode 123 or the charge generation layer, and red light, green light, blue light, and yellow light can be emitted.

### (Second Electrode 123)

The second electrode 123 is provided on the second surface side of the OLED layer 122W. The second electrode 123 is connected between the light-emitting elements 12W adjacent in the in-plane direction of the second surface of the drive substrate 11 in the effective pixel region RE1, and is an electrode common to the plurality of light-emitting elements 12W in the effective pixel region RE1.

The second electrode 123 is a cathode. When a voltage is applied between the first electrode 121 and the second electrode 123, electrons are injected from the second electrode 123 into the OLED layer 122W. The second electrode 123 is has translucency to each light emitted from the OLED layer 122W. The second electrode 123 is preferably a transparent electrode transparent to visible light. Herein, the visible light refers to light in a wavelength range of 360 nm to 830 nm.

The second electrode 123 preferably includes a material having translucency as high as possible and a work function as low as possible in order to enhance the luminous efficiency. The second electrode 123 includes, for example, at least one of a metal layer or a transparent conductive oxide layer. More specifically, the second electrode 123 includes a single-layer film of a metal layer or a transparent conductive oxide layer, or a multilayer film of a metal layer and a transparent conductive oxide layer. In a case where the second electrode 123 includes a multilayer film, the metal layer may be provided adjacent to the OLED layer 122W, or the transparent conductive oxide layer may be provided adjacent to the OLED layer 122W, but, from the viewpoint of placing a layer with a low work function adjacent to the OLED layer 122W, the metal layer is preferably provided adjacent to the OLED layer 122W.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The transparent conductive oxide layer includes a transparent conductive oxide. As the transparent conductive oxide, a material similar to the transparent conductive oxide of the first electrode 121 described above can be exemplified.

### (Insulating Layer 13)

The insulating layer 13 is provided on a second surface of the drive substrate 11 between the separated first electrodes 121. The insulating layer 13 can insulate between the first electrodes 121 adjacent in the in-plane direction of the second surface of the drive substrate 11. The insulating layer 13 has a plurality of openings 13a. Each of the plurality of openings 13a is provided for a corresponding one of the light-emitting elements 12W. More specifically, each of the plurality of openings 13a is provided on the second surface (the surface adjacent to the OLED layer 122W) of a corresponding one of the first electrodes 121. The first electrode 121 and the OLED layer 122W are in contact with each other via the opening 13a.

The insulating layer 13 may be an organic insulating layer, an inorganic insulating layer, or a multilayer body including these. The organic insulating layer includes, for example, at least one selected from a group including polyimide resin, acrylic resin, novolac resin, and the like. The inorganic insulating layer includes, for example, at least one selected from a group including silicon oxide (SiOₓ), silicon nitride (SiNₓ), silicon oxynitride (SiOₓN_{y}), and the like.

### (Multilayer Body 14)

The multilayer body 14 is provided on a second surface of the second electrode 123 and covers the plurality of light-emitting elements 12W. The multilayer body 14 can condense light emitted in an oblique direction from each light-emitting element 12W and bring the light close to parallel light. The multilayer body 14 is translucency to white light emitted from the light-emitting element 12W. The multilayer body 14 is preferably transparent to visible light. The multilayer body 14 may have a function as a protective layer. For example, the multilayer body 14 can suppress moisture ingress into the plurality of light-emitting elements 12W from an external environment. Furthermore, in a case where the second electrode 123 includes a metal layer, the multilayer body 14 may have a function of inhibiting oxidation of the metal layer.

The multilayer body 14 includes a first layer 141, a second layer 142, and a third layer 143 in order on the second surface of the second electrode 123. The first layer 141 has a first refractive index n₁. The second layer 142 has a second refractive index n₂ different from the first refractive index n₁. The third layer 143 has a third refractive index n₃ different from the second refractive index n₂. The first refractive index n₁, the second refractive index n₂, and the third refractive index n₃ satisfy, for example, n₁ and n₃<n₂. The refractive index difference Δn₂₁ (=|n₂−n₁|) between the second layer 142 and the first layer 141 is preferably equal to or more than 0.1, more preferably equal to or more than 0.2, still more preferably equal to or more than 0.3, 0.4 or 0.5. The refractive index difference Δn₂₃ (=|n₂−n₃|) between the second layer 142 and the third layer 143 is preferably equal to or more than 0.1, more preferably equal to or more than 0.2, still more preferably equal to or more than 0.3, 0.4, or 0.5. Herein, the refractive index refers to a refractive index for light having a wavelength of 589.3 nm (sodium D line).

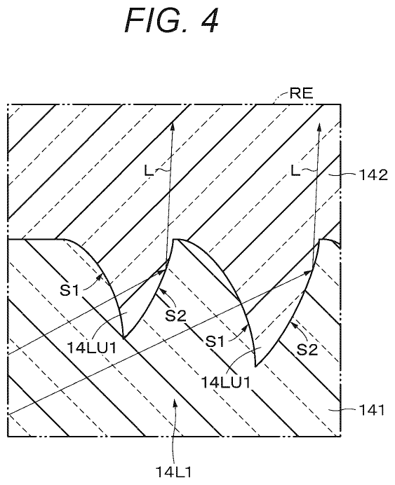

FIG. 4 is an enlarged cross-sectional view illustrating a region RE in FIG. 3. The second layer 142 includes a plurality of first lens portions 14L1 and a plurality of second lens portions 14L2. From the viewpoint of improving the light condensing effect, shapes of a first lens portion 14L1 and a second lens portion 14L2 and the positional relationship between the first lens portion 14L1 and the second lens portion 14L2 may be adjusted in accordance with the size of the subpixel 10.

The plurality of first lens portions 14L1 is provided on a first surface (surface on the first layer 141 side) of the second layer 142, and each first lens portion 14L1 is located in the peripheral portion of the subpixel 10 in plan view. The first lens portion 14L1 can reflect light emitted from each light-emitting element 12W at a wide angle, bring the light close to parallel light, and emit the light. Here, the parallel light represents a light beam parallel to a perpendicular line of the display surface. The first lens portion 14L1 is a lens array (first lens array) and includes a plurality of first protrusions (single lenses) 14LU1. The lens array may be a concentric prism lens array.

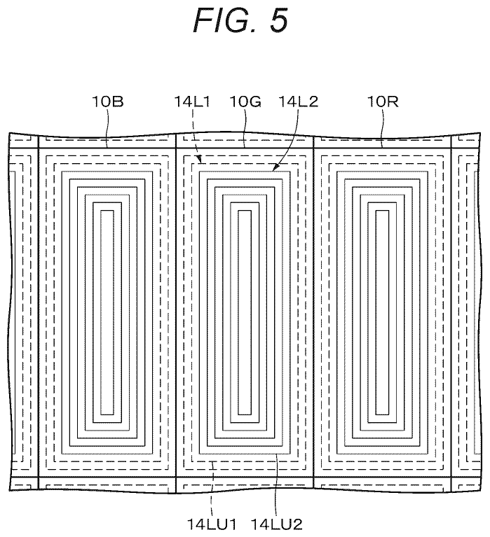

FIG. 5 is a plan view of the first lens portion 14L1 and the second lens portion 14L2. The plurality of first protrusions 14LU1 may have a concentric shape surrounding a central portion of the subpixel 10 in plan view. The concentric shape may be, for example, a concentric polygonal shape, a concentric oval shape, or a concentric circular shape, but is not limited to these examples. The concentric polygonal shape may be, for example, a concentric rectangular shape or a concentric hexagonal shape, but is not limited to these shapes. Each of the first protrusions 14LU1 may have an annular shape surrounding the central portion of the subpixel 10. The height of the plurality of first protrusions 14LU1 (the height of the lens array) preferably increases with increasing distance from the concentric center. Thus, since the amount of incident light incident on the plurality of first protrusions 14LU1 can be increased, the amount of reflected light by the first lens portion 14L1 can be increased. Therefore, luminous efficiency can be further enhanced. The concentric center preferably substantially coincides with an optical axis 12L of the light-emitting element 12W.

The first protrusion 14LU1 includes a first surface S1 and a second surface S2. The first surface S1 is a surface on an inner peripheral side of the first protrusion 14LU1, and the second surface S2 is a surface on the outer peripheral side of the first protrusion 14LU1. Since the first refractive index n₁ and the second refractive index n₂ satisfy n₁<n₂ as described above, light L emitted from the light-emitting element 12W at a wide angle is reflected by the second surface S2 after passing through the first surface S1. The first protrusion 14LU1 may have a ridge line. The ridge line may be formed by bringing an upper side of the first surface S1 and an upper side of the second surface S2 into contact with each other.

The cross-sectional shape of the first surface S1 is, for example, a concave curved line shape. The concave curved line shape is, for example, an arc shape. The cross-sectional shape of the second surface S2 is, for example, a convex curved line shape. The convex curved line shape is, for example, a parabolic shape. Here, the cross-sectional shape of the first surface S1 represents a cross-sectional shape of the first surface S1 obtained by cutting the first protrusion 14LU1 in a plane perpendicular to a circumferential direction of the first protrusion 14LU1. The cross-sectional shape of the second surface S2 represents a cross-sectional shape of the second surface S2 obtained by cutting the first protrusion 14LU1 in a plane perpendicular to the circumferential direction of the first protrusion 14LU1. In the present specification, a lens array having the above-described cross-sectional shape is also included in the prism lens array.

The plurality of second lens portions 14L2 is provided on a second surface (surface on the third layer 143 side) of the second layer 142, and each second lens portion 14L2 is located at the central portion of the subpixel 10 in plan view. The second lens portion 14L2 can condense the light emitted from each light-emitting element 12W at a low angle, bring the light close to parallel light, and emit the light. The second lens portion 14L2 is a Fresnel lens array (second lens array) and includes a plurality of second protrusions (single lenses) 14LU2.

As described above, since the second refractive index n₂ and the third refractive index n₃ satisfy n₃<n₂, the second lens portion 14L2 can have a light condensing function. That is, the light L emitted from the light-emitting element 12W at a low angle is refracted so as to bring the light close to parallel light at the interface between the second lens portion 14L2 and the third layer 143.

The plurality of second protrusions 14LU2 may be arranged concentrically in a plan view from a direction perpendicular to the second surface of the second layer 142. The concentric shape may be, for example, a concentric polygonal shape, a concentric oval shape, or a concentric circular shape, but is not limited to these examples. The concentric polygonal shape may be, for example, a concentric rectangular shape or a concentric hexagonal shape, but is not limited to these shapes. The concentric center preferably substantially coincides with the optical axis 12L of the light-emitting element 12W. In the present specification, a lens array having a concentric shape other than the concentric shape is also included in the Fresnel lens array.

When a center line which is parallel to the optical axis 12L of the light-emitting element 12W and passes through a midpoint between the adjacent subpixels 10 is a center line 12LM, the light-emitting element 12W, the first lens portion 14L1, and the second lens portion 14L2 included in the adjacent subpixels 10 may be symmetric with respect to the center line 12LM. Here, the midpoint between the adjacent subpixels 10 represents a point at an equal distance from both ends of a straight line connecting geometric centers of the adjacent subpixels 10.

The materials of the first layer 141 and the second layer 142 are preferably different. Here, the difference in the materials of the first layer 141 and the second layer 142 may refer to either the components of the materials constituting the first layer 141 and the second layer 142 being different, or the components of the materials constituting the first layer 141 and the second layer 142 being the same but with varying content ratios. The materials of the second layer 142 and the third layer 143 are preferably different from each other. Here, the difference in the materials of the second layer 142 and the third layer 143 may refer to either the components of the materials constituting the second layer 142 and the third layer 143 being different, or the components of the materials constituting the second layer 142 and the third layer 143 being the same but with varying content ratios.

The first layer 141, the second layer 142, and the third layer 143 include, for example, an inorganic material or a polymer resin having low hygroscopicity. The first layer 141, the second layer 142, and the third layer 143 may have a single-layer structure or a multilayer structure. In a case where the thickness of each of the first layer 141, the second layer 142, and the third layer 143 is increased, a multilayer structure is preferable. This is to alleviate internal stress in each of the first layer 141, the second layer 142, and the third layer 143. The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one resin selected from a group including thermosetting resin, ultraviolet curable resin, and the like. Specifically, the polymer resin includes, for example, at least one selected from a group including acrylic resin, polyimide resin, novolac resin, epoxy resin, norbornene resin, parylene resin, and the like.

### (Color Filter 15)

The color filter 15 is provided above the plurality of light-emitting elements 12W. More specifically, the color filter 15 is provided on a second surface of the multilayer body 14. The color filter 15 is, for example, an on-chip color filter (OCCF). The color filter 15 includes, for example, a plurality of red filter portions 15FR, a plurality of green filter portions 15FG, and a plurality of blue filter portions 15FB. Note that, in the following description, the red filter portions 15FR, the green filter portions 15FG, and the blue filter portions 15FB may be collectively referred to as filter portion 15F in a case where they are collectively referred to without being particularly distinguished.

The plurality of filter portions 15F is two-dimensionally arranged on the second surface of the multilayer body 14 in a prescribed arrangement pattern. The prescribed arrangement pattern is as described for the prescribed arrangement pattern of the plurality of subpixels 10. Each filter portion 15F is provided above a corresponding one of the light-emitting elements 12W. The subpixel 10R includes a light-emitting element 12W and a red filter portion 15FR provided above the light-emitting element 12W. The subpixel 10G includes a light-emitting element 12W and a green filter portion 15FG provided above the light-emitting element 12W. The subpixel 10B includes a light-emitting element 12W and a blue filter portion 15FB provided above the light-emitting element 12W.

The red filter portions 15FR can transmit red light out of the white light emitted from the light-emitting elements 12W and absorb light other than the red light. The green filter portions 15FG can transmit green light out of the white light emitted from the light-emitting elements 12W and absorb light other than the green light. The blue filter portions 15FB can transmit blue light out of the white light emitted from the light-emitting elements 12W and absorb light other than the blue light.

The red filter portion 15FR includes, for example, a red color resist. The green filter portion 15FG includes, for example, a green color resist. The blue filter portion 15FB includes, for example, a blue color resist.

### Method for Manufacturing Display Device 101

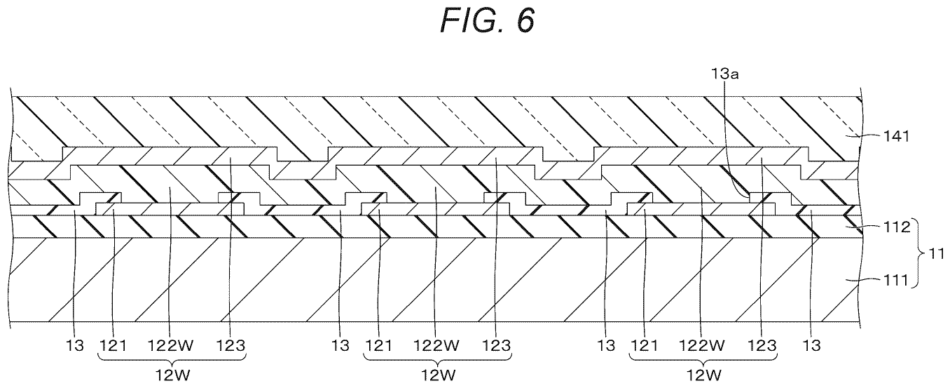

Hereinafter, an example of the method for manufacturing the display device 101 according to the first embodiment will be described with reference to FIGS. 6 to 10.

### (Process of Forming First Electrode 121)

First, a metal layer and a metal oxide layer are sequentially formed on the second surface of the drive substrate 11 by, for example, a sputtering method, and then the metal layer and the metal oxide layer are patterned by, for example, a photolithography method. Thus, the plurality of first electrodes 121 is formed on the second surface of the drive substrate 11.

### (Process of Forming Insulating Layer 13)

Next, the insulating layer 13 is formed on the second surface of the drive substrate 11 in such a way as to cover the plurality of first electrodes 121 by, for example, a chemical vapor deposition (CVD) method. Next, the openings 13a are formed in the insulating layer 13 at portions corresponding to the second surfaces of the first electrodes 121 by, for example, a photolithography technique.

### (Process of Forming OLED Layer 122W)

Next, a hole transport layer, a red light-emitting layer, a light-emitting separation layer, a blue light-emitting layer, a green light-emitting layer, an electron transport layer, and an electron injection layer are stacked in this order on the second surfaces of the plurality of first electrodes 121 and the second surface of the drive substrate 11 by, for example, a vapor deposition method, thereby forming the OLED layer 122W.

### (Process of Forming Second Electrode 123)

Next, the second electrode 123 is formed on the second surface of the OLED layer 122W by, for example, a vapor deposition method or a sputtering method. Thus, the plurality of light-emitting elements 12W is thus formed on the second surface of the drive substrate 11.

### (Process of Forming Multilayer Body 14)

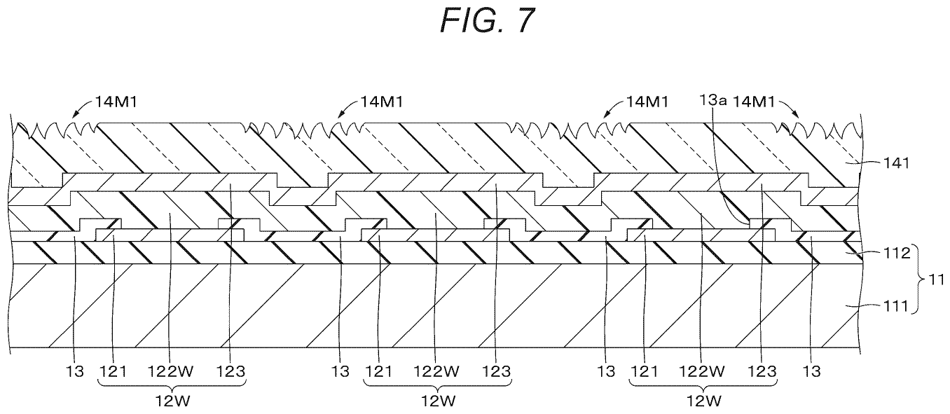

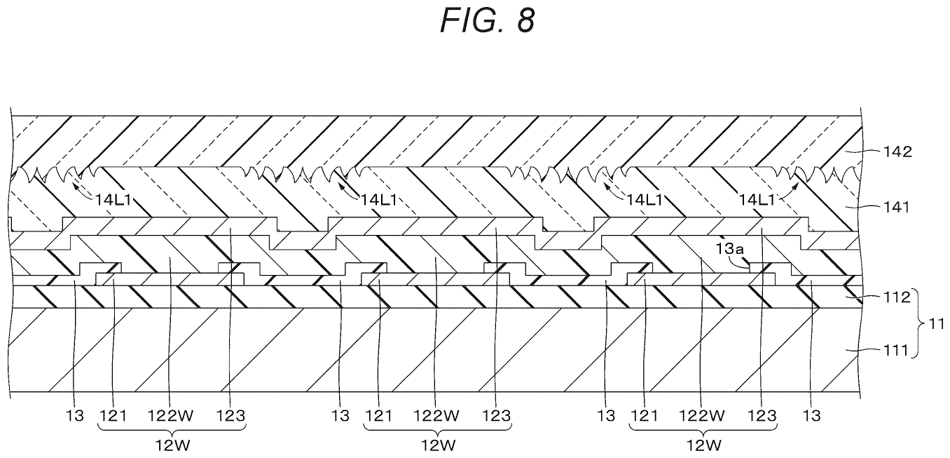

Next, as illustrated in FIG. 6, the first layer 141 is formed on the second surface of the second electrode 123 by, for example, a CVD method. Next, for example, as illustrated in FIG. 7, a plurality of uneven portions 14M1 corresponding to the plurality of first lens portions 14L1 is formed on a second surface of the first layer 141 by a photolithography technique using a hard mask or the like. Next, as illustrated in FIG. 8, the second layer 142 is formed on the second surface of the first layer 141 by a CVD method, for example, so as to fill the plurality of uneven portions 14M1. Thus, the plurality of first lens portions 141L1 is formed on the first surface of the second layer 142.

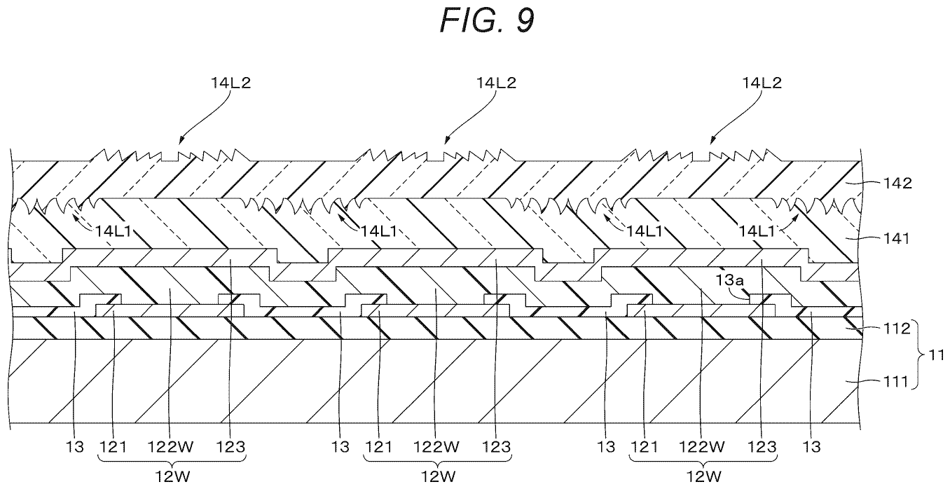

Next, as illustrated in FIG. 9, the plurality of second lens portions 14L2 is formed on the second surface of the second layer 142 by a photolithography technique using a hard mask or the like, for example.

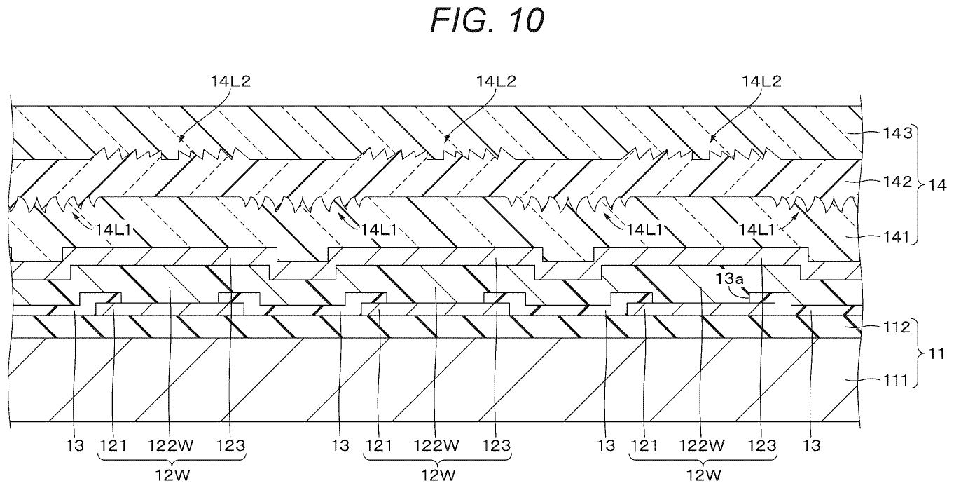

Next, as illustrated in FIG. 10, the third layer 143 is formed on the second surface of the second layer 142 so as to fill the plurality of second lens portions 14L2 by, for example, a CVD method. Thus, the multilayer body 14 including the first layer 141, the second layer 142, and the third layer 143 is formed on the second surface of the second electrode 123.

### (Process of Forming Color Filter 15)

Next, a coloring composition for forming a green filter portion is applied onto the second surface of the multilayer body 14, and after pattern exposure by irradiation with ultraviolet rays through a photomask, development is performed to form the green filter portion 15FG. Next, a coloring composition for forming a red filter portion is applied onto the second surface of the multilayer body 14, and after pattern exposure by irradiation with ultraviolet rays through a photomask, development is performed to form the red filter portion 15FR. Next, a coloring composition for forming a blue filter portion is applied onto the second surface of the multilayer body 14, and after pattern exposure by irradiation with ultraviolet rays through a photomask, development is performed to form the blue filter portion 15FB. Thus, the color filter 15 is formed on the second surface of the multilayer body 14. As described above, the intended display device 101 is obtained.

### Operations and Effects

In the display device 101 according to the first embodiment, the plurality of first lens portions 14L1 is provided on the first surface (surface on the first layer 141 side) of the second layer 142, and each of the first lens portions 14L1 includes the plurality of first protrusions 14LU1 arranged concentrically and is located in the peripheral portion of the subpixel 10 in plan view. Furthermore, the plurality of second lens portions 14L2 is provided on the second surface (surface on the third layer 143 side) of the second layer 142, and each of the second lens portions 14L2 includes the plurality of second protrusions 14LU2 arranged concentrically and is located at the central portion of the subpixel 10 in plan view. Thus, the light L emitted from the light-emitting element 12W at a wide angle is reflected by the first lens portion 14L1 and brought close to parallel light. On the other hand, the light L emitted from the light-emitting element 12W at a low angle is condensed by the second lens portion 14L2 and brought close to parallel light. Accordingly, luminous efficiency can be improved, and color mixing can be suppressed.

The second lens portion 14L2 provided on the second surface (surface on the third layer 143 side) of the second layer 142 is a Fresnel lens array. Therefore, the distance between the light-emitting element 12W and the filter portion 15F can be reduced. Therefore, color mixing can be suppressed.

### 2. Second Embodiment

In the following description, a first direction and a second direction orthogonal to each other in display surfaces of display devices 101, 102, and the like may be referred to as an X-axis direction and a Y-axis direction, respectively, and a third direction perpendicular to the display surfaces of the display devices 101, 102, and the like may be referred to as a Z-axis direction. For example, the X-axis direction corresponds to a horizontal direction of the display surface, and the Y-axis direction corresponds to a vertical direction of the display surface.

In the display device 101 according to the first embodiment, the light L emitted from the light-emitting element 12W at a wide angle is reflected by the first lens portion 14L1 and brought close to parallel light (see FIG. 4), and the light L emitted from the light-emitting element 12W at a low angle is condensed by the second lens portion 14L2 and brought close to parallel light. Thus, in the display device 101 according to the first embodiment, the light extraction efficiency in a front direction (a direction perpendicular to the display surface) is improved.

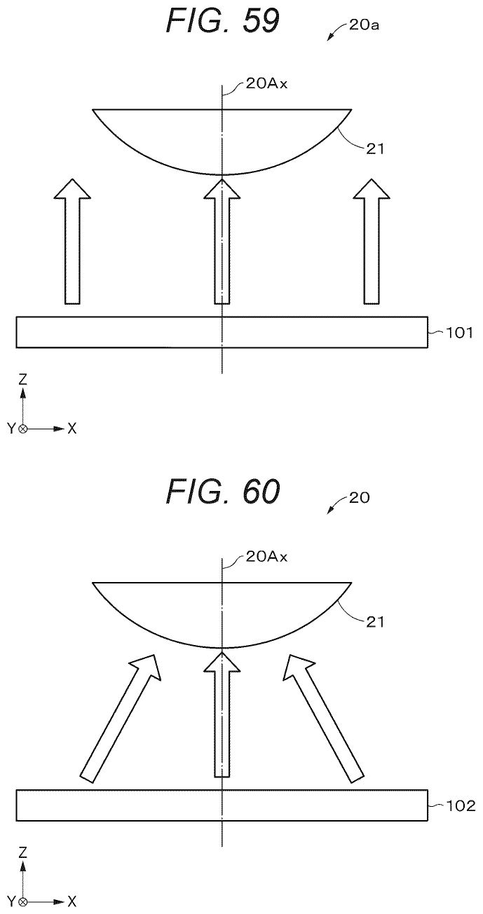

However, as illustrated in FIG. 59, in a case where the display device 101 is provided in an optical system 20a of an eyewear device such as a VR device, an MR device, or an AR device, there is a possibility that most of light emitted from a peripheral edge portion of an effective pixel region RE1 of the display device 101 is not incident on the imaging lens 21. Therefore, depending on the application of the display device 101, it may be required to condense emitted light from the light-emitting element 12W. In the second embodiment, a display device capable of condensing the emitted light from the light-emitting element 12W toward an optical axis 20Ax will be described.

### Configuration of Optical System 20

FIG. 60 is a schematic diagram of the optical system 20. The optical system 20 includes the display device 102 and the imaging lens 21 according to the second embodiment. The display device 102 is provided to face the imaging lens 21. The optical system 20 has an optical axis 20Ax that passes through the center of the effective pixel region RE1 of the display device 102 and is perpendicular to the display surface of the display device 102. Here, the center of the effective pixel region RE1 represents the geometric center of the effective pixel region RE1 in plan view. The display device 102 according to the second embodiment can condense the emitted light from the light-emitting element 12W toward the optical axis 20Ax of the optical system 20.

### Configuration of Display Device 102

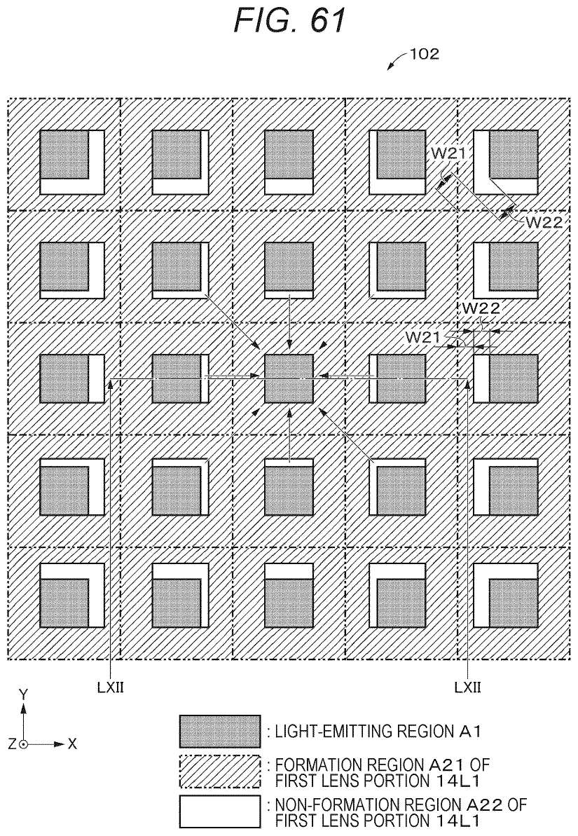

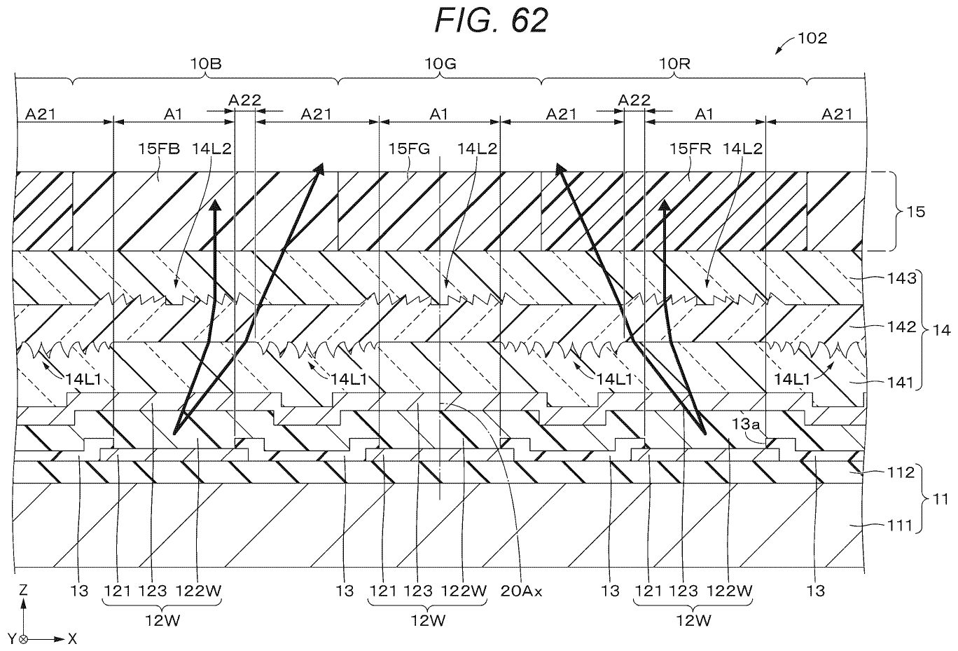

FIG. 61 is an enlarged plan view illustrating a part of the effective pixel region RE1 of the display device 102 according to a second embodiment. FIG. 62 is a cross-sectional view taken along line LXII-LXII of FIG. 61. Each subpixel 10 has a light-emitting region A1, a formation region A21 of a first lens portion 14L1, and a non-formation region A22 of the first lens portion 14L1 in the in-plane direction.

The light-emitting region A1 is located at the central portion of the subpixel 10 in plan view. The light-emitting region A1 is a region where the first electrode 121 and the second electrode 123 face each other with the OLED layer 122W interposed therebetween, and corresponds to a formation region of the opening 13a of the insulating layer 13.

The formation region A21 of the first lens portion 14L1 is a region where the first lens portion 14L1 is formed on the second surface of the second layer 142. The formation region A21 of the first lens portion 14L1 is located in a peripheral portion of the subpixel 10 in plan view. The non-formation region A22 of the first lens portion 14L1 is a region located between the light-emitting region A1 and the formation region A21 of the first lens portion 14L1 in a plan view in a region where the first lens portion 14L1 is not formed on the second surface.

In the display device 101 according to the first embodiment, a width W21 of a portion located on the center side of the effective pixel region RE1 in the formation region A21 of the first lens portion 14L1 is constant without changing from the center toward an outer periphery of the effective pixel region RE1. On the other hand, in the display device 102 according to the second embodiment, as illustrated in FIGS. 61 and 62, the width W21 of the portion located on the center side of the effective pixel region RE1 in the formation region A21 of the first lens portion 14L1 becomes narrower from the center toward the outer periphery of the effective pixel region RE1. Thus, a width W22 of the non-formation region A22 of the first lens portion 14L1 becomes wider from the center toward the outer periphery of the effective pixel region RE1. Therefore, as the subpixel 10 is farther from the center of the effective pixel region RE1, the light emitted from the light-emitting element 12W to a wider angle side is more likely to be extracted via the non-formation region A22 of the first lens portion 14L1 (see arrows in FIGS. 61 and 62). Thus, the emitted light from the light-emitting element 12W is condensed toward the optical axis 20Ax of the optical system 20.

As illustrated in FIG. 61, the width W21 of the formation region A21 of the first lens portion 14L1 may change for each subpixel 10 from the center to the outer periphery of the effective pixel region RE1. However, the change in the width W21 is not limited to this example, and for example, the width W21 may change for every predetermined number of subpixels 10 from the center toward the outer periphery of the effective pixel region RE1. More specifically, for example, the effective pixel region RE1 may have a plurality of regions in order from the center to the outer periphery of the effective pixel region RE1, and the width W21 may change for each of these regions.

The plurality of subpixels 10 provided in the effective pixel region RE1 includes a subpixel 10 in which the center of the filter portion 15F is shifted in a direction from the outer periphery of the effective pixel region RE1 toward the center with reference to a center Pl of the light-emitting region. The shift amount of the center of the filter portion 15F with respect to the center of the light-emitting region A1 of the subpixel 10 increases from the center of the effective pixel region RE1 toward the outer periphery. Thus, the light condensed toward the optical axis 20Ax of the optical system 20 is easily transmitted through the filter portion 15F. The shift amount of the center of the filter portion 15F with reference to the center of the light-emitting region A1 of the subpixel 10 preferably increases as the width W21 of the formation region A21 of the first lens portion 14L1 decreases, that is, as the width W22 of the non-formation region A22 of the first lens portion 14L1 increases.

Herein, unless otherwise specified, the center of the light-emitting region, the center of the formation region A21 of the first lens portion 14L1, the center of the formation region A31 of the second lens portion 14L2, and the center of the filter portion 15F respectively represent the geometric center of the light-emitting region in plan view, the geometric center of the formation region A21 of the first lens portion 14L1 in plan view, the geometric center of the formation region A31 of the second lens portion 14L2 in plan view, and the geometric center of the filter portion 15F in plan view.

### Operations and Effects

In the display device 102 according to the second embodiment, the width W21 of the portion located on the center side of the effective pixel region RE1 in the formation region A21 of the first lens portion 14L1 becomes narrower from the center toward the outer periphery of the effective pixel region RE1. Thus, the width W22 of the non-formation region A22 of the first lens portion 14L1 located between the light-emitting region A1 and the formation region A21 of the first lens portion 14L1 becomes wider from the center toward the outer periphery of the effective pixel region RE1. Therefore, light emitted from the light-emitting element 12W toward the center side of the effective pixel region RE1 is easily extracted via the non-formation region A22 of the first lens portion 14L1 (see arrows in FIGS. 61 and 62). Thus, as illustrated in FIG. 60, the emitted light from the light-emitting element 12W is condensed toward the optical axis 20Ax of the optical system 20. That is, the light emitted from the peripheral edge portion of the effective pixel region RE1 of the display device 101 is easily incident on the imaging lens 21.

### 3. Third Embodiment

In a third embodiment, as in the second embodiment, a display device 103 capable of condensing emitted light from a light-emitting element 12W toward an optical axis 20Ax will be described.

### Configuration of Display Device 103

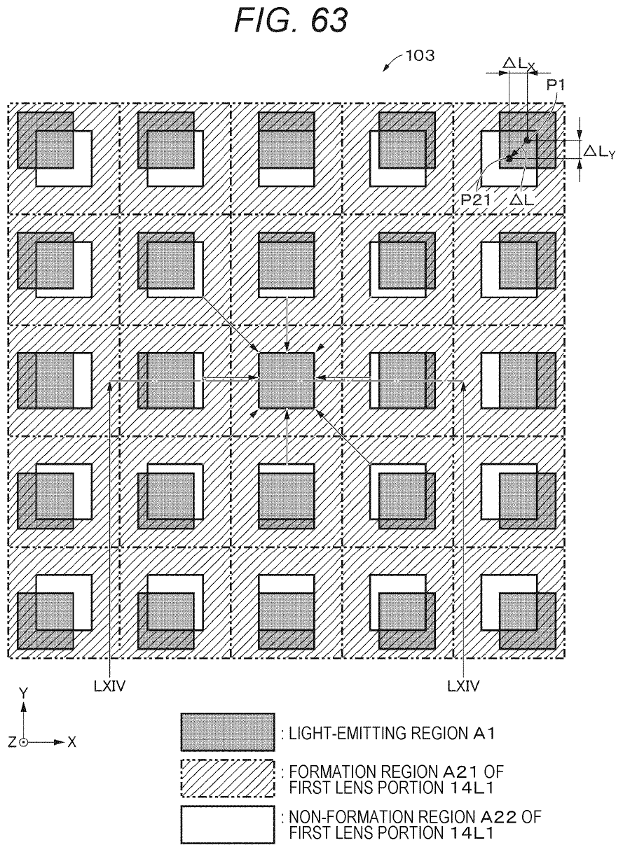

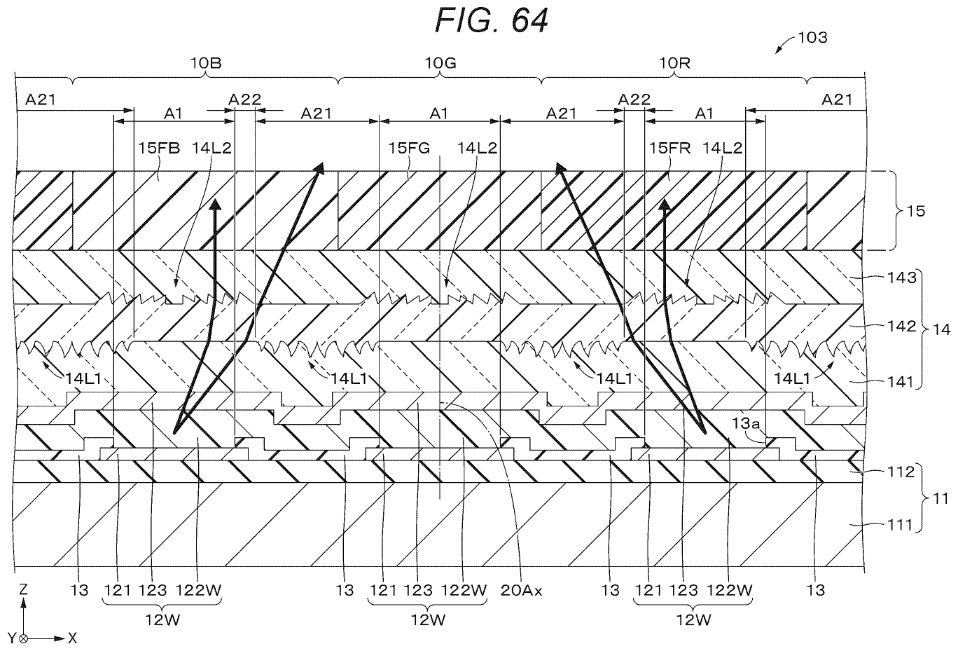

FIG. 63 is an enlarged plan view illustrating a part of an effective pixel region RE1 of the display device 103 according to the third embodiment. FIG. 64 is a cross-sectional view taken along line LXIV-LXIV in FIG. 63. In the display device 101 according to the first embodiment, the center P1 of the light-emitting region A1 of a subpixel 10 coincides with a center P21 of the formation region A21 of the first lens portion 14L1. On the other hand, in the display device 103 according to the third embodiment, the plurality of subpixels 10 provided in the effective pixel region RE1 includes the first lens portion 14L1 in which the center P21 of the formation region A21 of the first lens portion 14L1 is shifted in a direction from an outer periphery of the effective pixel region RE1 toward the center with reference to the center P1 of the light-emitting region A1 of the subpixel 10. The shift amount AL between the center P1 of the light-emitting region A1 of the subpixel 10 and the center P21 of the formation region A21 of the first lens portion 14L1 increases from the center of the effective pixel region RE1 toward the outer periphery. Thus, a width of a non-formation region A22 of the first lens portion 14L1 located between the light-emitting region A1 and the formation region A21 of the first lens portion 14L1 increases from the center toward the outer periphery of the effective pixel region RE1. Therefore, the emitted light from the light-emitting element 12W is condensed toward the optical axis 20Ax of the optical system 20 (see arrows in FIGS. 63 and 64). Note that, in FIG. 63, the shift amount ΔL_{X} represents a shift amount between the center P1 and the center P21 in the X-axis direction, and the shift amount ΔL_{Y} represents a shift amount between the center P1 and the center P21 in the Y-axis direction.

As illustrated in FIG. 63, the shift amount ΔL between the center P1 of the light-emitting region A1 of the subpixel 10 and the center P21 of the formation region A21 of the first lens portion 14L1 may change for each subpixel 10 from the center of the effective pixel region RE1 toward the outer periphery. However, the change in the shift amount ΔL is not limited to this example, and for example, the shift amount ΔL may change for every predetermined number of subpixels 10 from the center of the effective pixel region RE1 toward the outer periphery. More specifically, for example, the effective pixel region RE1 may have a plurality of regions in order from the center to the outer periphery of the effective pixel region RE1, and the shift amount ΔL may change for each of these regions.

In the third embodiment, it is preferable that the shift amount of the center of the filter portion 15F with reference to the center P1 of the light-emitting region A1 of the subpixel 10 increases as the shift amount ΔL between the center P1 of the light-emitting region A1 of the subpixel 10 and the center P21 of the formation region A21 of the first lens portion 14L1 increases. The arrangement of the filter portion 15F is similar to the arrangement of the filter portion 15F in the second embodiment in other points.

### Operations and Effects

In the display device 103 according to the third embodiment, the shift amount ΔL between the center P1 of the light-emitting region A1 of the subpixel 10 and the center P21 of the formation region A21 of the first lens portion 14L1 increases from the center of the effective pixel region RE1 toward the outer periphery. Thus, the width of the non-formation region A22 of the first lens portion 14L1 located between the light-emitting region A1 and the formation region A21 of the first lens portion 14L1 increases from the center toward the outer periphery of the effective pixel region RE1. Therefore, effects similar to those of the display device 102 according to the second embodiment can be achieved.

### 4. Fourth Embodiment

In a fourth embodiment, as in the second embodiment, a display device 104 capable of condensing emitted light from a light-emitting element 12W toward an optical axis 20Ax will be described.

### Configuration of Display Device 104

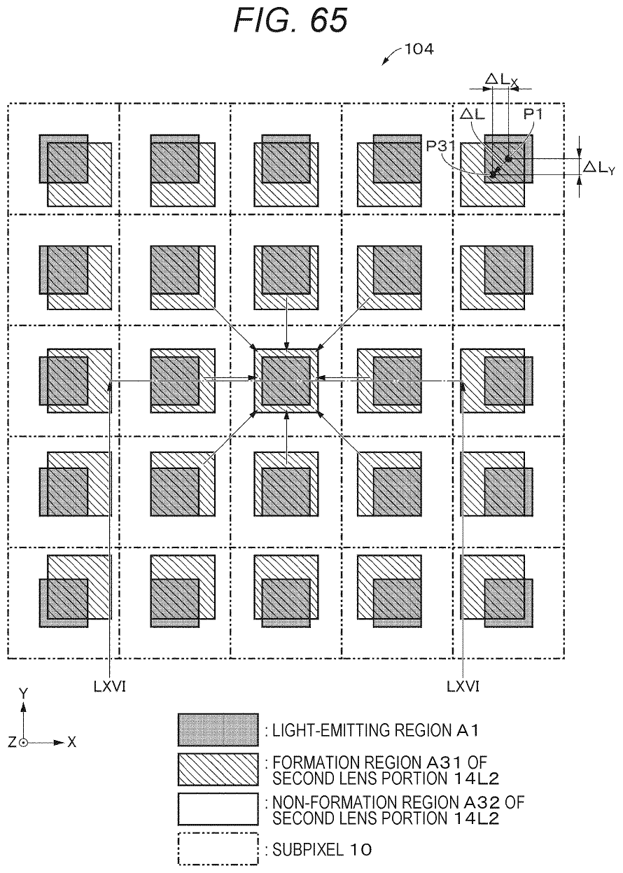

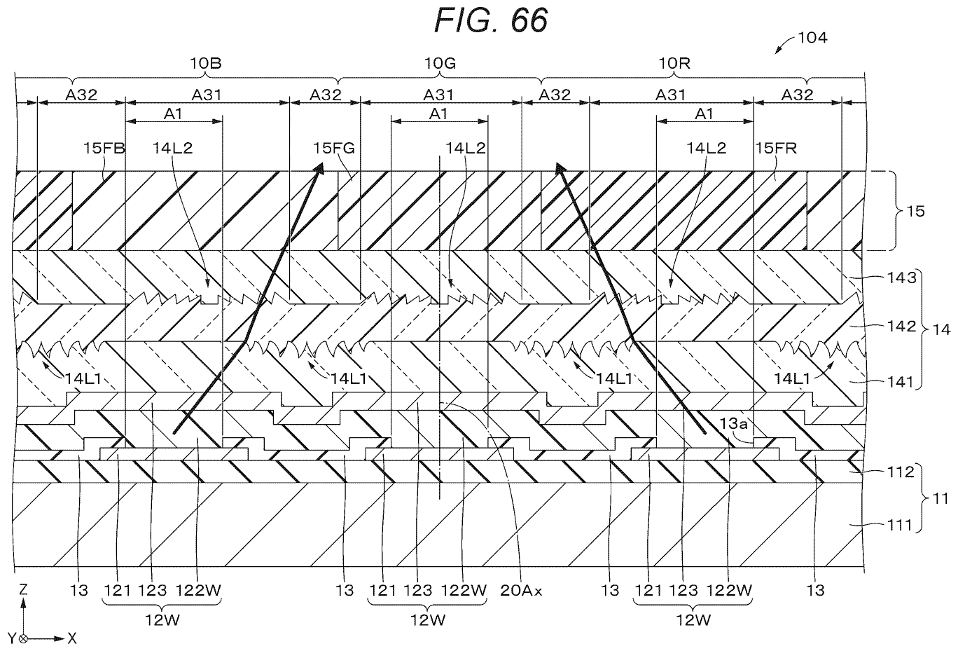

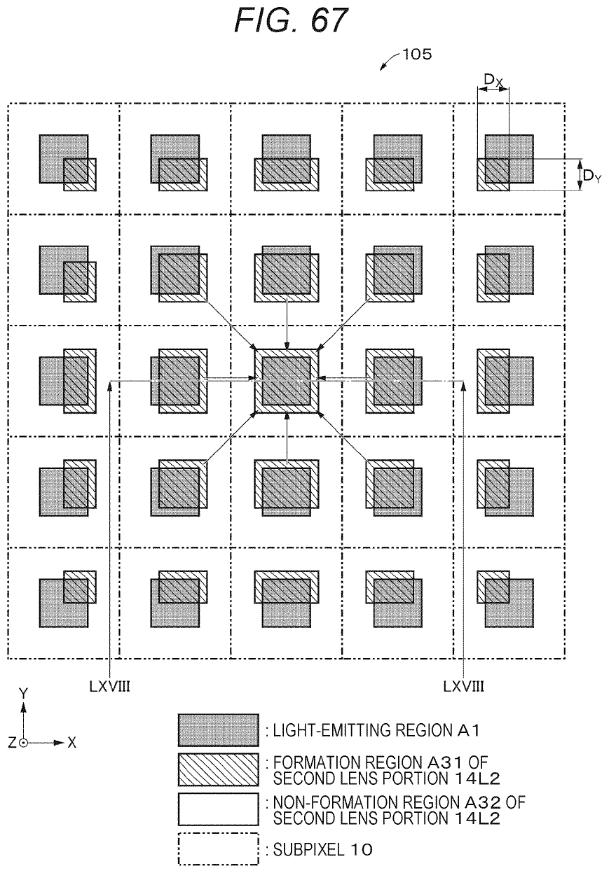

FIG. 65 is an enlarged plan view illustrating a part of an effective pixel region RE1 of the display device 104 according to the fourth embodiment. FIG. 66 is a cross-sectional view taken along line LXVI-LXVI in FIG. 65. As described in the second embodiment, the center of the filter portion 15F is shifted in a direction from an outer periphery of the effective pixel region RE1 toward the center with reference to a center P1 of a light-emitting region. Therefore, in a case where the position of the filter portion 15F is regarded as the position of the subpixel 10, as illustrated in FIG. 66, the center of the subpixel 10 is also shifted in a direction from the outer periphery of the effective pixel region RE1 toward the center with reference to the center P1 of the light-emitting region. However, in FIG. 65, in order to facilitate understanding of the positional relationship between the light-emitting region A1 of the subpixel 10 and a formation region A31 of a second lens portion 14L2, the subpixel 10 is illustrated without shifting the subpixel 10 as described above. Similarly, in FIGS. 67, 72, and 73, the subpixel 10 is illustrated without shifting the subpixel 10 as described above for the similar reason.

In the display device 101 according to the first embodiment, the center P1 of the light-emitting region A1 of the subpixel 10 coincides with a center P31 of the formation region A31 of the second lens portion 14L2. On the other hand, in the display device 102 according to the fourth embodiment, as illustrated in FIGS. 65 and 66, the plurality of subpixels 10 provided in the effective pixel region RE1 include a subpixel 10 in which the center P31 of the formation region A31 of the second lens portion 14L2 is shifted from the outer periphery of the effective pixel region RE1 toward the center with reference to the center P1 of the light-emitting region A1 of the subpixel 10. A shift amount ΔL of the center P31 of the formation region A31 of the second lens portion 14L2 with reference to the center P1 of the light-emitting region A1 of the subpixel 10 increases from the center of the effective pixel region RE1 toward the outer periphery. Thus, as the subpixel 10 is farther from the center of the effective pixel region RE1, the emitted light from the light-emitting element 12W is directed more inward of the effective pixel region RE1 (see arrows in FIGS. 65 and 66). Therefore, the emitted light from the light-emitting element 12W is condensed toward the optical axis 20Ax of the optical system 20.

As illustrated in FIG. 65, the shift amount ΔL between the center P1 of the light-emitting region A1 of the subpixel 10 and the center P31 of the formation region A31 of the second lens portion 14L2 may change for each subpixel 10 from the center of the effective pixel region RE1 toward the outer periphery. However, the change in the shift amount ΔL is not limited to this example, and for example, the shift amount ΔL may change for every predetermined number of subpixels 10 from the center of the effective pixel region RE1 toward the outer periphery. More specifically, for example, the effective pixel region RE1 may have a plurality of regions in order from the center to the outer periphery of the effective pixel region RE1, and the shift amount ΔL may change for each of these regions.

In the fourth embodiment, it is preferable that the shift amount of the center of the filter portion 15F with reference to the center P1 of the light-emitting region A1 of the subpixel 10 increases according to an increase in the shift amount ΔL between the center P1 of the light-emitting region A1 of the subpixel 10 and the center P31 of the formation region A31 of the second lens portion 14L2. The arrangement of the filter portion 15F is similar to the arrangement of the filter portion 15F in the second embodiment in other points.

### Operations and Effects

In the display device 104 according to the fourth embodiment, the shift amount ΔL of the center P31 of the formation region A31 of the second lens portion 14L2 with reference to the center P1 of the light-emitting region A1 of the subpixel 10 increases from the center toward the outer periphery of the effective pixel region RE1. Thus, as the subpixel 10 is farther from the center of the effective pixel region RE1, the emitted light from the light-emitting element 12W is directed more inward of the effective pixel region RE1. Therefore, the emitted light from the light-emitting element 12W is condensed toward the optical axis 20Ax of the optical system 20.

### 5. Fifth Embodiment

In a fifth embodiment, as in the second embodiment, a display device 105 capable of condensing emitted light from a light-emitting element 12W toward an optical axis 20Ax will be described.

### Configuration of Display Device 105

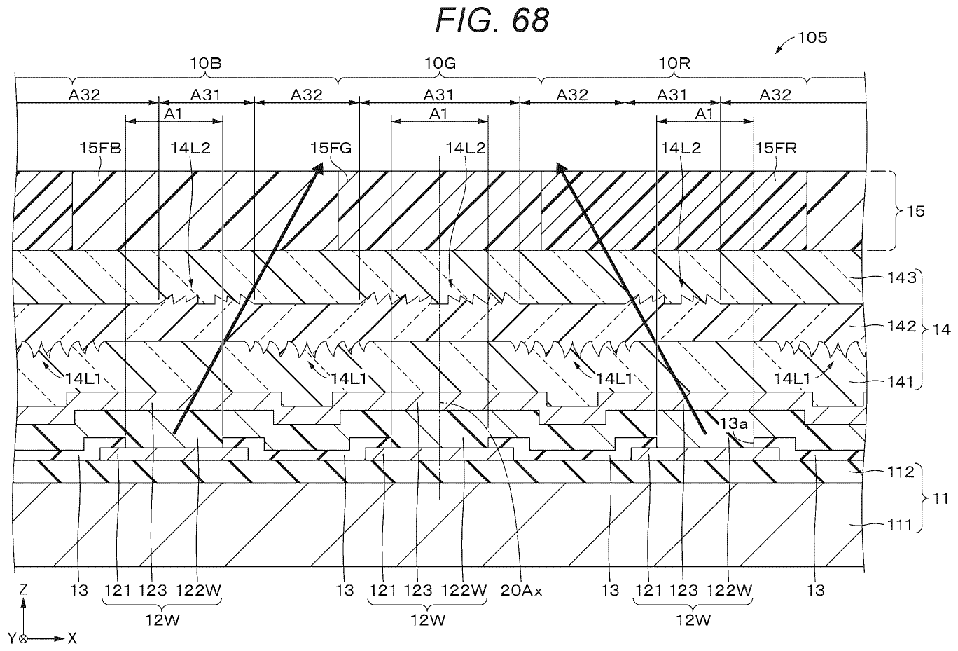

FIG. 67 is an enlarged plan view illustrating a part of an effective pixel region RE1 of the display device 105 according to the fifth embodiment. FIG. 68 is a cross-sectional view taken along line LXVIII-LXVIII in FIG. 67. In the display device 101 according to the first embodiment, widths D_{X} and D_{Y} of a formation region A31 of a second lens portion 14L2 are constant without changing from the center toward an outer periphery of the effective pixel region RE1. On the other hand, in the display device 105 according to the fifth embodiment, as illustrated in FIG. 67, the width Dx of the formation region A31 of the second lens portion 14L2 becomes narrower with increasing distance from the center of the effective pixel region RE1 in the X-axis direction. Then, as the width D_{X} decreases in the X-axis direction, the center of the formation region A31 of the second lens portion 14L2 is shifted in a direction from the outer periphery of the effective pixel region RE1 toward the center in the X-axis direction with reference to the center of the light-emitting region A1 of the subpixel 10. Furthermore, as illustrated in FIG. 67, the width D_{Y} of the formation region A31 of the second lens portion 14L2 becomes narrower with increasing distance from the center of the effective pixel region RE1 in the Y-axis direction. Then, as the width D_{Y} is narrowed in the Y-axis direction, the center of the formation region A31 of the second lens portion 14L2 is shifted from the outer periphery of the effective pixel region RE1 toward the center in the Y-axis direction with reference to the center of the light-emitting region A1 of the subpixel 10. Thus, as the subpixel 10 is farther from the center of the effective pixel region RE1, the emitted light from the light-emitting element 12W is directed more inward of the effective pixel region RE1 (see arrows in FIGS. 67 and 68). Therefore, the emitted light from the light-emitting element 12W is condensed toward the optical axis 20Ax of the optical system 20. Note that the width D_{X} represents the width of the formation region A31 of the second lens portion 14L2 in the X-axis direction, and the width D_{Y} represents the width of the formation region A31 of the second lens portion 14L2 in the Y-axis direction.

The widths D_{X} and D_{Y} of the formation region A31 of the second lens portion 14L2 and a shift amount between the center of the light-emitting region A1 of the subpixel 10 and the center of the formation region A31 of the second lens portion 14L2 may change for each subpixel 10 from the center of the effective pixel region RE1 toward the outer periphery as illustrated in FIG. 67. However, the changes in the widths D_{X} and D_{Y} and the shift amount are not limited to this example, and for example, the widths D_{X} and D_{Y} and the shift amount may change for every predetermined number of subpixels 10 from the center to the outer periphery of the effective pixel region RE1. More specifically, for example, the effective pixel region RE1 may have a plurality of regions in order from the center to the outer periphery of the effective pixel region RE1, and the widths D_{X} and D_{Y} and the shift amount may change for each of these regions.

In the fifth embodiment, it is preferable that the shift amount of the center of the filter portion 15F in the X-axis direction with reference to the center of the light-emitting region A1 of the subpixel 10 increases as the width D_{X} of the formation region A31 of the second lens portion 14L2 decreases. Furthermore, the shift amount of the center of the filter portion 15F in the Y-axis direction with reference to the center of the light-emitting region A1 of the subpixel 10 is preferably increased as the width D_{Y} of the formation region A31 of the second lens portion 14L2 decreases. The arrangement of the filter portion 15F is similar to the arrangement of the filter portion 15F in the second embodiment in other points.

### Operations and Effects

In the display device 105 according to the fifth embodiment, the width D_{X} of the formation region A31 of the second lens portion 14L2 becomes narrower with increasing distance from the center of the effective pixel region RE1 in the X-axis direction. Then, as the width D_{X} decreases in the X-axis direction, the center of the formation region A31 of the second lens portion 14L2 is shifted in a direction from the outer periphery of the effective pixel region RE1 toward the center in the X-axis direction with reference to the center of the light-emitting region A1 of the subpixel 10. Further, the width D_{Y} of the formation region A31 of the second lens portion 14L2 becomes narrower with increasing distance from the center of the effective pixel region RE1 in the Y-axis direction. Then, as the width D_{Y} is narrowed in the Y-axis direction, the center of the formation region A31 of the second lens portion 14L2 is shifted from the outer periphery of the effective pixel region RE1 toward the center in the Y-axis direction with reference to the center of the light-emitting region A1 of the subpixel 10. Thus, as the subpixel 10 is farther from the center of the effective pixel region RE1, the emitted light from the light-emitting element 12W is directed more inward of the effective pixel region RE1. Therefore, the emitted light from the light-emitting element 12W is condensed toward the optical axis 20Ax of the optical system 20.

### 7. Modifications

### Modification 1

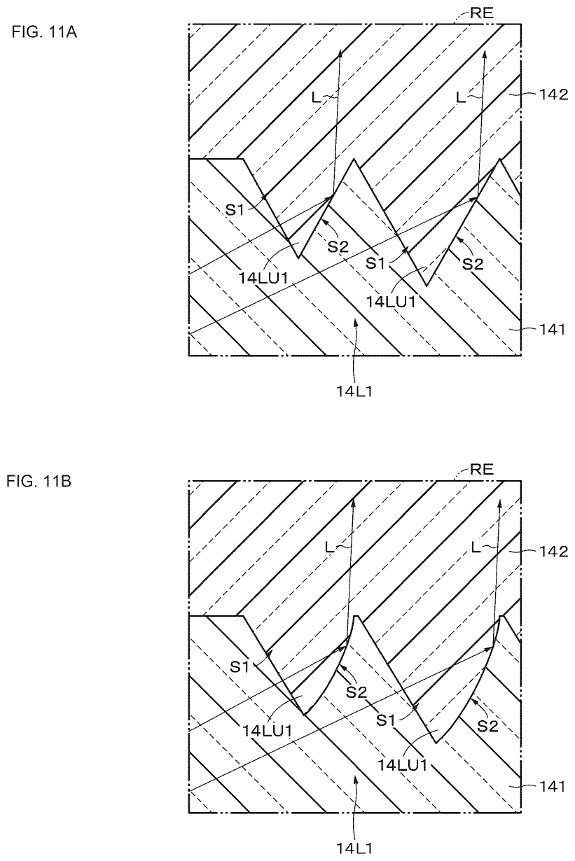

In the first embodiment, an example in which the cross-sectional shape of the first surface S1 is a concave curved line shape and the cross-sectional shape of the second surface S2 is a convex curved line shape (see FIG. 4) has been described, but the shapes of the first surface S1 and the second surface S2 of the first protrusion 14LU1 are not limited to this example. For example, as illustrated in FIG. 11A, the cross-sectional shape of the first surface S1 may be linear, and the cross-sectional shape of the second surface S2 may be linear. Alternatively, as illustrated in FIG. 11B, the cross-sectional shape of the first surface S1 may be a linear shape, and the cross-sectional shape of the second surface S2 may be a convex curved linear shape.

In a case where the cross-sectional shape of the first surface S1 is linear, the linear shape may be oblique to the optical axis 12L of the light-emitting element 12W. In a case where the cross-sectional shape of the second surface S2 is linear, the linear shape may be oblique to the optical axis 12L of the light-emitting element 12W or parallel to the optical axis 12L of the light-emitting element 12W.

### Modification 2

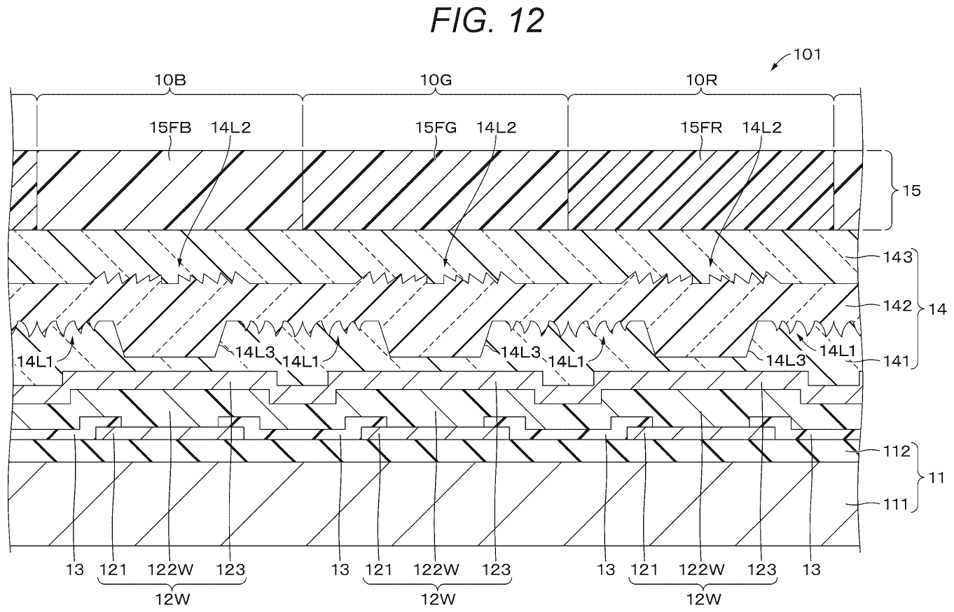

In the first embodiment, the example (see FIG. 4) in which the second layer 142 includes the plurality of first lens portions 14L1 and the plurality of second lens portions 14L2 has been described, but as illustrated in FIG. 12, the second layer 142 may further include a plurality of third lens portions 14L3. The third lens portion 14L3 is provided on the first surface (surface on the first layer 141 side) of the second layer 142, and each third lens portion 14L3 is located at the central portion of the subpixel 10 in plan view. The third lens portion 14L3 can condense light emitted from the light-emitting element 12W at a low angle. The first lens portion 14L1 is a convex lens. The convex lens has, for example, a frustum shape. The frustum shape may be, for example, a polygonal frustum shape, a truncated cone shape, or an elliptical frustum shape, or may be a frustum shape other than these.

In the display device 101 according to Modification 2, since the second layer 142 further includes the plurality of third lens portions 14L3, the luminous efficiency can be further improved, and color mixing can be further suppressed.

### Modification 3

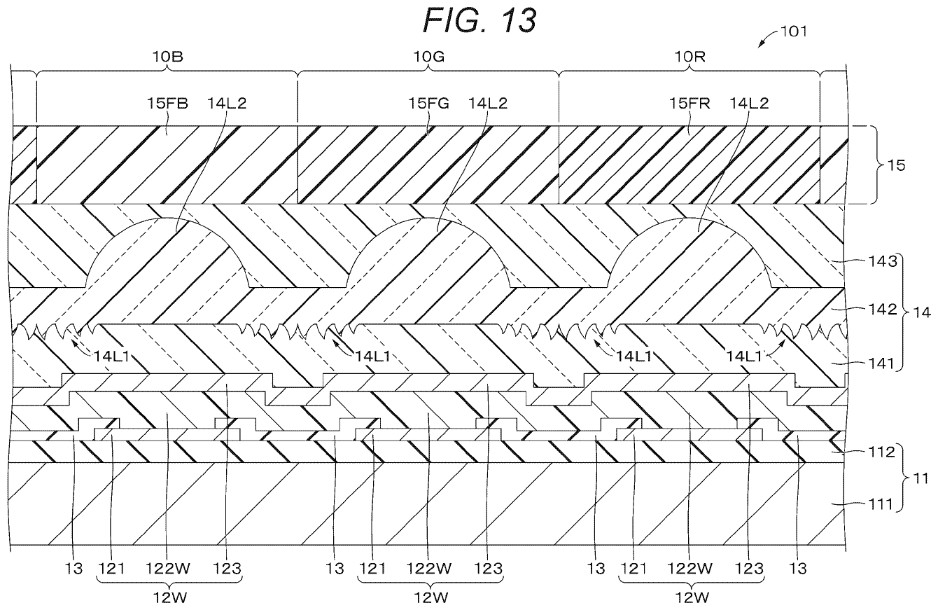

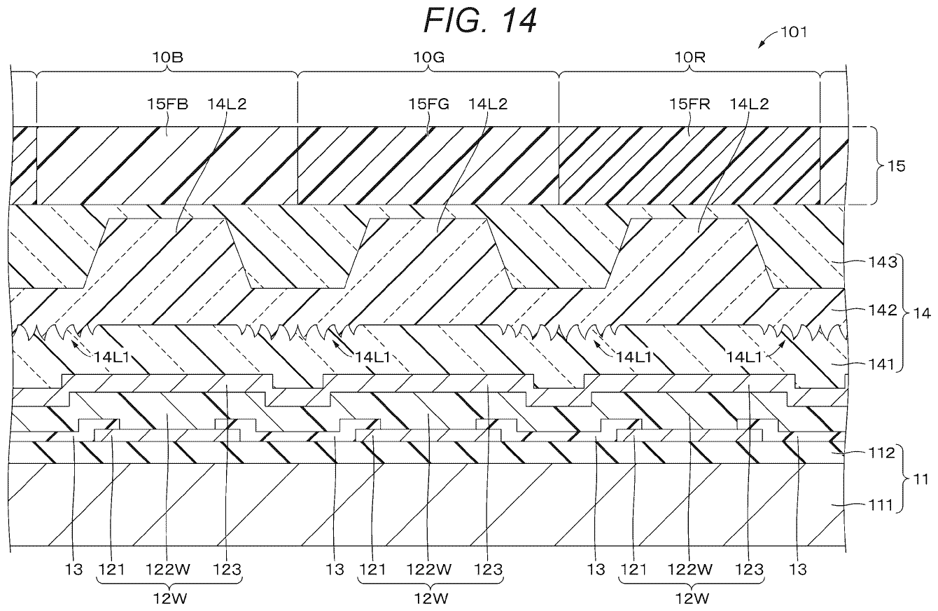

In the first embodiment, the example in which the second lens portion 14L2 is a Fresnel lens array (see FIG. 3) has been described, but the second lens portion 14L2 is not limited to this example. For example, the second lens portion 14L2 may be a spherical lens such as a hemispherical lens as illustrated in FIG. 13, or may be a frustum lens as illustrated in FIG. 14. The frustum shape may be, for example, a polygonal frustum shape, a truncated cone shape, or an elliptical frustum shape, or may be a frustum shape other than these.

### Modification 4

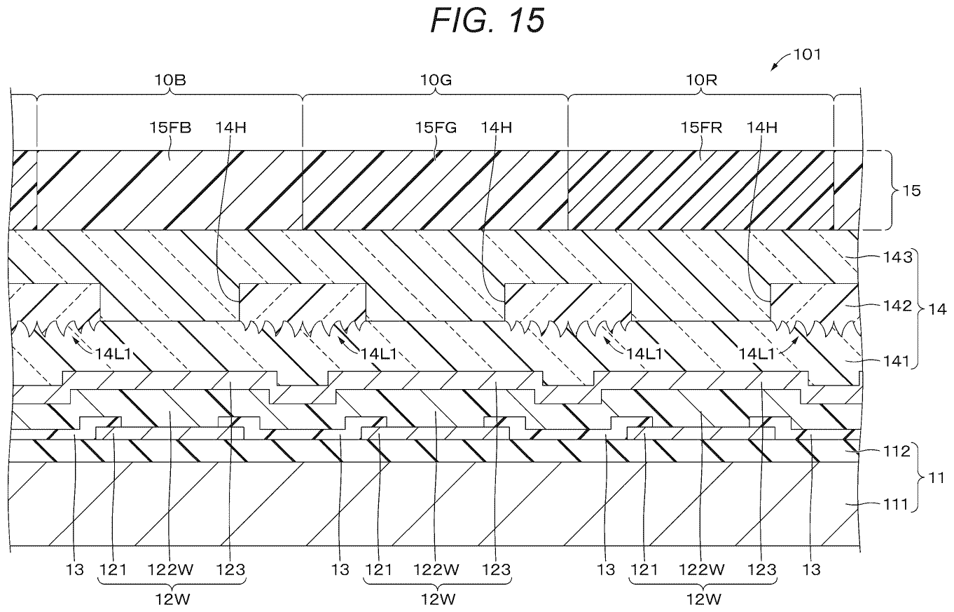

In the first embodiment, the example in which the second layer 142 includes the plurality of second lens portions 14L2 (see FIG. 3) has been described, but as illustrated in FIG. 15, the second layer 142 may include a plurality of through holes 14H instead of the plurality of second lens portions 14L2. The through holes 14H penetrate between the first surface and the second surface. The through holes 14H may be filled with materials similar to those of the third layer 143. The through holes 14H are each located at the central portion of the subpixel 10 in plan view. The through holes 14H can transmit light emitted from each light-emitting element 12W at a low angle.

Since the second layer 142 has the plurality of through holes 14H, it is possible to suppress interface reflection of light emitted from each light-emitting element 12W at a low angle at the interface between the first layer 141 and the second layer 142 and the interface between the second layer 142 and the third layer 143. From the viewpoint of suppressing interface reflection, the refractive index of the material in the through hole 14H is preferably substantially the same as the refractive index of the first layer 141 and the second layer 142.

### Modification 5

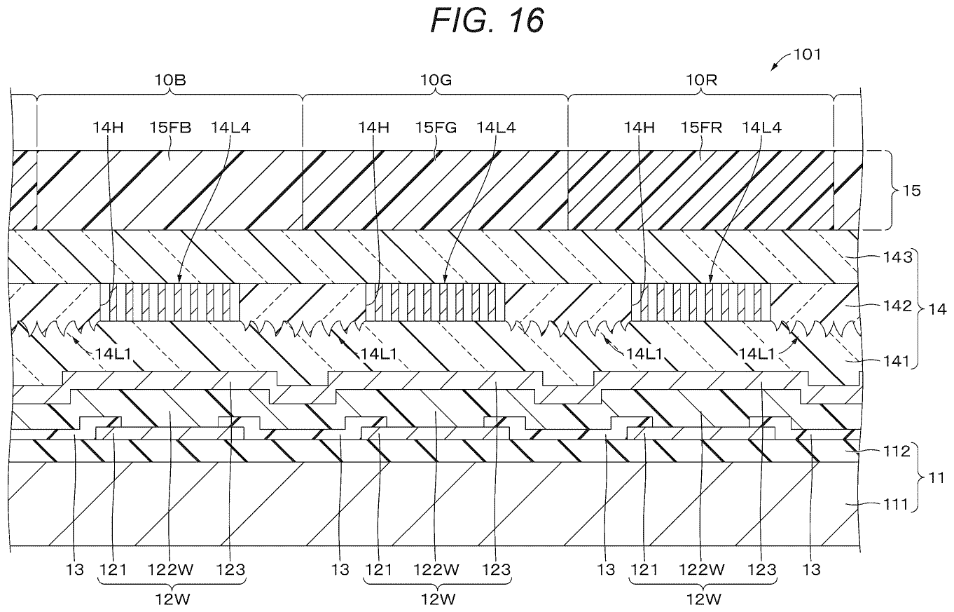

In the first embodiment, the example in which the second layer 142 includes the plurality of second lens portions 14L2 (see FIG. 3) has been described, but as illustrated in FIG. 16, the second layer 142 may include a plurality of fine periodic structures 14L4 instead of the plurality of second lens portions 14L2. Alternatively, the second layer 142 may include both the plurality of second lens portions 14L2 and the plurality of fine periodic structures 14L4.

Each of the fine periodic structures 14L4 is located at the central portion of the subpixel 10 in plan view. As illustrated in FIG. 16, the second layer 142 may have a plurality of through holes 14H, and each of the fine periodic structures 14L4 may be provided in the through hole 14H. However, the arrangement form of the plurality of fine periodic structures 14L4 is not limited to this example, and for example, the plurality of fine periodic structures 14L4 may be provided on the first surface of the second layer 142 or the second surface of the second layer 142. Alternatively, the plurality of fine periodic structures 14L4 may be provided in at least one of the through hole 14H, the first surface of the second layer 142, and the second surface of the second layer 142.

The fine periodic structure 14L4 can condense the light emitted from each light-emitting element 12W at a low angle, bring the light close to parallel light, and emit the light. The fine periodic structure 14L4 includes, for example, metamaterial. The metamaterial includes a plurality of nanostructures (meta-atoms) 151 having sizes that are equal to or less than the wavelength of light. Here, the light may be light emitted from the light-emitting element 12W. The metamaterial may be a two-dimensional metamaterial (meta-surface) or a three-dimensional metamaterial, or may be a combination of a two-dimensional metamaterial and a three-dimensional metamaterial.

### Modification 6

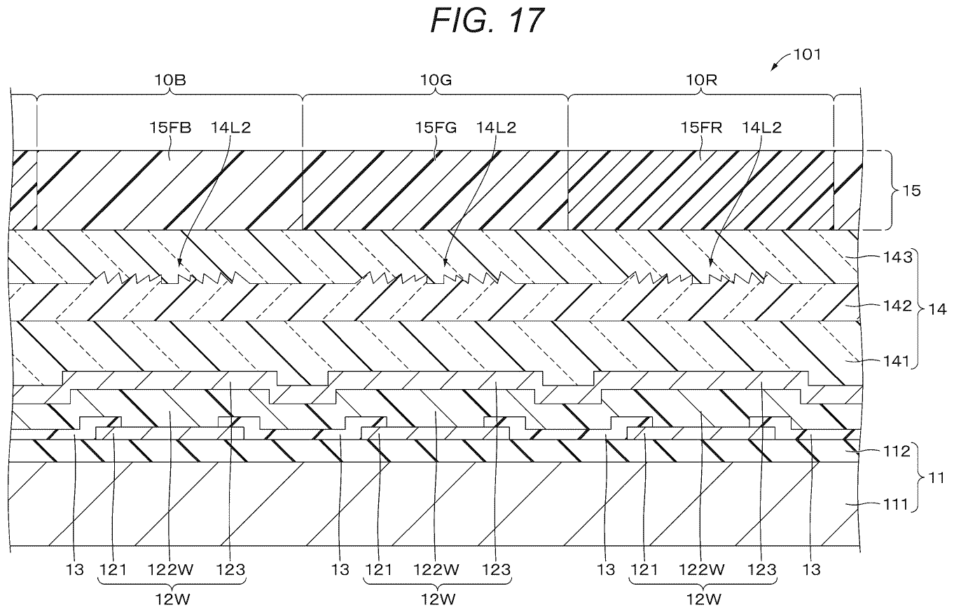

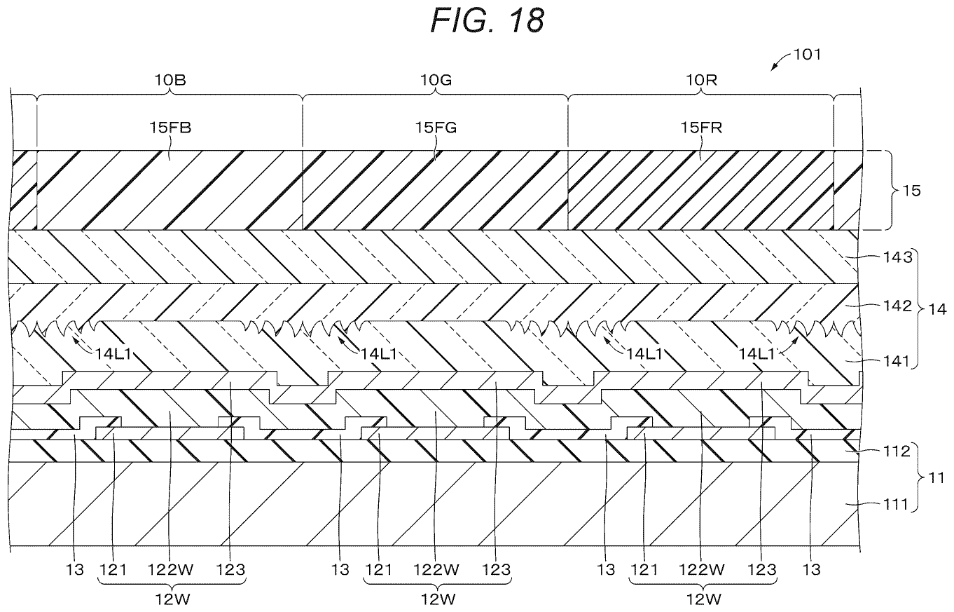

In the first embodiment, the example (see FIG. 3) in which the second layer 142 includes the plurality of first lens portions 14L1 and the plurality of second lens portions 14L2 has been described, but as illustrated in FIG. 17, the second layer 142 may include only the plurality of second lens portions 14L2, or as illustrated in FIG. 18, the second layer 142 may include only the plurality of first lens portions 14L1.

In a case where the second layer 142 includes only the plurality of second lens portions 14L2, the multilayer body 14 need not include the first layer 141, and the first refractive index n₁ of the first layer 141 and the second refractive index n₂ of the second layer 142 may be substantially the same. In a case where the second layer 142 includes only the plurality of first lens portions 14L1, the multilayer body 14 need not include the third layer 143, and the second refractive index n₂ of the second layer 142 and the third refractive index n₃ of the third layer 143 may be substantially the same.

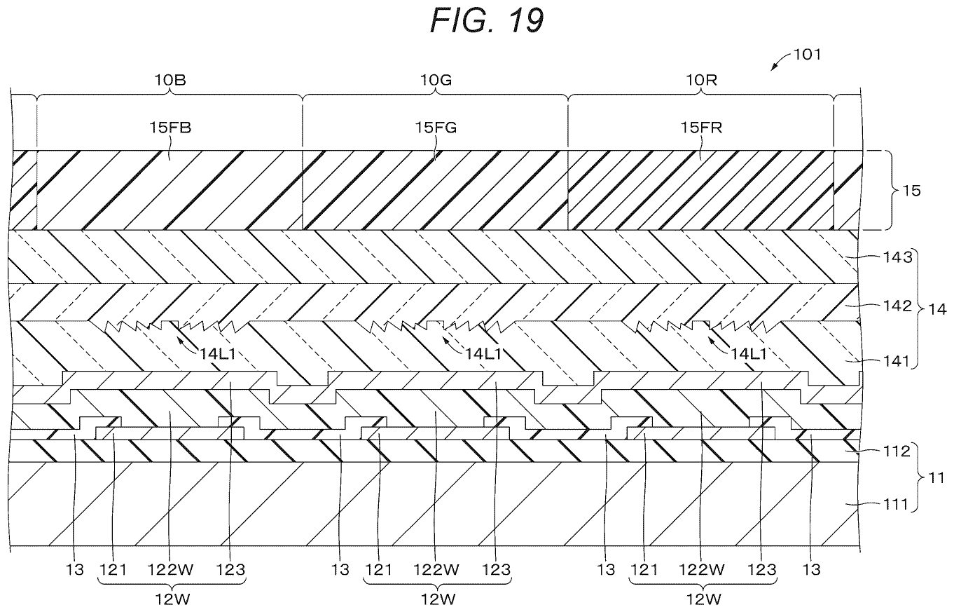

In a case where the second layer 142 includes only the plurality of first lens portions 14L1, as illustrated in FIG. 19, each of the first lens portions 14L1 may be located at the central portion of the subpixel 10 in plan view. In this case, the first lens portion 14L1 may be able to condense light emitted from each light-emitting element 12W at a low angle, bring the light close to parallel light, and emit the light. The first lens portion 14L1 having such a function may be a Fresnel lens array.

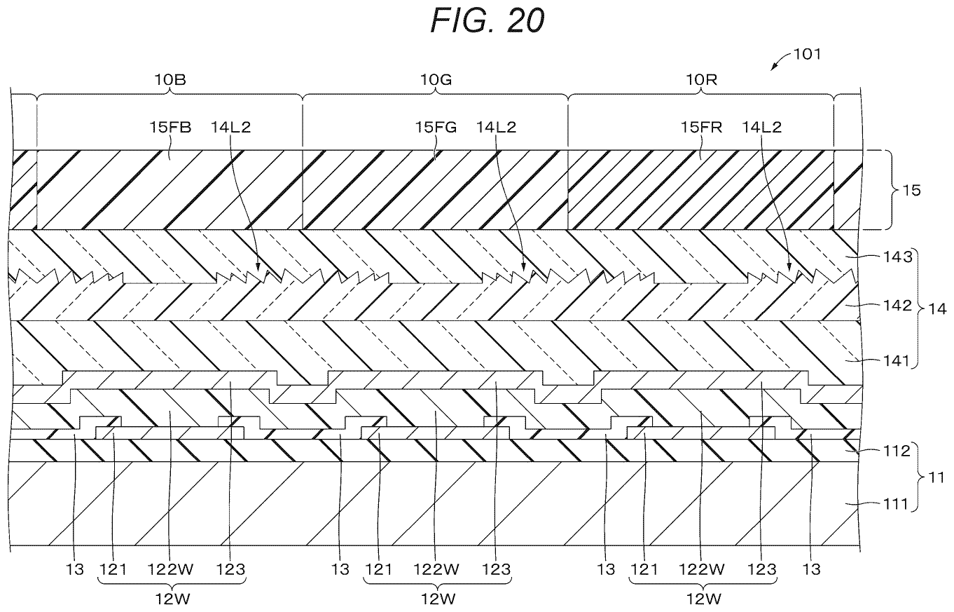

In a case where the second layer 142 includes only the plurality of second lens portions 14L2, as illustrated in FIG. 20, each of the second lens portions 14L2 may be located in a peripheral portion of the subpixel 10 in plan view.

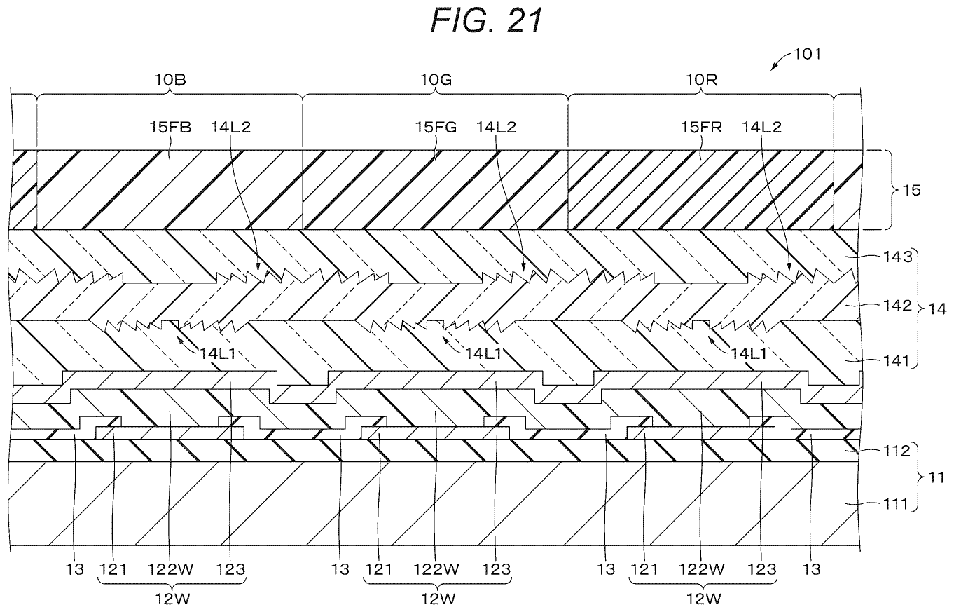

In the first embodiment, an example in which the first lens portion 14L1 is provided in the peripheral portion of the subpixel 10 in plan view and the second lens portion 14L2 is provided in the central portion of the subpixel 10 in plan view (see FIG. 3) has been described, but the arrangement form of the first lens portion 14L1 and the second lens portion 14L2 is not limited to this example. For example, as illustrated in FIG. 21, the first lens portion 14L1 may be provided in the central portion of the subpixel 10 in plan view, and the second lens portion 14L2 may be provided in the peripheral portion of the subpixel 10 in plan view. In this case, the first lens portion 14L1 may be able to condense light emitted from each light-emitting element 12W at a low angle, bring the light close to parallel light, and emit the light. The first lens portion 14L1 having such a function may be a Fresnel lens array.

### Modification 7

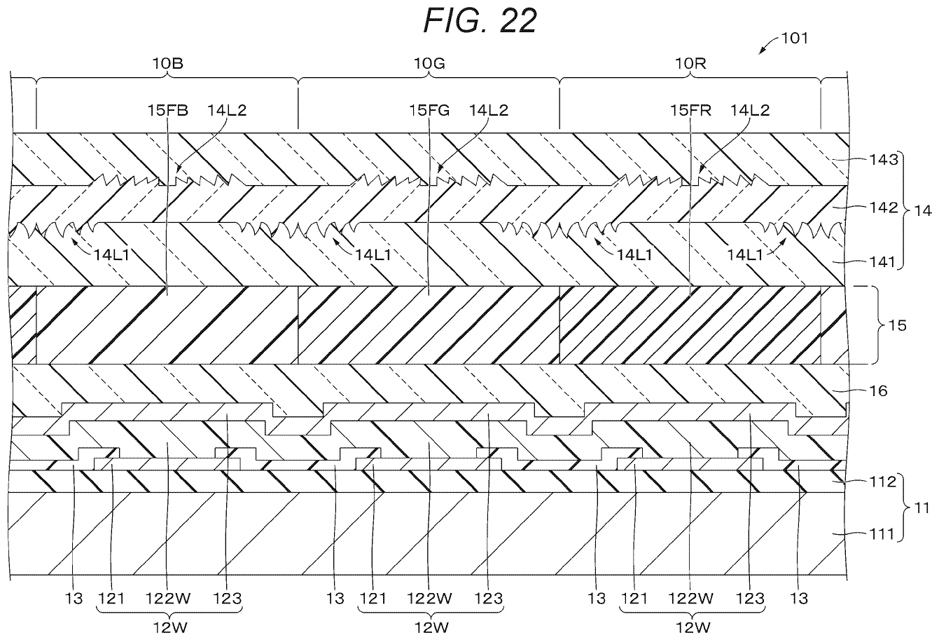

In the first embodiment described above, an example in which the color filter 15 is provided on the second surface of the multilayer body 14 (see FIG. 3) has been described, but as illustrated in FIG. 22, the multilayer body 14 may be provided on the second surface of the color filter 15. In this case, the display device 101 may further include the protective layer 16, and the protective layer 16 may be provided between the plurality of light-emitting elements 12W and the color filter 15.

The protective layer 16 includes, for example, a material with low hygroscopicity, such as an inorganic material or polymer resin. The protective layer 16 may have a single layer structure or a multilayer structure. In a case where the thickness of the protective layer 16 is increased, a multilayer structure is preferable. This is to alleviate internal stress in the protective layer 16. As the inorganic material, an inorganic material similar to that of the first layer 141 can be exemplified. As the polymer resin, a polymer resin similar to that of the first layer 141 can be exemplified.

### Modification 8

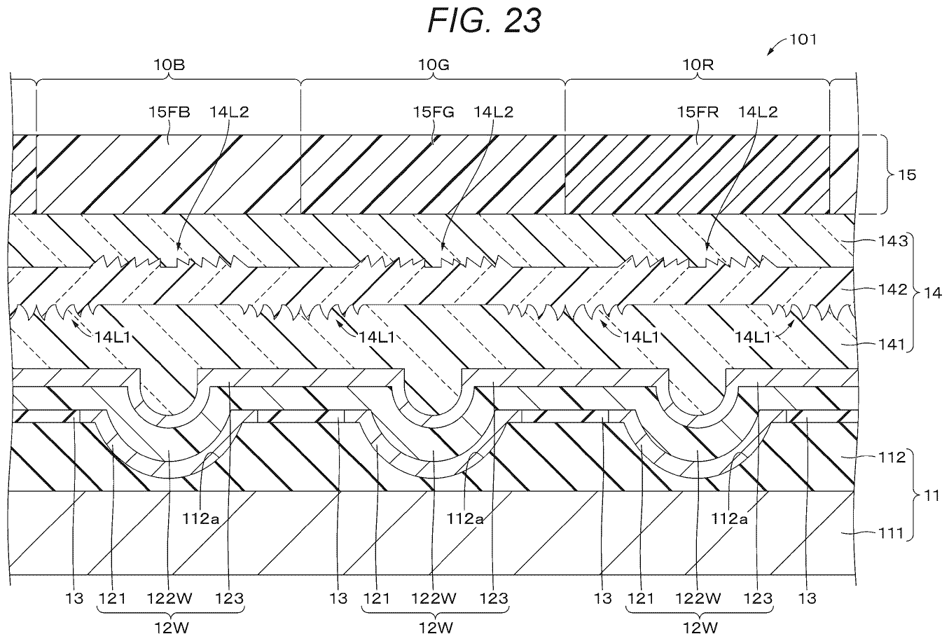

The second surface of the drive substrate 11 may be substantially flat, but as illustrated in FIG. 23, the second surface of the drive substrate 11 may have a plurality of concave portions 112a. The concave portions 112a have concave curved surfaces recessed in a direction away from the multilayer body 14. The curved surface is, for example, a substantially parabolic surface, a substantially hemispherical surface, a substantially semielliptical surface, or the like, but is not limited to these shapes. The plurality of concave portions 112a is provided at arrangement positions of the light-emitting elements 12W. The light-emitting elements 12W are provided along the curved surface of the concave portion 112a, and the light-emitting elements 12W each have a concave curved shape recessed in a direction away from the multilayer body 14. More specifically, the first electrode 121, the OLED layer 122W, and the second electrode 123 follow the curved surface of the concave portion 112a, and the first electrode 121, the OLED layer 122W, and the second electrode 123 have a concave curved shape recessed in a direction away from the multilayer body 14. A thickness of the OLED layer 122W is preferably substantially uniform from the viewpoint of suppressing characteristic defects such as color shift of the emission color.

Since the light-emitting element 12W follows the curved surface of the concave portion 112a as described above, the first electrode 121 included in the light-emitting element 12W is curved in a concave shape. Thus, since light emitted from the OLED layer 122W is reflected by the first electrodes 121, which are curved in a concave shape, toward the front direction, the luminous efficiency can be further improved.

### Modification 9

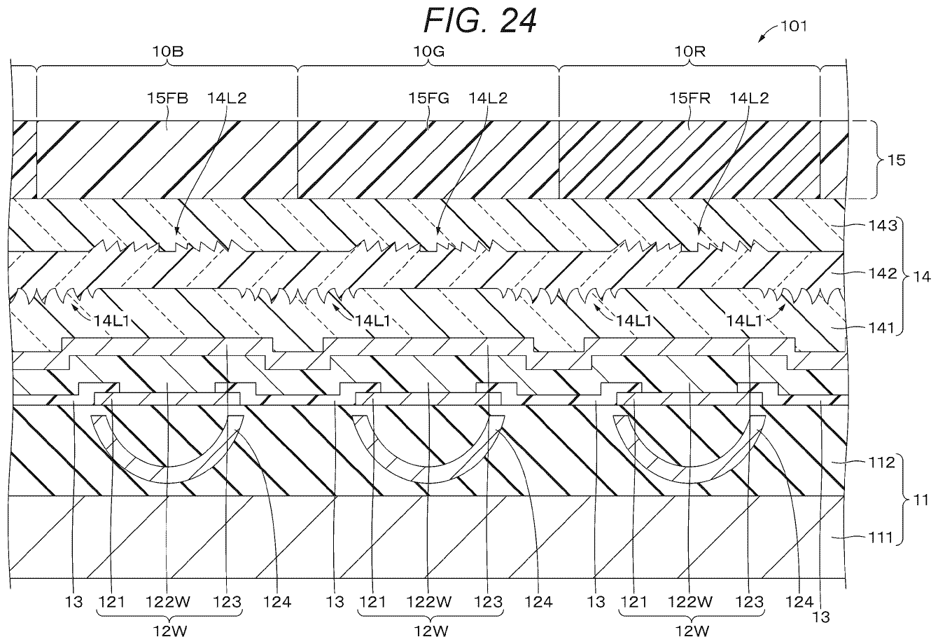

In Modification 8, an example in which the first electrode 121, the OLED layer 122W, and the second electrode 123 have a concave curved shape recessed in a direction away from the multilayer body 14 (see FIG. 23) has been described. However, the configuration of the display device 101 is not limited to this example. For example, as illustrated in FIG. 24, instead of the first electrode 121, the OLED layer 122W, and the second electrode 123 having a concave curved shape, a plurality of reflection layers 124 having a concave curved surface recessed in a direction away from the light-emitting element 12W may be provided.

A curved surface 44s of the reflection layer 124 is, for example, a substantially parabolic surface, a substantially hemispherical surface, a substantially semi-elliptical surface, or the like. As illustrated in FIG. 24, the reflection layer 124 itself may have a curved shape recessed in a direction away from the light-emitting element 12W. The plurality of reflection layers 124 is provided below the individual light-emitting element 12W. That is, the OLED layer 122W is provided above the reflection layer 124. Herein, the upper side represents a direction from the bottom side (the side opposite to the display surface) of the display device 101 toward the top side (the display surface side) of the display device 101. Furthermore, the downward direction represents a direction from the top side (display surface side) of the display device 101 toward the bottom side (side opposite to the display surface) of the display device 101.

The reflection layer 124 is constituted by, for example, a metal layer. As the material of the metal layer, a material similar to that of the metal layer of the first electrode 121 can be exemplified.

In the display device 101 according to Modification 9, the first electrode 121 has translucency to white light emitted from the OLED layer 122W. The first electrode 121 is preferably a transparent electrode transparent to visible light. The transparent electrode includes, for example, at least one of a metal layer or a transparent conductive oxide layer. As materials of the metal layer and the transparent conductive oxide layer, materials similar to those of the metal layer and the transparent conductive oxide layer in the second electrode 123 can be exemplified.

As described above, when the display device 101 includes the reflection layer 124 below each light-emitting element 12W, white light emitted from the OLED layer 122W is reflected toward the front direction by a curved surface of the reflection layer 124, so that the luminous efficiency can be further improved.

In the example described above, an example has been described in which the reflection layer 124 is divided between adjacent subpixels 10 and separately provided for the plurality of subpixels 10, but the reflection layer 124 may be connected between the adjacent subpixels 10.

### Modification 10

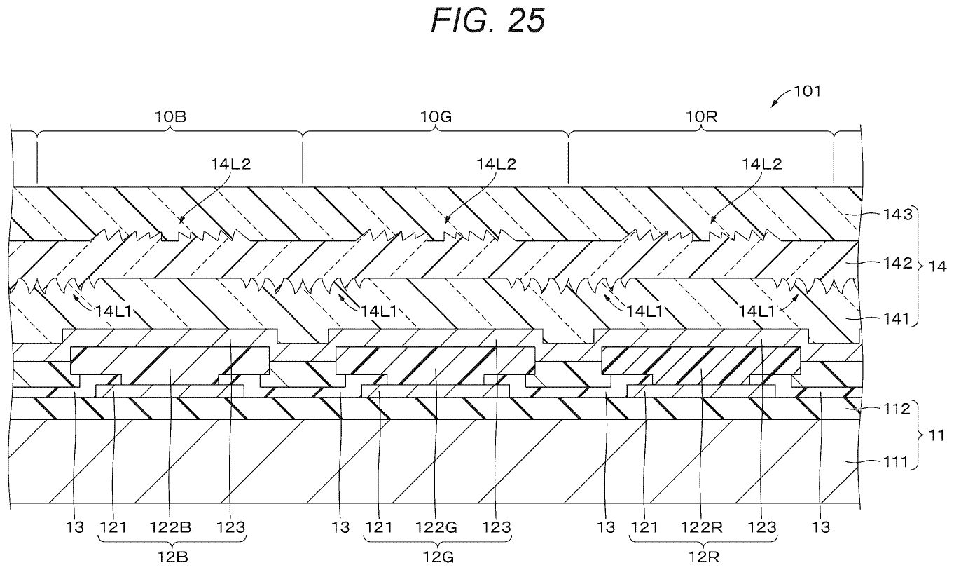

In the first embodiment described above, the example in which the display device 101 includes the plurality of light-emitting elements 12W capable of emitting white light and the color filter 15, and a color image can be displayed by the combination of the light-emitting elements 12W and the color filter 15 has been described, but the colorization method of the display device 101 is not limited to such an example. For example, as illustrated in FIG. 25, the display device 101 may include a plurality of light-emitting elements 12R capable of emitting red light, a plurality of light-emitting elements 12G capable of emitting green light, and a plurality of light-emitting elements 12B capable of emitting blue light, instead of the plurality of light-emitting elements 12W. In this case, the color filter 15 may or may not be provided. FIG. 25 illustrates an example in which the color filter 15 is not provided.

The light-emitting element 12R includes a first electrode 121, an OLED layer 122R, and a second electrode 123 in sequence on the second surface of the drive substrate 11. The light-emitting element 12G includes a first electrode 121, an OLED layer 122G, and a second electrode 123 in sequence on the second surface of the drive substrate 11. The light-emitting element 12B includes a first electrode 121, an OLED layer 122B, and a second electrode 123 in sequence on the second surface of the drive substrate 11.

The OLED layer 122R can emit red light. The OLED layer 122G can emit green light. The OLED layer 122B can emit blue light. The OLED layers 122R, 122G, and 122B are examples of the organic-containing layer in the claims.

The OLED layers 122R, 122G, and 122B are each provided between the first electrode 121 and the second electrode 123. The OLED layer 122R includes an organic light-emitting layer that can emit red light (hereinafter, referred to as “red organic light-emitting layer”). The OLED layer 122R includes an organic light-emitting layer that can emit green light (hereinafter, referred to as “green organic light-emitting layer”). The OLED layer 122B includes an organic light-emitting layer that can emit blue light (hereinafter, referred to as “blue organic light-emitting layer”). Furthermore, in the following description, the OLED layers 122R, 122G, and 122B may be collectively referred to as OLED layer 122 in a case where they are collectively referred to without being particularly distinguished. The red organic light-emitting layer, the green organic light-emitting layer, and the blue organic light-emitting layer may be collectively referred to as organic light-emitting layer in a case where they are collectively referred to without being particularly distinguished.

The OLED layers 122R, 122G, and 122B may each include a multilayer body including the corresponding organic light-emitting layer, and in this case, a part of the multilayer body (for example, an electron injection layer) may be an inorganic layer. The OLED layer 122R includes, for example, a hole injection layer, a hole transport layer, a red organic light-emitting layer, an electron transport layer, and an electron injection layer in sequence from the first electrode 121 to the second electrode 123. The OLED layer 122G includes, for example, a hole injection layer, a hole transport layer, a green organic light-emitting layer, an electron transport layer, and an electron injection layer in sequence from the first electrode 121 to the second electrode 123. The OLED layer 122G includes, for example, a hole injection layer, a hole transport layer, a blue organic light-emitting layer, an electron transport layer, and an electron injection layer in sequence from the first electrode 121 to the second electrode 123.

The red organic light-emitting layer can emit red light through recombination of holes injected from the first electrode 121 and electrons injected from the second electrode 123. The green organic light-emitting layer can emit green light through a phenomenon similar to the red organic light-emitting layer.

The blue organic light-emitting layer can emit blue light through a phenomenon similar to the red organic light-emitting layer.

### Modification 11

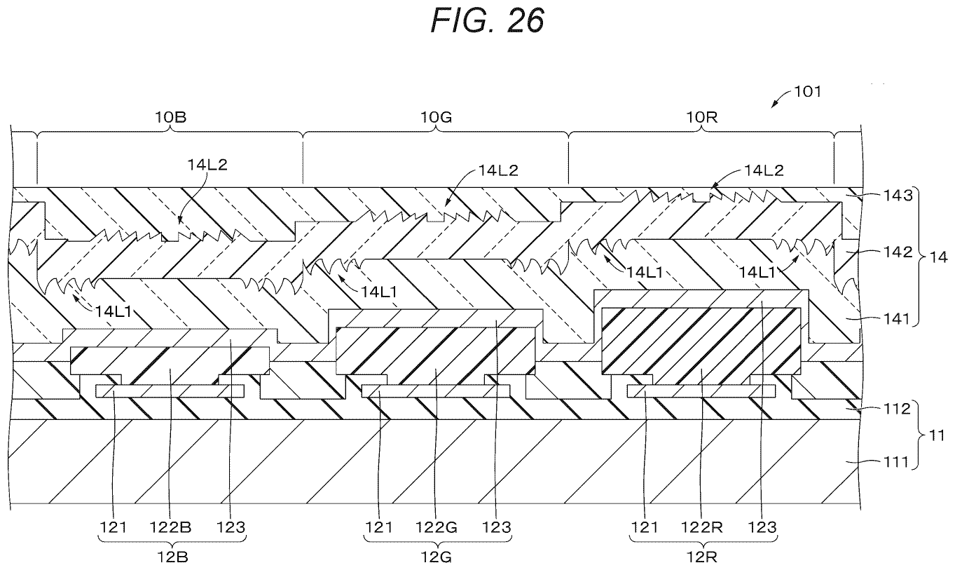

As illustrated in FIG. 26, the light-emitting element 12R, the light-emitting element 12G, and the light-emitting element 12B may have a first resonator structure, a second resonator structure, and a third resonator structure, respectively.

The first resonator structure can resonate and emphasize red light contained in light emitted by the OLED layer 122R. The first resonator structure may be achieved by the first electrodes 121 and the second electrode 123. An optical path length between the first electrode 121 and the second electrode 123 in the light-emitting element 12R may be set to a spectrum peak wavelength of the red subpixel 10R.

The second resonator structure can resonate and emphasize red light contained in light emitted by the OLED layer 122G. The second resonator structure may be achieved by the first electrodes 121 and the second electrode 123. An optical path length between the first electrode 121 and the second electrode 123 in the light-emitting element 12G may be set to a spectrum peak wavelength of the green subpixel 10G.

The third resonator structure can resonate and emphasize blue light contained in light emitted by the OLED layer 122B. The third resonator structure may be achieved by the first electrodes 121 and the second electrode 123. An optical path length between the first electrode 121 and the second electrode 123 in the light-emitting element 12B may be set to a spectrum peak wavelength of the blue subpixel 10B.

In the display device 101 according to Modification 10, the light-emitting element 12R, the light-emitting element 12G, and the light-emitting element 12B have the first resonator structure, the second resonator structure, and the third resonator structure, respectively, so that color purity of the display device 101 can be improved. Furthermore, it is possible to increase the front luminance of the display device 101.

In the example described above, an example has been described in which the first electrode 121 is a reflective electrode having a function as a reflection layer, and the first electrode 121 and the second electrode 123 constitute the first to third resonator structures, but the configurations of the first to third resonator structures are not limited thereto. For example, the display device 101 may include a reflection layer provided below the first electrode 121, and the reflection layer and the second electrode 123 may constitute the first to third resonator structures. In this case, the first electrode 121 is a transparent electrode. The reflection layer may be divided between adjacent subpixels 10, or may be connected between the adjacent subpixels 10.

Furthermore, a distance between the reflection layer and the second electrode 123 in the subpixels 10R, 10G, and 10B may be set according to a thickness of the OLED layer 122, or may be set according to a thickness of the insulating layer between the reflection layer and the first electrode 121.

### Modification 12

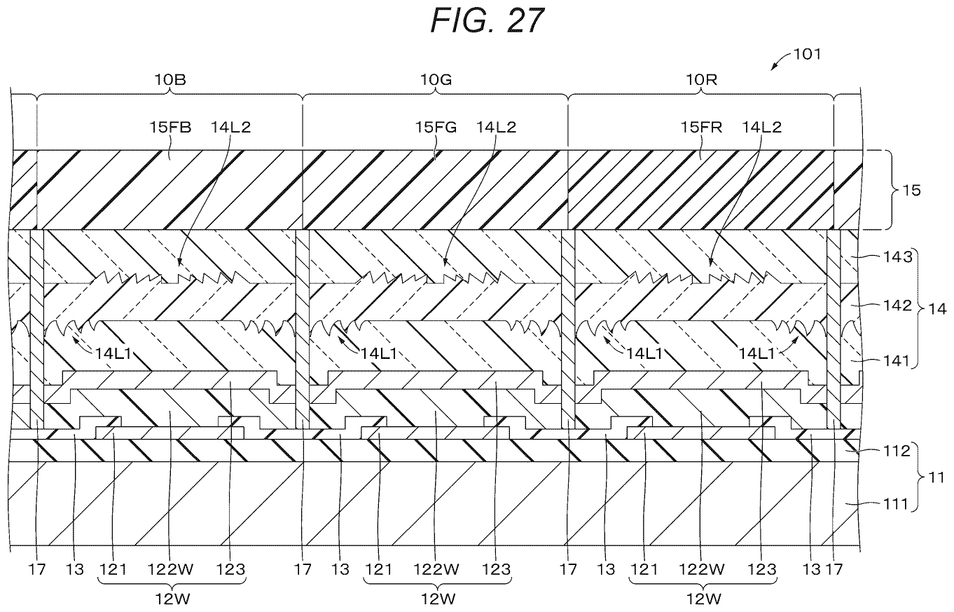

As illustrated in FIG. 27, the display device 101 may include a partition wall 17 between the adjacent subpixels 10. The partition wall 17 is a reflection wall that reflects light emitted from the light-emitting element 12W to the wide angle side.

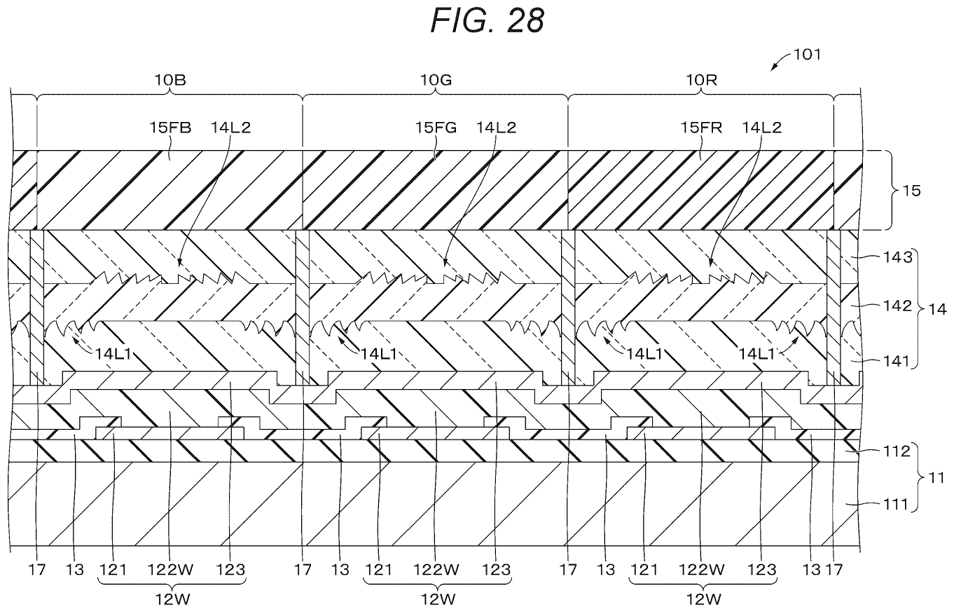

The partition wall 17 is provided on a second surface of the insulating layer 13, and is raised perpendicularly with respect to the second surface of the drive substrate 11. However, the position where the partition wall 17 is provided is not limited to this example. For example, as illustrated in FIG. 28, the partition wall 17 may be provided on the second surface of the second electrode 123.

An upper end of the partition wall 17 may be in contact with a first surface of the color filter 15. However, a position of the upper end of the partition wall 17 is not limited to these examples. For example, the upper end of the partition wall 17 may be located in the multilayer body 14 or may be located at substantially the same height as the second surface of the light-emitting element 12W.

The partition wall 17 may have an annular shape surrounding a periphery of the light-emitting element 12W in plan view. The partition wall 17 may be provided in a part of the periphery of the light-emitting element 12W. In this case, in the periphery of the light-emitting element 12W, the light-emitting element may be provided in a portion in the horizontal direction, a portion in the vertical direction, or both of them.

The partition wall 17 contains metal or polymer resin. As the metal, a material similar to the metal layer of the first electrode 121 can be exemplified, and at least one selected from a group including aluminum (Al) and silver (Ag) is particularly preferable among these metals, from the viewpoint of improving the reflectance. In a case where the partition wall 17 contains metal, an insulating material may be provided on a wall surface of the partition wall 17, or an insulating material may be provided on the wall surface and the partition wall 17.

A refractive index of the polymer resin is preferably lower than a refractive index of the OLED layer 122W. Thus, light emitted from the light-emitting element 12W to the wide angle side can be totally reflected by the partition wall 17. The polymer resin includes, for example, at least one selected from a group including a thermosetting resin, an ultraviolet curable resin, and the like. Specifically, the polymer resin includes, for example, at least one selected from the group from an acrylic resin, a polyimide resin, a novolac resin, an epoxy resin, a norbornene resin, and the like.

In the display device 101 according to Modification 12, the light emitted from the light-emitting element 12W to the wide angle side can be reflected by the partition wall 17 and extracted from the front. Therefore, light condensing property of light to the own subpixel 10 can be further enhanced.

### Modification 13

In Modification 12, an example in which the display device 101 includes the partition wall 17 between the adjacent subpixels 10 (see FIG. 27) has been described, but the display device 101 may have a gap between the adjacent subpixels 10 instead of the partition wall 17. A formation position, a shape, and a height of the gap can be made similar to the formation position, the shape, and the height of the partition wall 17. The gap includes, for example, a gas such as air.

In the display device 101 according to Modification 13, similarly to the display device 101 according to Modification 12, the light emitted from the light-emitting element 12W to the wide angle side can be reflected by the gap and extracted from the front. Therefore, light condensing property of light to the own subpixel 10 can be further enhanced.

### Modification 14

As illustrated in FIG. 29, the display device 101 may further include a lens array 18 above the multilayer body 14. More specifically, the display device 101 may further include a lens array 18 on the first surface of the color filter 15. The display device 101 may further include a flattening layer (not illustrated) between the color filter 15 and the lens array 18.

The lens array 18 includes a plurality of lenses 181. The lens 181 can condense the light emitted upward through the first lens portion 14L1 and the second lens portion 14L2 in the front direction. The plurality of lenses 181 is called an on-chip microlens (OCL), and is two-dimensionally arranged on the first surface of the color filter 15 in a prescribed arrangement pattern.

One lens 181 may be provided above one light-emitting elements 12W, or two or more lenses 181 may be provided above one light-emitting element 12W. FIG. 29 illustrates an example in which one lens 181 is provided above one light-emitting element 12W. The lens 181 may have a curved surface from which the light incident from the light-emitting element 12W is emitted. The curved surface is preferably a convex curved surface protruding in a direction away from the light-emitting element 12W. Examples of the curved surface include, but are not limited to, an approximately parabolic shape, an approximately hemispherical shape, and an approximately semielliptical shape.

The lens array 18 includes, for example, an inorganic material or an organic material transparent to visible light. The inorganic material includes, for example, silicon oxide (SiOₓ). The organic material may be a polymer resin. The organic material includes, for example, ultraviolet curable resin.

In the display device 101 according to Modification 14, the light directed to the front by the first lens portion 14L1 and the second lens portion 14L2 can be condensed by the lens array 18. Therefore, the light emitted from the light-emitting element 12W can be made closer to the parallel light. Thus, the front luminance can be further increased.

### Modification 15

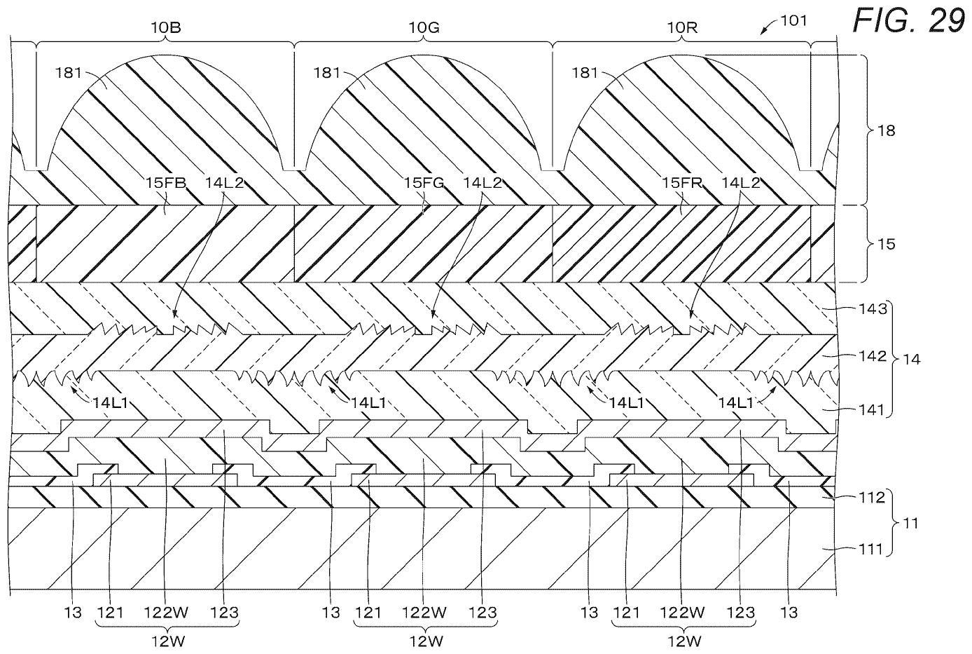

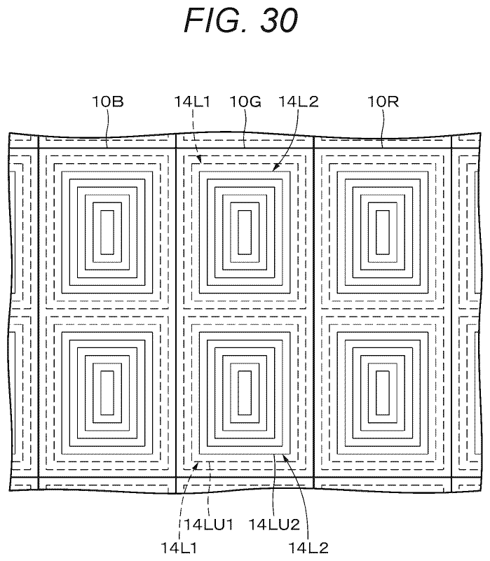

In the first embodiment described above, an example in which one lens pair including the first lens portion 14L1 and the second lens portion 14L2 is provided for one subpixel 10 (see FIG. 5) has been described, but as illustrated in FIG. 30, two or more lens pairs may be provided for one subpixel 10.

### Modification 16

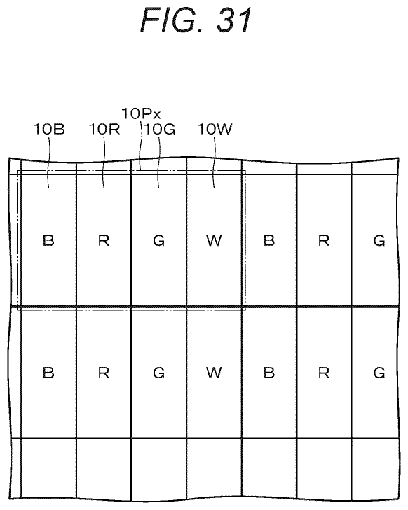

As illustrated in FIG. 31, the display device 101 may further include a plurality of subpixels 10W. One pixel 10Px may include four adjacent subpixels 10R, 10G, 10B, and 10W. The plurality of subpixels 10R, 10G, 10B, and 10W may be arranged in a stripe array.

The subpixel 10W can emit white light. The color filter 15 has a plurality of light-transmitting portions. The light-transmitting portion may be an opening or a transparent member. Each light-transmitting portion is provided at the position of the subpixel 10W. The first lens portion 14L1 and the second lens portion 14L2 are also provided in the subpixel 10W.

In the display device 101 according to Modification 16, the one pixel 10Px includes the four adjacent subpixels 10R, 10G, 10B, and 10W. Thus, luminance of the subpixels 10R, 10G, and 10B can be compensated by the white subpixel 10W.

### Modification 17

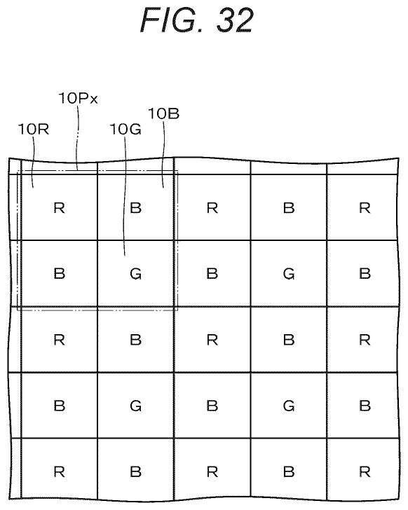

In the first embodiment described above, the example in which the plurality of subpixels 10R, 10G, and 10B are arranged in the stripe array (see FIG. 2) has been described, but as illustrated in FIG. 32, the plurality of subpixels 10R, 10G, and 10B may be arranged in a square array. One pixel 10Px may include four adjacent subpixels 10R, 10G, 10B, and 10B. The subpixels 10R, 10G, and 10B each have a square shape. In one pixel 10Px, the subpixel 10R and the subpixel 10G may be adjacent in a first oblique direction, and in one pixel 10Px, the subpixel 10B and the subpixel 10B may be adjacent in a second oblique direction.

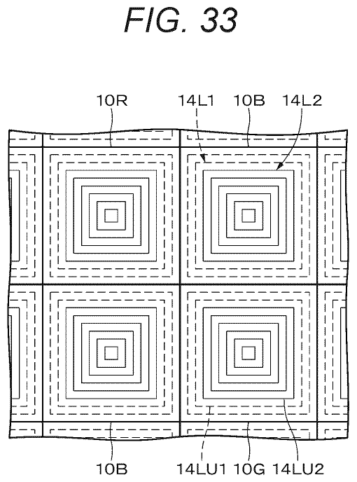

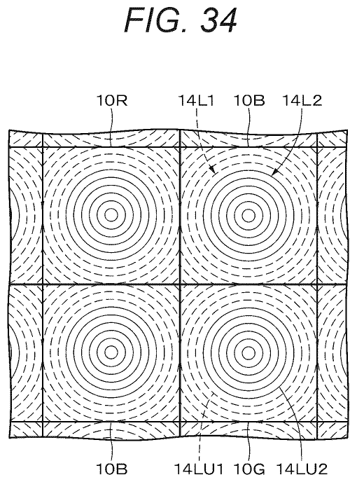

In a case where the subpixels 10R, 10G, and 10B have a square shape, the plurality of first protrusions 14LU1 and the plurality of second protrusions 14LU2 may have a concentric square shape in plan view as illustrated in FIG. 33, or may have concentric circular shapes in plan view as illustrated in FIG. 34. However, the arrangement form of the plurality of first protrusions 14LU1 and the plurality of protrusions LU2 is not limited to these examples.

### Modification 18

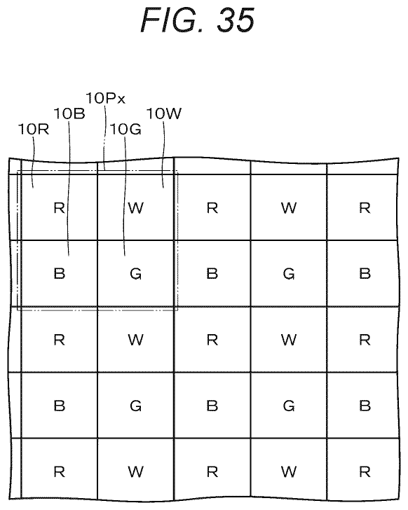

In Modification 17, the example in which the plurality of subpixels 10R, 10G, and 10B is arranged in the square array (see FIG. 32) has been described, but as illustrated in FIG. 35, the plurality of subpixels 10R, 10G, 10B, and 10W may be arranged in the square array. One pixel 10Px may include four adjacent subpixels 10R, 10G, 10B, and 10W. The subpixels 10R, 10G, 10B, and 10W each have a square shape. In one pixel 10Px, the subpixel 10R and the subpixel 10G may be adjacent in the first oblique direction, and in one pixel 10Px, the subpixel 10B and the subpixel 10W may be adjacent in the second oblique direction.

### Modification 19

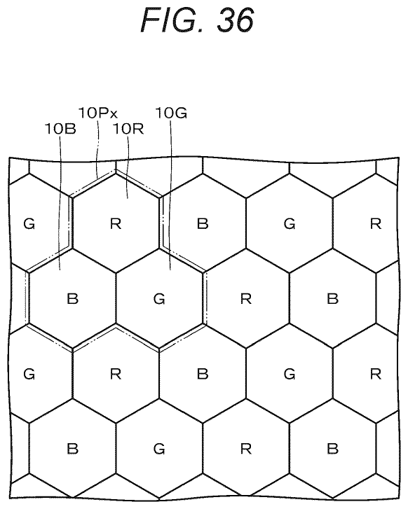

In the first embodiment, the example in which the plurality of subpixels 10R, 10G, and 10B are arranged in the stripe array (see FIG. 2) has been described, but as illustrated in FIG. 36, the plurality of subpixels 10R, 10G, and 10B may be arranged in a delta array. One pixel 10Px may include three subpixels 10R, 10G, and 10B. The subpixels 10R, 10G, and 10B may have a hexagonal shape as illustrated in FIG. 36, or may have an elliptical shape as illustrated in FIG. 40. In a case where the subpixels 10R, 10G, and 10B have a hexagonal shape, the hexagonal shape may be a regular hexagonal shape. In a case where the subpixels 10R, 10G, and 10B have an elliptical shape, the major axis directions of the subpixels 10R, 10G, and 10B preferably coincide with each other.

In a case where the subpixels 10R, 10G, and 10B have a hexagonal shape, the plurality of first protrusions 14LU1 and the plurality of second protrusions 14LU2 may have a concentric hexagonal shape in plan view as illustrated in FIG. 37, or may have a concentric shape in plan view as illustrated in FIG. 38. However, the arrangement form of the plurality of first protrusions 14LU1 and the plurality of protrusions LU2 is not limited to these examples.

In a case where the subpixels 10R, 10G, and 10B have an elliptical shape, as illustrated in FIG. 41, the plurality of first protrusions 14LU1 and the plurality of second protrusions 14LU2 may have a concentric elliptical shape in plan view, may have a concentric circular shape in plan view, or may have a concentric rectangular shape in plan view. However, the arrangement form of the plurality of first protrusions 14LU1 and the plurality of protrusions LU2 is not limited to these examples.

### Modification 20

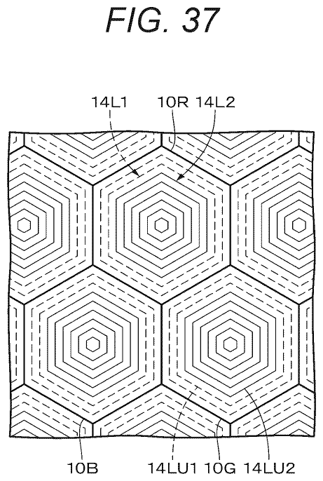

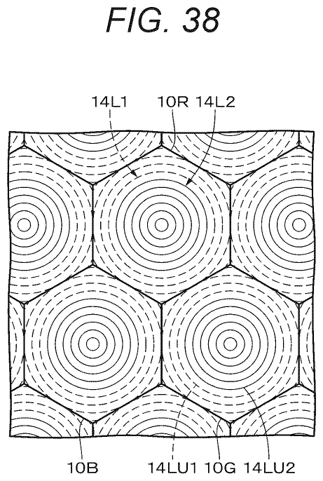

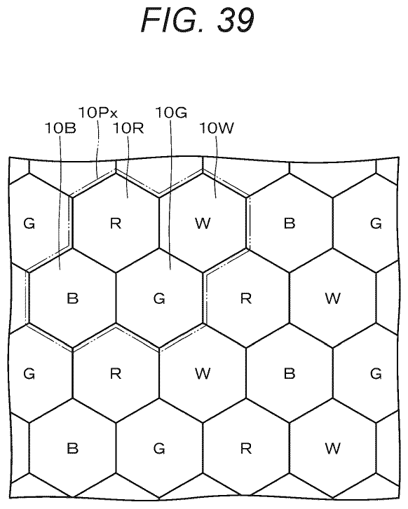

In Modification 19, the example in which the plurality of subpixels 10R, 10G, and 10B is arranged in the delta array (see FIG. 36) has been described, but as illustrated in FIGS. 39 and 42, an array in which one subpixel 10W is further added to three subpixels 10R, 10G, and 10B arranged in the delta array may be used. The subpixel 10W may have a shape similar to that of the subpixels 10R, 10G, and 10B. That is, as illustrated in FIG. 39, in a case where the subpixels 10R, 10G, and 10B have a hexagonal shape, the subpixel 10W may also have a hexagonal shape. As illustrated in FIG. 42, in a case where the subpixels 10R, 10G, and 10B have an elliptical shape, the subpixel 10W may also have an elliptical shape.

### Modification 21

In the first embodiment described above, an example in which the first refractive index n₁, the second refractive index n₂, and the third refractive index n₃ satisfy n₁ and n₃<n₂ has been described, but the first refractive index n₁, the second refractive index n₂, and the third refractive index n₃ may satisfy n₂<n₁ and n₃. In this case, the refractive index difference Δn₂₁ (=|n₂−n₁|) is preferably equal to or more than 0.1, more preferably equal to or more than 0.2, still more preferably equal to or more than 0.3, 0.4, or 0.5. The refractive index difference Δn₂₃ (=|n₂−n₃|) is preferably equal to or more than 0.1, more preferably equal to or more than 0.2, and still more preferably equal to or more than 0.3, 0.4, or 0.5.

The first refractive index n₁ and the second refractive index n₂ may be n₁=n2. The second refractive index n₂ and the third refractive index n₃ may be n₂=n₃.

### Modification 22

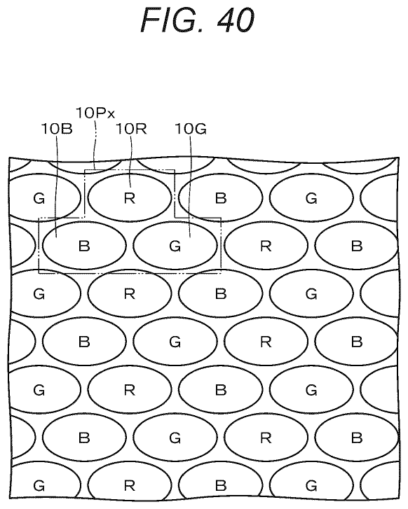

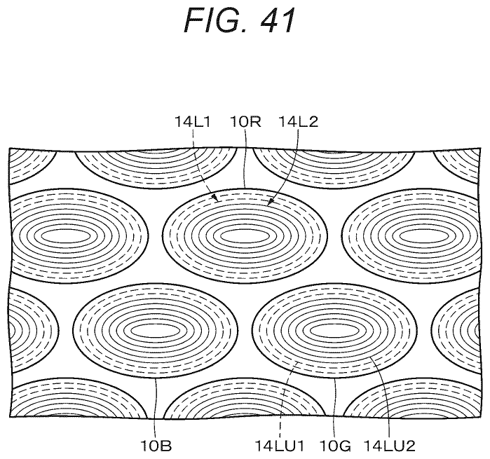

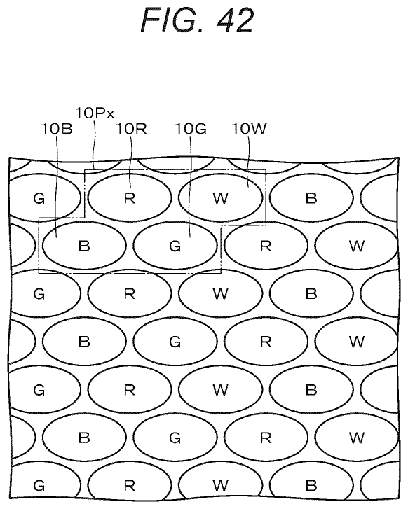

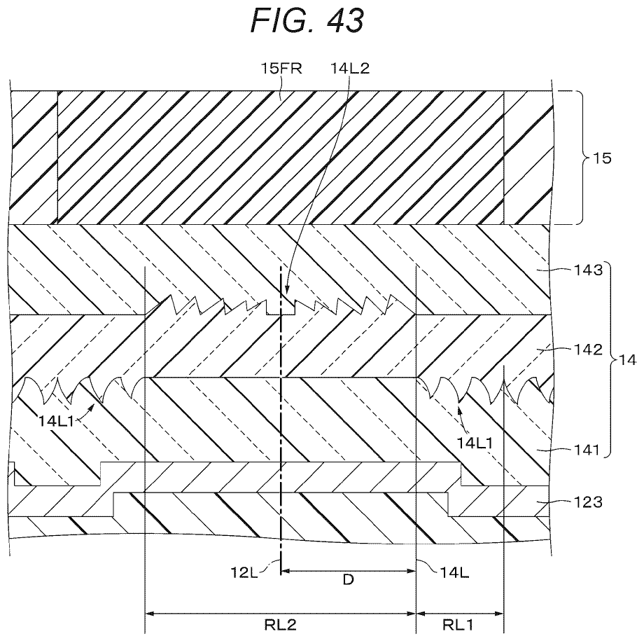

As illustrated in FIG. 43, an inner circumference of a first lens portion formation region RL1 where the first lens portion 14L1 is formed and an outer circumference of a second lens portion formation region RL2 where the second lens portion 14L2 is formed may substantially coincide with each other in plan view. A distance D from the geometric center of the subpixel 10 to a boundary 14L between the first lens portion formation region RL1 and the second lens portion formation region RL2 in an in-plane direction is preferably 1 μm or less. When the distance D is 1 μm or less, the light condensing efficiency in the front direction can be increased, and color mixing to adjacent pixels can be reduced. Herein, the in-plane direction refers to an in-plane direction in a display surface or a second surface of the drive substrate 11.

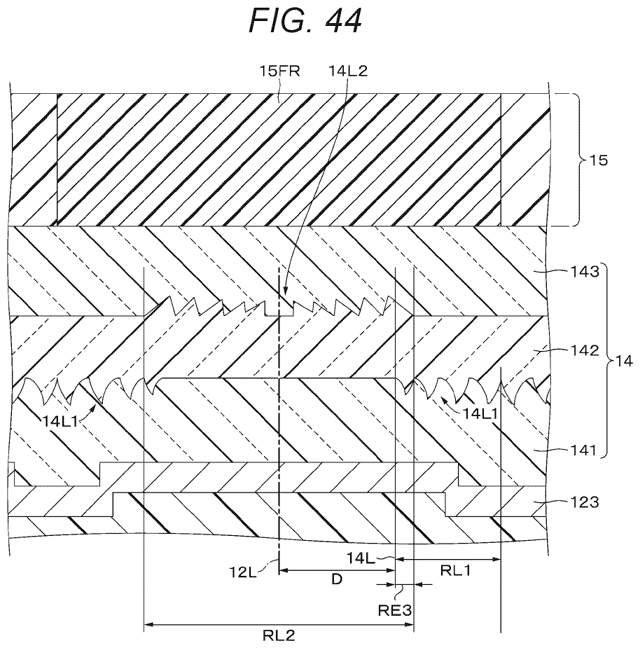

As illustrated in FIG. 44, the first lens portion formation region RL1 where the first lens portion 14L1 is formed and the second lens portion formation region RL2 where the second lens portion 14L2 is formed may partially overlap to form an overlap region RE3. In this case, the boundary 14L between the first lens portion formation region RL1 and the second lens portion formation region RL2 represents an inner circumference of the overlap region RE3.

### Modification 23

The display device 101 may further include a filling resin layer and a cover layer in order on the second surface of the color filter 15. When the display device 101 includes the filling resin layer and the cover layer, characteristics such as scratch resistance and weather resistance of the display device 101 can be improved.

A filler layer is filled between the second surface of the color filter 15 and the second surface of the cover layer. The filler layer has translucency to light of each color emitted from the color filter 15. The filler layer is preferably transparent to visible light. The filler layer preferably has a function as an adhesive layer for bonding the color filter 15 and the cover layer.

The filler layer contains, for example, a curable resin. The curable resin contains at least one selected from a group including a thermosetting resin, an ultraviolet curable resin, and the like. Note that the filler layer is not limited to thermosetting resins and ultraviolet curable resins, and may contain some other kind of curable resin that is neither a thermosetting resin nor an ultraviolet curable resin.

The cover layer is provided on the second surface of the filler layer. The cover layer seals the second surface of the drive substrate 11 on which the respective members such as the plurality of light-emitting elements 12W are provided. The cover layer has translucency to light of each color emitted from the color filter 15. The cover layer is preferably transparent to visible light. The cover layer is, for example, a glass substrate.

### Modification 24

The display device 101 may further include a hard coat layer on the second surface of the color filter 15. When the display device 101 includes the hard coat layer, characteristics such as scratch resistance and weather resistance of the display device 101 can be improved.

The hard coat layer contains, for example, an ultraviolet curable resin. The ultraviolet curable resin composition contains, for example, at least one selected from a group including a radical polymerization ultraviolet curable resin composition, a cationic polymerization ultraviolet curable resin composition, and the like. The ultraviolet curable resin may contain an additive as necessary. The additive includes, for example, at least one selected from the group including a sensitizer, a filler, a stabilizer, a leveling agent, an ultraviolet absorber, an antistatic agent, an antifoaming agent, a viscosity modifier, and the like. Specifically, the ultraviolet curable resin may include, for example, an acrylic ultraviolet curable resin.

Pencil hardness of the surface of the hard coat layer is preferably equal to or more than 4H, more preferably equal to or more than 5H, and still more preferably equal to or more than 6H from the viewpoint of improving characteristics such as scratch resistance and weather resistance of the display device 101. The pencil hardness of the surface of the hard coat layer is measured in accordance with JIS K5600-5-4. The measurement is performed in an atmosphere at a temperature of 23±1° C. and a relative humidity of 50±5%.

Since the display device 101 according to Modification 24 does not include a cover layer such as a glass substrate, the display device 101 can be thinned. Furthermore, it is also possible to reduce the material cost of the display device 101 and the manufacturing process takt of the display device 101.

The display device 101 may further include an optical element on the second surface of the hard coat layer. The optical element is, for example, a polarizing plate or a polarizing film.

### Modification 25

In the first embodiment described above, an example in which the light-emitting element 12W is an OLED element has been described, but the light-emitting element is not limited to this example and may be, for example, a light-emitting element of a self-luminous type such as a light-emitting diode (LED), an inorganic electro-luminescence (IEL) element, or a semiconductor laser element. The display device may be provided with two or more types of light-emitting elements.

### Modification 26

In the first embodiment described above, the example in which the present disclosure is applied to the display device has been described, but the present disclosure is not limited to this example. For example, the present disclosure may be applied to a light-emitting device such as a lighting device.

### Modification 27

In the first embodiment described above, the example in which the color filter 15 is provided has been described, but a quantum dot layer may be provided instead of the color filter 15, or a quantum dot layer may be provided together with the color filter 15. The quantum dot layer includes quantum dots (semiconductor particles), and can convert a color of light emitted from a plurality of light-emitting elements. As the plurality of light-emitting elements, a plurality of light-emitting elements capable of emitting blue light may be provided instead of the plurality of light-emitting elements 12W.

### Modification 28

In the first embodiment described above, the example in which the first electrode 121 is an anode and the second electrode 123 is a cathode has been described, but the first electrode 121 may be a cathode, and the second electrode 123 may be an anode.

### Modification 29

In the first embodiment described above, an example in which the first electrode 121 is an individual electrode and the second electrode 123 is a common electrode has been described, but the first electrode 121 may be a common electrode and the second electrode 123 may be an individual electrode.

### Modification 30

In the first embodiment described above, the example in which the first lens portion 14L1 includes the plurality of first protrusions 14LU1 (see FIGS. 3 and 5) has been described, but the first lens portion 14L1 may include one first protrusion 14LU1. In the first embodiment described above, the example in which the second lens portion 14L2 includes the plurality of second protrusions 14LU2 (see FIGS. 3 and 5) has been described, but the second lens portion 14L2 may include one first protrusion 14LU1.

### Modification 31

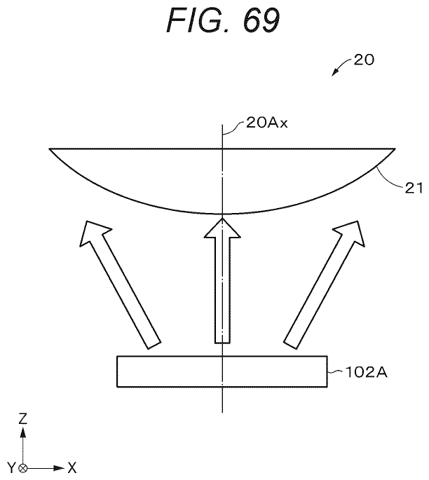

In the second embodiment, an example has been described in which the display device 102 is configured to be capable of condensing the emitted light from the light-emitting element 12W toward the optical axis 20Ax of the optical system 20. However, the present disclosure is not limited to this example, and as illustrated in FIG. 69, it may be configured to be capable of spreading the emitted light from the light-emitting element 12W with respect to the optical axis 20Ax of the optical system 20. In Modification 31, a display device 102A having such a configuration will be described.

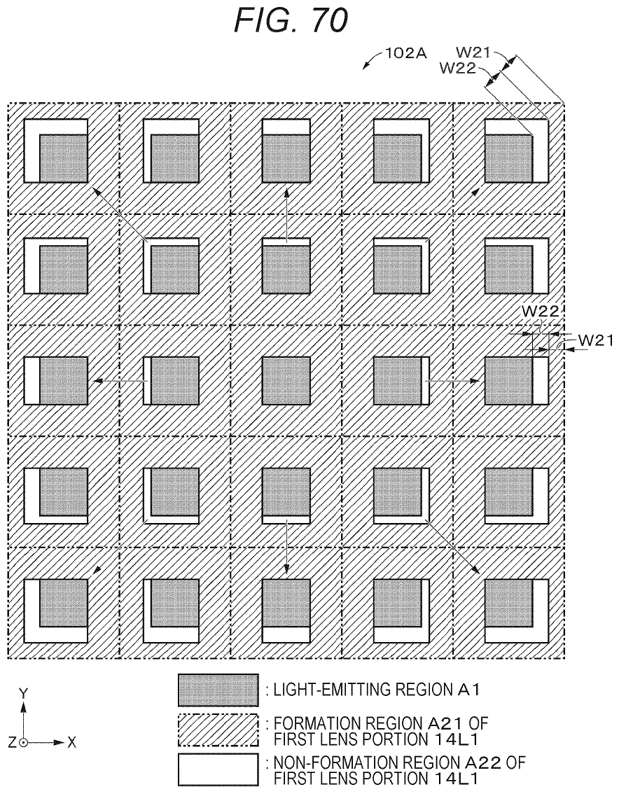

In the display device 102A according to Modification 31, as illustrated in FIG. 70, a width W21 of a portion located on the outer peripheral side of the effective pixel region RE1 in the formation region A21 of the first lens portion 14L1 becomes narrower from the center toward the outer periphery of the effective pixel region RE1. Thus, the width W22 of the non-formation region A22 of the first lens portion 14L1 located between the light-emitting region A1 and the formation region A21 of the first lens portion 14L1 becomes wider from the center toward the outer periphery of the effective pixel region RE1. Therefore, as the subpixel 10 is farther from the center of the effective pixel region RE1, the light emitted from the light-emitting element 12W to the wider angle side is more likely to be extracted via the non-formation region A22 of the first lens portion 14L1 (see arrows in FIG. 70). Thus, the emitted light from the light-emitting element 12W is spread with respect to the optical axis 20Ax of the optical system 20.

The change in the width W21 of the formation region A21 of the first lens portion 14L1 is as described in the second embodiment, and may change for each subpixel 10 from the center of the effective pixel region RE1 toward the outer periphery, or may change for each predetermined number of subpixels 10 from the center of the effective pixel region REI toward the outer periphery.

The plurality of subpixels 10 provided in the effective pixel region RE1 include the subpixel 10 in which the center of the filter portion 15F is shifted in a direction from the center of the effective pixel region RE1 toward the outer periphery with reference to the center P1 of the light-emitting region. The shift amount of the center of the filter portion 15F with reference to the center P1 of the light-emitting region A1 of the subpixel 10 increases from the center of the effective pixel region RE1 toward the outer periphery. Thus, the emitted light from the light-emitting element 12W spread with respect to the optical axis 20Ax of the optical system 20 easily transmits through the filter portion 15F. The shift amount of the center of the filter portion 15F with reference to the center P1 of the light-emitting region A1 of the subpixel 10 preferably increases as the width W21 of the formation region A21 of the first lens portion 14L1 narrows, that is, as the width W22 of the non-formation region A22 of the first lens portion 14L1 widens.

### Modification 32

A display device 103A according to Modification 32 is configured to be capable of spreading the emitted light from the light-emitting element 12W with respect to the optical axis 20Ax, similarly to the display device 102A according to Modification 31.

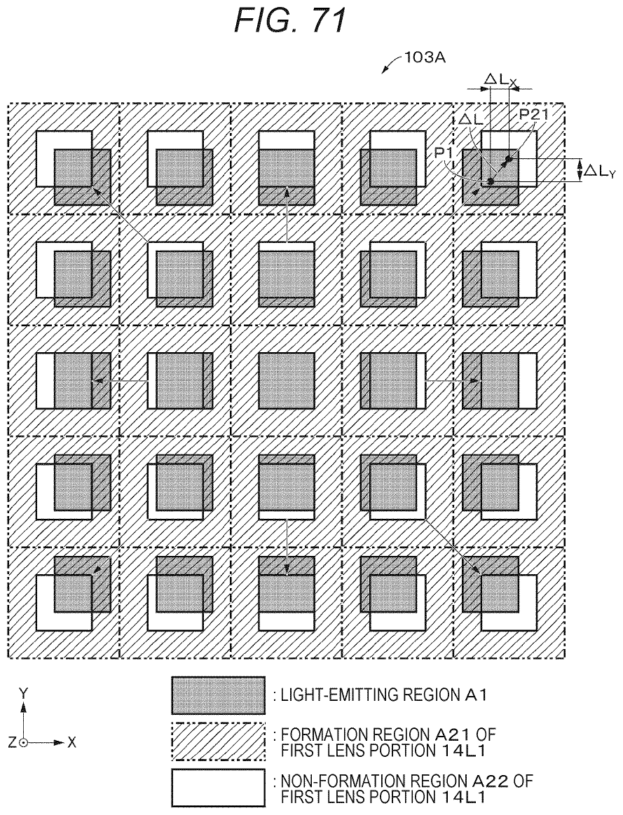

In the display device 103A according to Modification 32, as illustrated in FIG. 71, the plurality of subpixels 10 provided in the effective pixel region RE1 includes the first lens portion 14L1 in which the center P21 of the formation region A21 of the first lens portion 14L1 is shifted in a direction from the center of the effective pixel region RE1 toward the outer periphery with reference to the center P1 of the light-emitting region A1 of the subpixel 10. The shift amount ΔL between the center P1 of the light-emitting region A1 of the subpixel 10 and the center P21 of the formation region A21 of the first lens portion 14L1 increases from the center of the effective pixel region RE1 toward the outer periphery. Thus, the width of the non-formation region A22 of the first lens portion 14L1 located between the light-emitting region A1 and the formation region A21 of the first lens portion 14L1 increases from the center toward the outer periphery of the effective pixel region RE1. Therefore, the emitted light from the light-emitting element 12W is spread with respect to the optical axis 20Ax of the optical system 20 (see arrows in FIG. 71).

The change in the shift amount ΔL between the center P1 of the light-emitting region A1 of the subpixel 10 and the center P21 of the formation region A21 of the first lens portion 14L1 is as described in the third embodiment, and may change for each subpixel 10 from the center of the effective pixel region RE1 toward the outer periphery, or may change for each predetermined number of subpixels 10 from the center of the effective pixel region RE1 toward the outer periphery.

In Modification 32, it is preferable that the shift amount of the center of the filter portion 15F with reference to the center P1 of the light-emitting region A1 of the subpixel 10 increases as the shift amount ΔL between the center P1 of the light-emitting region A1 of the subpixel 10 and the center P21 of the formation region A21 of the first lens portion 14L1 increases. The arrangement of the filter portion 15F is similar to the arrangement of the filter portion 15F in Modification 31 in other points.

### Modification 33

The display device 104A according to Modification 33 is configured to be capable of spreading the emitted light from the light-emitting element 12W with respect to the optical axis 20Ax, similarly to the display device 102A according to Modification 31.

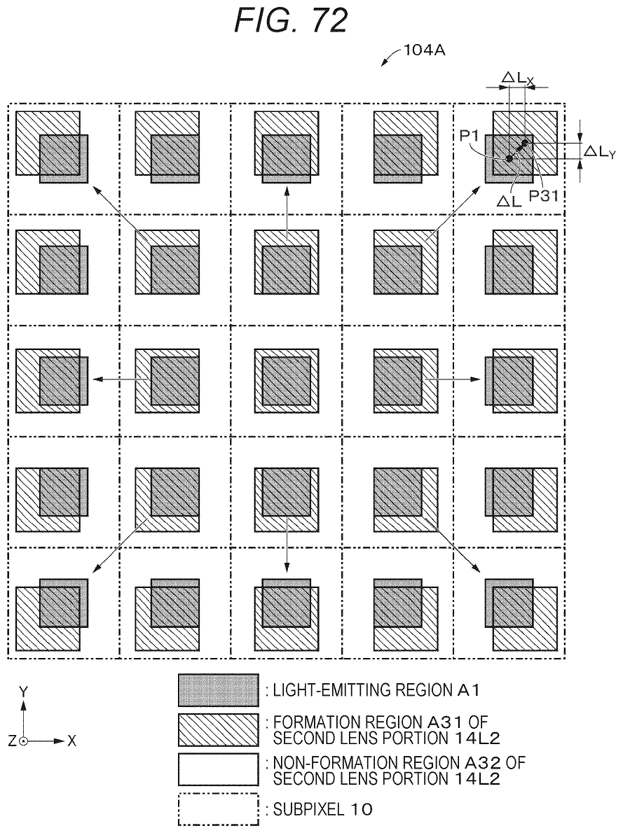

In the display device 104A according to Modification 33, as illustrated in FIG. 72, the plurality of subpixels 10 provided in the effective pixel region RE1 includes the subpixel 10 in which the center P31 of the formation region A31 of the second lens portion 14L2 is shifted in a direction from the center of the effective pixel region RE1 toward the outer periphery with reference to the center P1 of the light-emitting region A1 of the subpixel 10. A shift amount ΔL of the center P31 of the formation region A31 of the second lens portion 14L2 with reference to the center P1 of the light-emitting region A1 of the subpixel 10 increases from the center of the effective pixel region RE1 toward the outer periphery. Thus, as the subpixel 10 is farther from the center of the effective pixel region RE1, the emitted light from the light-emitting element 12W is directed more outward of the effective pixel region RE1 (see arrows in FIG. 72). Therefore, the emitted light from the light-emitting element 12W is spread with respect to the optical axis 20Ax of the optical system 20.

The change in the shift amount ΔL between the center P1 of the light-emitting region A1 of the subpixel 10 and the center P31 of the formation region A31 of the second lens portion 14L2 is as described in the fourth embodiment, and may change for each subpixel 10 from the center of the effective pixel region RE1 toward the outer periphery, or may change for each predetermined number of subpixels 10 from the center of the effective pixel region REI toward the outer periphery.

In Modification 33, it is preferable that the shift amount of the center of the filter portion 15F with reference to the center P1 of the light-emitting region A1 of the subpixel 10 is increased according to an increase in the shift amount ΔL between the center P1 of the light-emitting region A1 of the subpixel 10 and the center P31 of the formation region A31 of the second lens portion 14L2. The arrangement of the filter portion 15F is similar to the arrangement of the filter portion 15F in Modification 31 in other points.

### Modification 34

The display device 105A according to Modification 34 is configured to be capable of spreading the emitted light from the light-emitting element 12W with respect to the optical axis 20Ax, similarly to the display device 102A according to Modification 31.

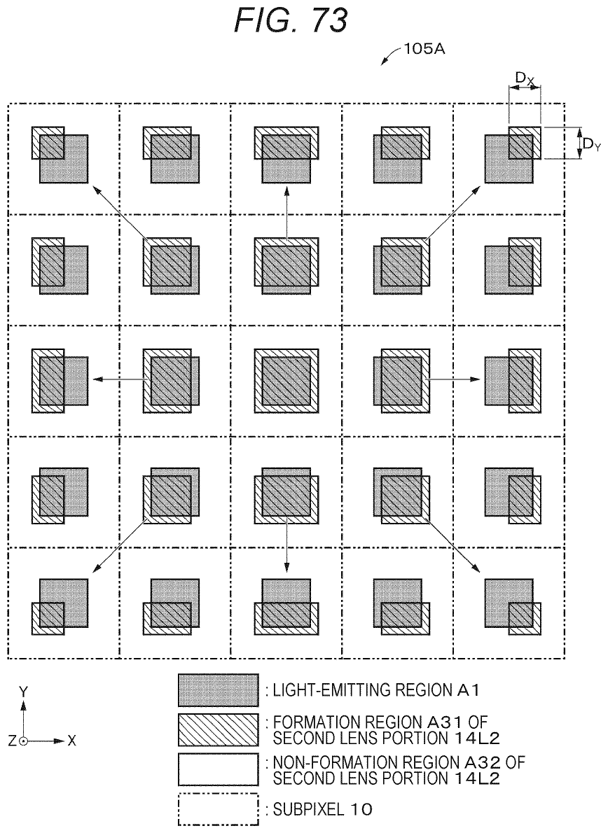

In the display device 105A according to Modification 34, as illustrated in FIG. 73, the width D_{X} of the formation region A31 of the second lens portion 14L2 becomes narrower with increasing distance from the center of the effective pixel region RE1 in the X-axis direction. Then, as the width D_{X} decreases in the X-axis direction, the center of the formation region A31 of the second lens portion 14L2 is shifted in a direction from the center of the effective pixel region REI toward the outer periphery in the X-axis direction with reference to the center of the light-emitting region A1 of the subpixel 10. Furthermore, as illustrated in FIG. 73, the width D_{Y} of the formation region A31 of the second lens portion 14L2 becomes narrower with increasing distance from the center of the effective pixel region RE1 in the Y-axis direction. Then, as the width D_{X} decreases in the X-axis direction, the center of the formation region A31 of the second lens portion 14L2 is shifted in the Y-axis direction from the center of the effective pixel region RE1 toward the outer periphery with reference to the center of the light-emitting region A1 of the subpixel 10. Thus, as the subpixel 10 is farther from the center of the effective pixel region RE1, the emitted light from the light-emitting element 12W is directed more outward of the effective pixel region RE1 (see arrows in FIG. 73). Therefore, the emitted light from the light-emitting element 12W is spread with respect to the optical axis 20Ax of the optical system 20.

The changes in the widths D_{X} and D_{Y} of the formation region A31 of the second lens portion 14L2 and the shift amount between the center of the light-emitting region A1 of the subpixel 10 and the center of the formation region A31 of the second lens portion 14L2 are as described in the fifth embodiment, and may change for each subpixel 10 from the center of the effective pixel region RE1 toward the outer periphery, or may change for each predetermined number of subpixels 10 from the center of the effective pixel region RE1 toward the outer periphery.

In Modification 34, it is preferable that the shift amount of the center of the filter portion 15F in the X-axis direction with reference to the center of the light-emitting region A1 of the subpixel 10 increases as the width D_{X} of the formation region A31 of the second lens portion 14L2 decreases. Furthermore, the shift amount of the center of the filter portion 15F in the Y-axis direction with reference to the center of the light-emitting region A1 of the subpixel 10 is preferably increased as the width D_{Y} of the formation region A31 of the second lens portion 14L2 decreases. The arrangement of the filter portion 15F is similar to the arrangement of the filter portion 15F in Modification 31 in other points.

### Other Modifications

Although the first embodiment and the modifications thereof and the second to fifth embodiments and the modifications thereof of the present disclosure have been specifically described above, the present disclosure is not limited to the above-described first embodiment and modifications thereof and the second to fifth embodiments and the modifications thereof, and various modifications based on the technical idea of the present disclosure are possible.

For example, the configurations, methods, processes, shapes, materials, numerical values, and the like mentioned in the above-described first embodiment and modifications thereof and the second to fifth embodiments and the modifications thereof are merely examples, and different configurations, methods, processes, shapes, materials, numerical values, and the like may be used as necessary.

The configurations, methods, processes, shapes, materials, numerical values, and the like of the above-described first embodiment and modifications thereof and the second to fifth embodiments and the modifications thereof can be combined with each other without departing from the gist of the present disclosure.

The materials exemplified in the above-described first embodiment and modifications thereof and the second to fifth embodiments and the modifications thereof can be used alone or in combination of two or more unless otherwise specified.

The technology described in Modifications 1 to 30 may be applied to the display devices 102, 103, 104, and 105 according to the second, third, fourth, and fifth embodiments and the display devices 102A, 103A, 104A, and 105A according to Modification 31, Modification 32, Modification 33, and Modification 34.

Furthermore, the present disclosure may also employ the following configurations.
(1)

A display device including:
a plurality of light-emitting elements; and
a multilayer body covering the plurality of light-emitting elements, in which
the multilayer body includes, in order, a first layer having a first refractive index n₁, a second layer having a second refractive index n₂ different from the first refractive index n₁, and a third layer having a third refractive index n₃ different from the second refractive index n₂,
the second layer includes a plurality of first lens portions and a plurality of second lens portions,
the plurality of first lens portions and the plurality of second lens portions are provided on different surfaces of the second layer,
the first lens portions are provided in one of a central portion and a peripheral portion of pixels, and the second lens portions are provided in another of the central portion and the peripheral portion of the pixels.
(2)

The display device according to (1), in which
the plurality of first lens portions is provided on a first surface on a side of the first layer, the first lens portions each include at least one annular first protrusion and are located in the peripheral portion of the pixels,
the plurality of second lens portions is provided on a second surface on a side of the third layer, and
the second lens portions each include at least one annular second protrusion and are located in the central portion of the pixels.
(3)

The display device according to (2), in which
the at least one annular first protrusion includes a plurality of annular first protrusions, and
the plurality of annular first protrusions is concentrically arranged.
(4)

The display device according to (2), in which the first lens portions are a concentric prism lens array, and
the second lens portions are a Fresnel lens, a spherical lens, or a frustum lens.
(5)

The display device according to any one of (2) to (4), in which
the second layer further includes a plurality of third lens portions,
the plurality of third lens portions is provided on the first surface, and each of the third lens portions is located in the central portion of the pixels.
(6)

The display device according to any one of (1) to (5), in which
the first lens portions and the second lens portions included in adjacent pixels among the pixels are parallel to an optical axis of the light-emitting element and symmetric with respect to a center line passing through a midpoint between the adjacent pixels.
(7)

The display device according to any one of (1) to (6), in which
the first refractive index n₁, the second refractive index n₂, and the third refractive index n₃ satisfy n₁ and n₃<n₂.
(8)

The display device according to any one of (1) to (7), in which
a distance from a geometric center of each of the pixels to a boundary between a formation region of the first lens portions and a formation region of the second lens portions in an in-plane direction is equal to or less than 1 μm.
(9)

The display device according to any one of (1) to (8), in which
a formation region of the first lens portions and a formation region of the second lens portions overlap each other.
(10)

The display device according to any one of (1) to (9), further including:
a color filter, in which
the color filter is provided between the plurality of light-emitting elements and the multilayer body or is provided on the multilayer body.
(11)

The display device according to any one of (1) to (10), in which
each of the light-emitting elements includes a first electrode, an organic-containing layer including an organic light-emitting layer, and a second electrode in order.
(12)

The display device according to (11), in which
the first electrode, the organic-containing layer, and the second electrode have a curved shape recessed in a direction away from the display surface.
(13)

The display device according to any one of (1) to (12), in which
at least a part of the plurality of light-emitting elements has a resonator structure.
(14)

The display device according to any one of (1) to (13), further including:
a partition wall, in which
the partition wall is provided between adjacent pixels among the pixels.
(15)

The display device according to any one of (1) to (14), further including:
a plurality of lenses, in which
the plurality of lenses is provided above the multilayer body.
(16)

A display device including:
a plurality of light-emitting elements; and
a multilayer body covering the plurality of light-emitting elements, in which
the multilayer body includes, in order, a first layer having a first refractive index n₁ and a second layer having a second refractive index n₂ different from the first refractive index n₁,
the second layer includes a plurality of first lens portions,
the plurality of first lens portions is provided on a first surface on a side of the first layer, and the first lens portions are located in one of a central portion and a peripheral portion of pixels.
(17)

A display device including:
a plurality of light-emitting elements; and
a multilayer body covering the plurality of light-emitting elements, in which
the multilayer body includes, in order, a second layer having a second refractive index n₂ and a third layer having a third refractive index n₃ different from the second refractive index n₂,
the second layer includes a plurality of second lens portions,
the plurality of second lens portions is provided on a second surface on a side of the third layer, and the second lens portions are located in one of a central portion and a peripheral portion of pixels.
(18)

The display device according to (16), in which the second layer includes a plurality of metamaterials, and the metamaterials are located in another of the central portion and the peripheral portion of the pixels.
(19)

The display device according to (16), in which
the second layer includes a plurality of through holes,
the first lens portions are located in the peripheral portion of the pixels, and
the through holes are located in the central portion of the pixels.
(20)

An electronic apparatus including the display device according to any one of (1) to (19).
(21)

The display device according to any one of (1) to (15), in which
the multilayer body is configured to be capable of condensing incident light from the plurality of light-emitting elements toward an optical axis.
(22)

The display device according to any one of (1) to (15) and (21), in which
a width of a portion located on a center side of an effective pixel region in a formation region of the first lens portions decreases from a center toward an outer periphery of the effective pixel region.
(23)

The display device according to any one of (1) to (15) and (21), in which
the plurality of first lens portions includes a first lens portion in which a center of the first lens portion is shifted in a direction from an outer periphery toward a center of an effective pixel region with reference to a center of a light-emitting region of the pixel, and
a shift amount between the center of the light-emitting region of the pixel and the center of the first lens portion increases from the center toward the outer periphery of the effective pixel region.
(24)

The display device according to any one of (1) to (15) and (21), in which
the plurality of second lens portions includes a second lens portion in which a center of the second lens portion is shifted in a direction from an outer periphery toward a center of an effective pixel region with reference to a center of a light-emitting region of the pixel, and
a shift amount between the center of the light-emitting region of the pixel and the center of the second lens portion increases from the center toward the outer periphery of the effective pixel region.
(25)

The display device according to any one of (1) to (15) and (21), in which
a width of a formation region of the second lens portions decreases from an outer periphery toward a center of an effective pixel region, and a center of the second lens portions shifts in a direction from the outer periphery toward the center of the effective pixel region with reference to a center of a light-emitting region of the pixel.
(26)

The display device according to any one of (1) to (15), in which
the multilayer body is configured to be capable of spreading incident light from the plurality of light-emitting elements with respect to an optical axis.
(27)

The display device according to any one of (1) to (15) and (26), in which
a width of a portion located on an outer peripheral side of an effective pixel region in a formation region of the first lens portions decreases from a center toward an outer periphery of the effective pixel region.
(28)

The display device according to any one of (1) to (15) and (26), in which
the plurality of first lens portions includes a first lens portion in which a center of the first lens portion is shifted in a direction from a center toward an outer periphery of an effective pixel region with reference to a center of a light-emitting region of the pixel, and
a shift amount between the center of the light-emitting region of the pixel and the center of the first lens portion increases from the center toward the outer periphery of the effective pixel region.
(29)

The display device according to any one of (1) to (15) and (26), in which
the plurality of second lens portions include a second lens portion in which a center of the second lens portion is shifted in a direction from a center toward an outer periphery of an effective pixel region with reference to a center of a light-emitting region of the pixel, and
a shift amount between the center of the light-emitting region of the pixel and the center of the second lens portion increases from the center toward the outer periphery of the effective pixel region.
(30)

The display device according to any one of (1) to (15) and (26), in which
a width of a formation region of the second lens portions decreases from a center toward an outer periphery of an effective pixel region, and a center of the second lens portions shifts in a direction from the center toward the outer periphery of the effective pixel region with reference to a center of a light-emitting region of the pixel.

### 8. Relationship Among Normal Lines Passing Through Centers of Light-Emitting Unit, Lens Member, and Wavelength Selection Unit

In the description below, a relationship among a normal line LN extending through a center of a light-emitting unit, a normal line LN′ extending through a center of a lens member, and a normal line LN″ extending through a center of a wavelength selection unit is described. Here, the light-emitting unit is, for example, the light-emitting element 12W, the light-emitting element 12R, the light-emitting element 12G, or the light-emitting element 12B. The lens member is, for example, the first lens portion 14L1, the second lens portion 14L2, the third lens portion 14L3, or the lens 181 of the lens array 18. The wavelength selection unit is, for example, a filter portion 15F.

Note that the size of the wavelength selection unit may be changed as appropriate in accordance with light emitted from the light-emitting unit, or in a case where a light absorbing unit (for example, a black matrix unit) is provided between the wavelength selection units of adjacent light-emitting units, the size of the light absorbing unit may be changed as appropriate in accordance with light emitted from the light-emitting unit. Furthermore, the size of the wavelength selection unit may be changed as appropriate in accordance with a distance (offset amount) d₀ between the normal line passing through the center of the light-emitting unit and the normal line passing through the center of the wavelength selection unit. The planar shape of the wavelength selection unit may be the same as, similar to, or different from the planar shape of the lens member.

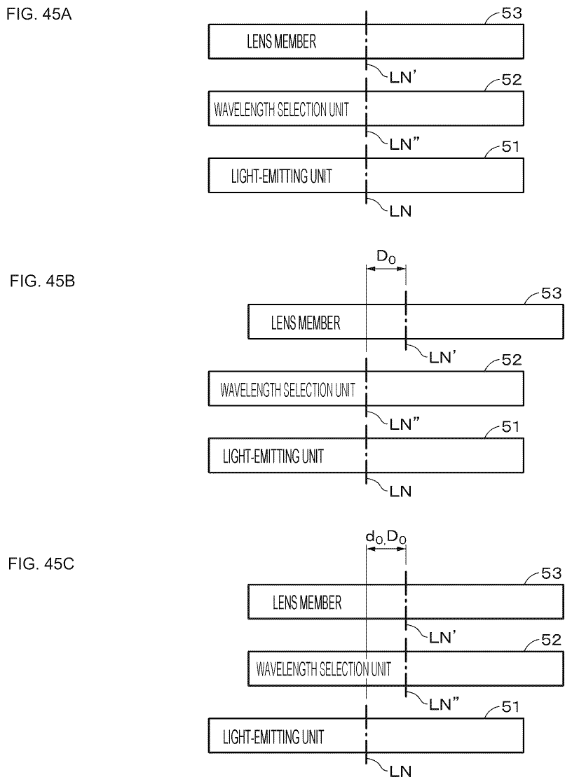

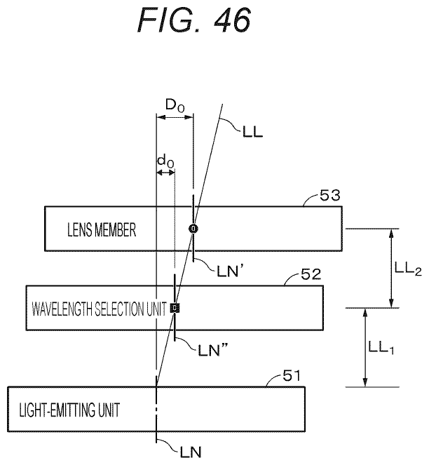

Hereinafter, with reference to FIGS. 45A, 45B, 45C, and 46, a relationship among the normal lines each passing through the center of each unit in a case where the light-emitting unit 51, the wavelength selection unit 52, and the lens member 53 are disposed in this order will be described.

As illustrated in FIG. 45A, the normal line LN passing through the center of the light-emitting unit 51, the normal line LN″ passing through the center of the wavelength selection unit 52, and the normal line LN′ passing through the center of the lens member 53 may coincide with each other. That is, D₀=0 and d₀=0 may be satisfied. Here, Do represents the distance (offset amount) between the normal line LN passing through the center of the light-emitting unit 51 and the normal line LN′ passing through the center of the lens member 53, and do represents the distance (offset amount) between the normal line LN passing through the center of the light-emitting unit 51 and the normal line LN″ passing through the center of the wavelength selection unit 52.

As illustrated in FIG. 45B, the normal line LN passing through the center of the light-emitting unit 51 and the normal line LN″ passing through the center of the wavelength selection unit 52 may coincide with each other, but the normal line LN passing through the center of the light-emitting unit 51 and the normal line LN″ passing through the center of the wavelength selection unit 52 need not coincide with the normal line LN′ passing through the center of the lens member 53. That is, D₀>0 and d₀=0 may be satisfied.

As illustrated in FIG. 45C, the normal line LN passing through the center of the light-emitting unit 51 need not coincide with the normal line LN″ passing through the center of the wavelength selection unit 52 and the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 46, it may be configured that the normal line LN passing through the center of the light-emitting unit 51, the normal line LN″ passing through the center of the wavelength selection unit 52, and the normal line LN′ passing through the center of the lens member 53 do not coincide with each other. That is, D₀>0, d₀>0, and D₀≠d₀ may be satisfied. Here, the center of the wavelength selection unit 52 (position indicated by a black square in FIG. 46) is preferably located on a straight line LL connecting the center of the light-emitting unit 51 and the center of the lens member 53 (position indicated by a black circle in FIG. 46). Specifically, assuming that the distance in the thickness direction (vertical direction in FIG. 46) between the center of the light-emitting unit 51 and the center of the wavelength selection unit 52 is denoted as LL₁, and that the distance in a thickness direction between the center of the wavelength selection unit 52 and the center of the lens member 53 is denoted as LL₂, it is preferable that

$${D}_{0} > {d}_{0} > 0$$

is satisfied, and with manufacturing variations being taken into consideration,

$${d}_{0} : {D}_{0} = L {L}_{1} : ( {LL}_{1} + {LL}_{2} )$$

is satisfied.

Here, the thickness direction indicates the thickness direction of the light-emitting unit 51, the wavelength selection unit 52, and the lens member 53.

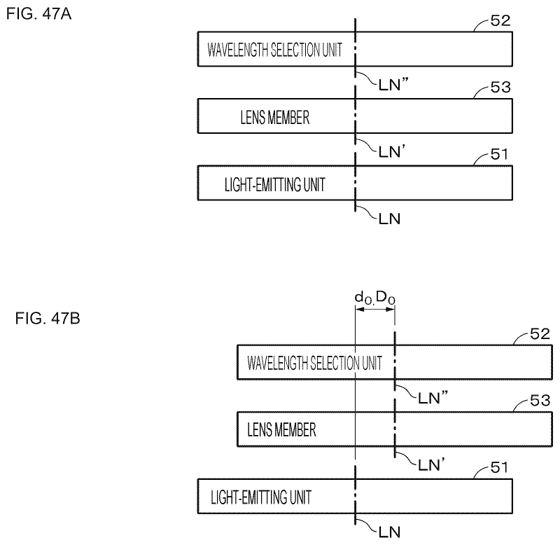

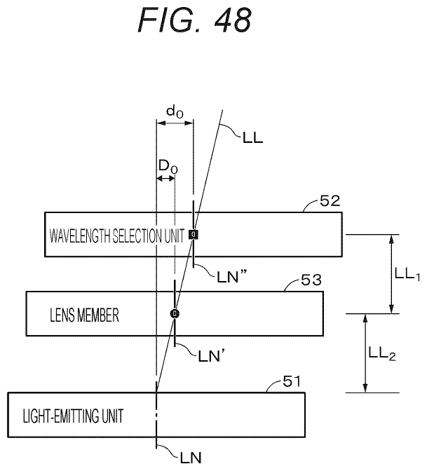

Hereinafter, with reference to FIGS. 47A, 47B, and 48, a relationship among the normal lines each passing through the center of each unit in a case where the light-emitting unit 51, the lens member 53, and the wavelength selection unit 52 are disposed in this order will be described.

As illustrated in FIG. 47A, it may be configured that the normal line LN passing through the center of the light-emitting unit 51, the normal line LN″ passing through the center of the wavelength selection unit 52, and the normal line LN′ passing through the center of the lens member 53 coincide with each other. That is, D₀>0 and d₀=0 may be satisfied.

As illustrated in FIG. 47B, the normal line LN passing through the center of the light-emitting unit 51 need not coincide with the normal line LN″ passing through the center of the wavelength selection unit 52 and the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 48, it may be configured that the normal line IN passing through the center of the light-emitting unit 51, the normal line LN″ passing through the center of the wavelength selection unit 52, and the normal line LN′ passing through the center of the lens member 53 do not coincide with each other. Here, the center of the lens member 53 (the position indicated by a black circle in FIG. 48) is preferably located on a straight line LL connecting the center of the light-emitting unit 51 and the center of the wavelength selection unit 52 (position indicated by a black square in FIG. 48). Specifically, assuming that the distance in the thickness direction (vertical direction in FIG. 48) between the center of the light-emitting unit 51 and the center of the lens member 53 is denoted as LL₂, and that the distance in the thickness direction between the center of the lens member 53 and the center of the wavelength selection unit 52 is denoted as LL₁, it is preferable that

$${d}_{0} > {D}_{0} > 0$$

is satisfied, and with manufacturing variations being taken into consideration,

$${D}_{0} : {d}_{0} = L {L}_{2} : ( {LL}_{1} + {LL}_{2} )$$

is satisfied.

Here, the thickness direction indicates the thickness direction of the light-emitting unit 51, the wavelength selection unit 52, and the lens member 53.

### 9. Example of Resonator Structure

The pixel used in the above-described display device according to the present disclosure may have a configuration including a resonator structure that resonates light generated by the light-emitting element. Hereinafter, the resonator structure will be described with reference to the drawings. Furthermore, in the following description, the second surface of each layer may be referred to as upper surface.

### Resonator Structure: First Example

FIG. 49A is a schematic cross-sectional view for describing a first example of the resonator structure. Note that, in the following description, the light-emitting elements provided corresponding to the subpixels 10R, 10G, and 10B may be collectively referred to as light-emitting element 12 in a case where they are collectively referred to without being particularly distinguished. The light-emitting elements provided corresponding to the subpixels 10R, 10G, and 10B may be referred to as light-emitting elements 12R, 12G, and 12B, respectively.

Portions of the OLED layer 122 corresponding to the subpixels 10R, 10G, and 10B may be referred to as OLED layer 122R, OLED layer 122G, and OLED layer 122B, respectively. The light-emitting element is the light-emitting element 12W in the first embodiment or the light-emitting elements 12R, 12G, and 12B in the modification. The light-emitting element may be the light-emitting elements 12W in the second to fifth embodiments.

In the first example, the first electrode 121 is formed with a common film thickness across the light-emitting elements 12. This similarly applies to the second electrode 123.

A reflector 71 is arranged below the first electrode 121 of the light-emitting element 12 with an optical adjustment layer 72 interposed therebetween. A resonator structure that causes resonance of light generated by the OLED layer 122 is formed between the reflector 71 and the second electrode 123. In the following description, the optical adjustment layers 72 provided corresponding to the subpixels 10R, 10G, and 10B may be referred to as optical adjustment layers 72R, 72G, and 72B, respectively.

The reflector 71 is formed with a common film thickness across the light-emitting elements 12. The film thickness of the optical adjustment layer 72 varies in a manner that depends on a color to be displayed by the pixel. Since the optical adjustment layers 72R, 72G, and 72B have different film thicknesses, it is possible to set an optical distance that causes optimum resonance for a wavelength of light corresponding to the color to be displayed.

In the example illustrated in FIG. 49A, the reflectors 71 are arranged to make their respective upper surfaces flush with each other across the light-emitting elements 12R, 12G, and 12B. As described above, since the film thickness of the optical adjustment layer 72 varies in a manner that depends on the color to be displayed by the pixel, the position of the upper surface of the second electrode 123 varies in a manner that depends on the types of the light-emitting elements 12R, 12G, and 12B.

The reflector 71 can include a metal such as aluminum (Al), silver (Ag), or copper (Cu), or an alloy containing these as main components, for example.

The optical adjustment layer 72 can include an inorganic insulating material such as silicon nitride (SiNₓ), silicon oxide (SiOₓ), or silicon oxynitride (SiOₓN_{y}), or an organic resin material such as acrylic resin or polyimide resin. The optical adjustment layer 72 may be a single layer, or may be a multilayer film including the plurality of materials. Furthermore, the number of layers may vary in a manner that depends on the type of the light-emitting element 12.

The first electrode 121 can include a transparent conductive material such as indium tin oxide (ITO), indium zinc oxide (IZO), or zinc oxide (ZnO).

The second electrode 123 needs to function as a semi-transparent reflective film. The second electrode 123 can include magnesium (Mg), silver (Ag), a magnesium-silver alloy (MgAg) containing these materials as main components, an alloy containing an alkali metal or an alkaline earth metal, or the like.

### Resonator Structure: Second Example

FIG. 49B is a schematic cross-sectional view for describing a second example of the resonator structure.

In the second example as well, the first electrode 121 and the second electrode 123 are each formed with a common film thickness across the light-emitting elements 12.

In addition, in the second example as well, the reflector 71 is arranged below the first electrode 121 of the light-emitting element 12 with the optical adjustment layer 72 interposed therebetween. A resonator structure that causes resonance of light generated by the OLED layer 122 is formed between the reflector 71 and the second electrode 123. Similarly to the first example, the reflector 71 is formed with a common film thickness across the light-emitting elements 12, and the film thickness of the optical adjustment layer 72 varies in a manner that depends on the color to be displayed by the pixel.

In the first example illustrated in FIG. 49A, the reflectors 71 are arranged to make their respective upper surfaces flush with each other across the light-emitting elements 12_{R}, 12_{G}, and 12_{B}, and the position of the upper surface of the second electrode 123 varies in a manner that depends on the types of the light-emitting elements 12_{R}, 12_{G}, and 12_{B}.

On the other hand, in the second example illustrated in FIG. 49B, the second electrodes 123 are arranged to make their respective upper surfaces flush with each other across the light-emitting elements 12_{R}, 12_{G}, and 12_{B}. In order to make the upper surfaces of the second electrodes 123 flush with each other, in the light-emitting elements 12_{R}, 12_{G}, and 12_{B}, the reflectors 71 are arranged such that the positions of their respective upper surfaces vary in a manner that depends on the types of the light-emitting elements 12_{R}, 12_{G}, and 12_{B}. Therefore, the lower surfaces of the reflectors 71 (in other words, the upper surfaces of the underlayers (insulating layers) 73) form a stair shape according to the types of the light-emitting elements 12.

Materials and the like constituting the reflector 71, the optical adjustment layer 72, the first electrode 121, and the second electrode 123 are similar to those described in the first example, and thus the description thereof will be omitted.

### Resonator Structure: Third Example

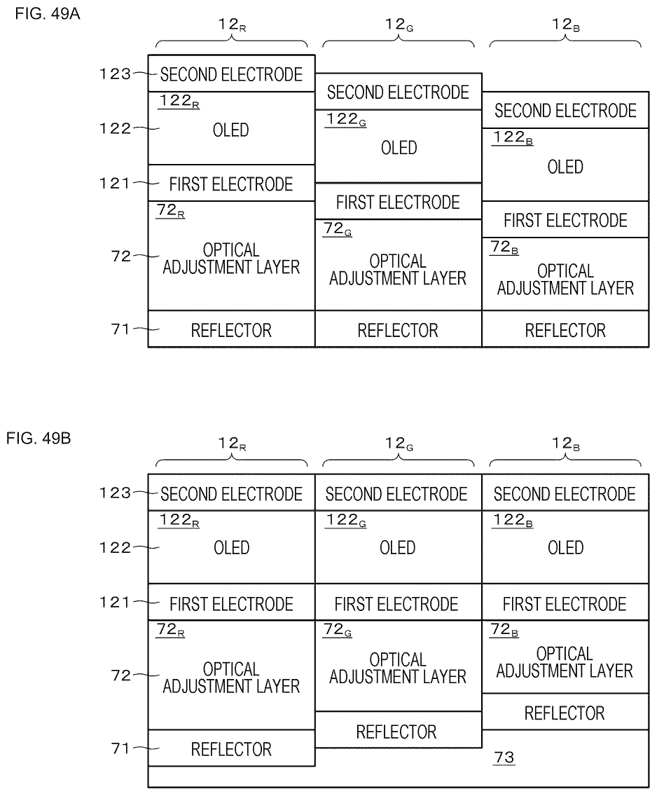

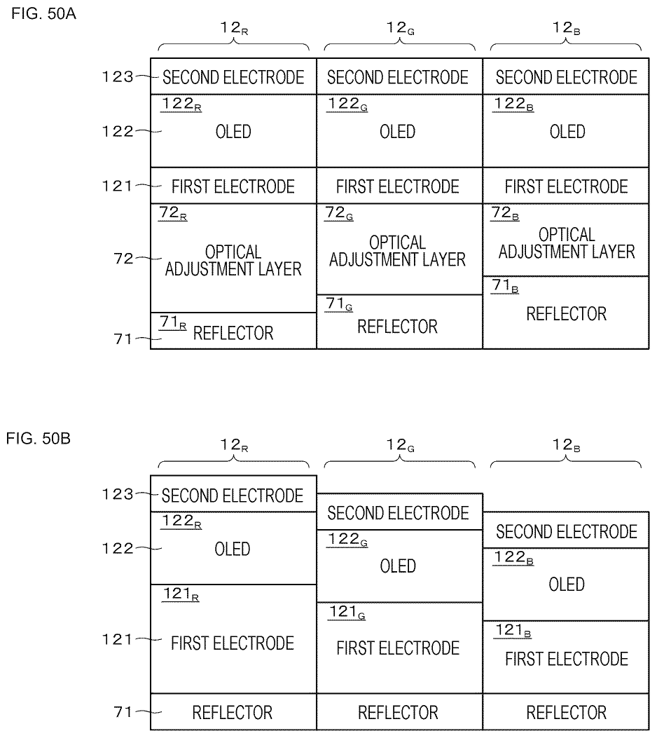

FIG. 50A is a schematic cross-sectional view for describing a third example of the resonator structure. In the following description, the reflectors 71 provided corresponding to the subpixels 10R, 10G, and 10B may be referred to as reflectors 71_{R}, 71_{G}, and 71_{B}, respectively.

In the third example as well, the first electrode 121 and the second electrode 123 are each formed with a common film thickness across the light-emitting elements 12.

In addition, in the third example as well, the reflector 71 is arranged below the first electrode 121 of the light-emitting element 12 with the optical adjustment layer 72 interposed therebetween. A resonator structure that causes resonance of light generated by the OLED layer 122 is formed between the reflector 71 and the second electrode 123. Similarly to the first and the second examples, the film thickness of the optical adjustment layer 72 varies in a manner that depends on the color to be displayed by the pixel. Then, similarly to the second example, the second electrodes 123 are arranged to make their respective upper surfaces flush with each other across the light-emitting elements 12_{R}, 12_{G}, and 12_{B}.

In the second example illustrated in FIG. 49B, to make the upper surfaces of the second electrodes 123 flush with each other, the lower surfaces of the reflectors 71 form a stair shape according to the types of the light-emitting elements 12.

On the other hand, in the third example illustrated in FIG. 50A, the film thickness of the reflector 71 is set to vary in a manner that depends on the types of the light-emitting elements 12_{R}, 12_{G}, and 12_{B}. More specifically, the film thickness is set so that the lower surfaces of the reflectors 71_{R}, 71_{G}, and 71_{B} are flush with each other.

Materials and the like constituting the reflector 71, the optical adjustment layer 72, the first electrode 121, and the second electrode 123 are similar to those described in the first example, and thus the description thereof will be omitted.

### Resonator Structure: Fourth Example

FIG. 50B is a schematic cross-sectional view for describing a fourth example of the resonator structure. In the following description, the first electrodes 121 provided corresponding to the subpixels 10R, 10G, and 10B will be referred to as first electrodes 121_{R}, 121_{G}, and 121_{B}, respectively.

In the first example illustrated in FIG. 49A, the first electrode 121 and the second electrode 123 of each light-emitting element 12 are formed with a common film thickness. In addition, the reflector 71 is arranged below the first electrode 121 of the light-emitting element 12 with the optical adjustment layer 72 interposed therebetween.

On the other hand, in the fourth example illustrated in FIG. 50B, the optical adjustment layer 72 is omitted, and the film thickness of the first electrode 121 is set to vary in a manner that depends on the types of the light-emitting elements 12_{R}, 12_{G}, and 12_{B}.

The reflector 71 is formed with a common film thickness across the light-emitting elements 12. The film thickness of the first electrode 121 varies in a manner that depends on the color to be displayed by the pixel. Since the first electrodes 121_{R}, 121_{G}, and 121_{B} have different film thicknesses, it is possible to set an optical distance that causes optimum resonance for a wavelength of light according to the color to be displayed.

Materials and the like constituting the reflector 71, the optical adjustment layer 72, the first electrode 121, and the second electrode 123 are similar to those described in the first example, and thus the description thereof will be omitted.

### Resonator Structure: Fifth Example

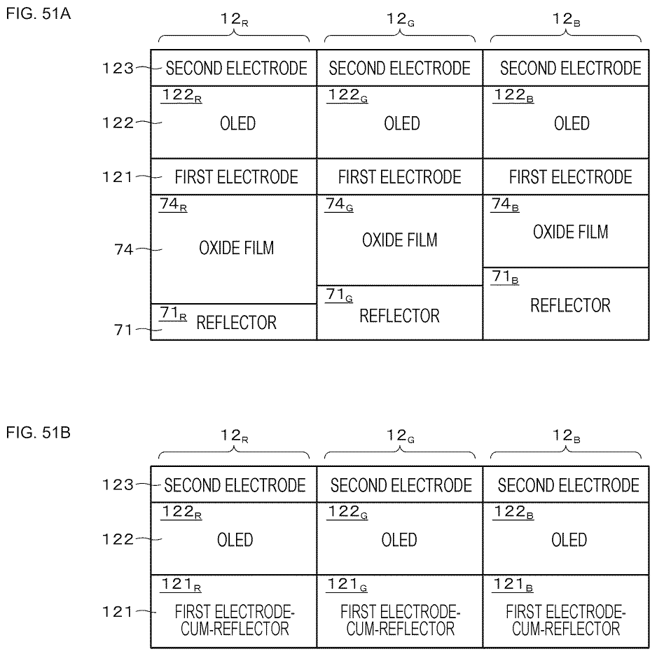

FIG. 51A is a schematic cross-sectional view for describing a fifth example of the resonator structure.

In the first example illustrated in FIG. 49A, the first electrode 121 and the second electrode 123 are each formed with a common film thickness across the light-emitting elements 12.

In addition, the reflector 71 is arranged below the first electrode 121 of the light-emitting element 12 with the optical adjustment layer 72 interposed therebetween.

On the other hand, in the fifth example illustrated in FIG. 51A, the optical adjustment layer 72 is omitted, and instead, an oxide film 74 is formed on a surface of the reflector 71. The film thickness of the oxide film 74 is set to vary in a manner that depends on the types of the light-emitting elements 12_{R}, 12_{G}, and 12_{B}. In the following description, the oxide films 74 provided corresponding to the subpixels 10R, 10G, and 10B are referred to as oxide films 74_{R}, 74_{G}, and 74_{B}, respectively.

The film thickness of the oxide film 74 varies in a manner that depends on the color to be displayed by the pixel. Since the oxide films 74_{R}, 74_{G}, and 74_{B} have different film thicknesses, it is possible to set an optical distance that causes optimum resonance for a wavelength of light according to the color to be displayed.

The oxide film 74 is a film obtained by oxidizing the surface of the reflector 71, and includes, for example, aluminum oxide, tantalum oxide, titanium oxide, magnesium oxide, zirconium oxide, or the like. The oxide film 74 functions as an insulating film for adjusting the optical path length (optical distance) between the reflector 71 and the second electrode 123.

The oxide films 74 having film thicknesses that vary in a manner that depends on the types of the light-emitting elements 12_{R}, 12_{G}, and 12_{B} can be formed, for example, as follows.

First, an electrolytic solution is filled in a container, and a substrate on which the reflector 71 is formed is immersed in the electrolytic solution. Furthermore, an electrode is arranged to face the reflector 71.

Thus, a positive voltage is applied to the reflector 71 with reference to the electrode to anodize the reflector 71. A film thickness of the oxide film obtained as a result of the anodization is proportional to a voltage value for the electrode. Therefore, the anodization is performed with a voltage determined according to the types of the light-emitting elements 12 applied to each of the reflectors 71_{R}, 71_{G}, and 71_{B}. Thus, the oxide films 74 having different film thicknesses can be collectively formed.

Materials and the like constituting the reflector 71, the first electrode 121, and the second electrode 123 are similar to those described in the first example, and thus, the description thereof will be omitted.

### Resonator Structure: Sixth Example

FIG. 51B is a schematic cross-sectional view for describing a sixth example of the resonator structure.

In the sixth example, the light-emitting element 12 includes a stack of the first electrode 121, the OLED layer 122, and the second electrode 123. However, in the sixth example, the first electrode 121 is formed to function as both an electrode and a reflector. The first electrode (-cum-reflector) 121 includes a material having an optical constant selected according to the types of the light-emitting elements 12_{R}, 12_{G}, and 12_{B}. Since a phase shift caused by the first electrode (-cum-reflector) 121 varies, it is possible to set an optical distance that causes optimum resonance for a wavelength of light according to the color to be displayed.

The first electrode (-cum-reflector) 121 can include pure metal such as aluminum (Al), silver (Ag), gold (Au), or copper (Cu), or an alloy containing these as main components. For example, the first electrode (-cum-reflector) 121_{R} of the light-emitting element 12_{R} can include copper (Cu), and the first electrode (-cum-reflector) 121_{G} of the light-emitting element 12_{G} and the first electrode (-cum-reflector) 121_{B} of the light-emitting element 12_{B} can include aluminum.

Materials and the like constituting the second electrode 123 are similar to those described in the first example, and thus the description thereof will be omitted.

### Resonator Structure: Seventh Example

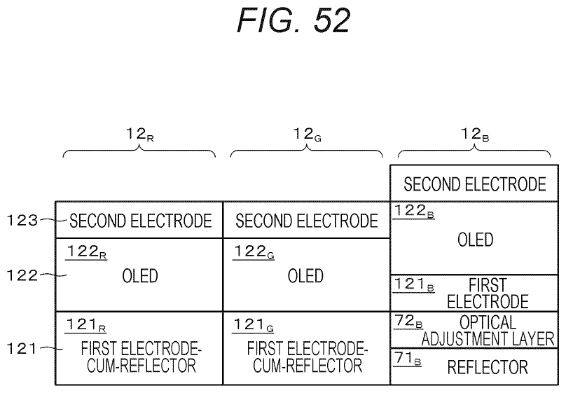

FIG. 52 is a schematic cross-sectional view for describing a seventh example of the resonator structure.

The seventh example basically has a configuration where the sixth example is applied to the light-emitting elements 12_{R} and 12_{G}, and the first example is applied to the light-emitting elements 12_{B}. With this configuration as well, it is possible to set an optical distance that causes optimum resonance for a wavelength of light according to the color to be displayed.

The first electrodes (-cum-reflectors) 121_{R} and 121_{G} used for the light-emitting elements 12_{R} and 12_{G} can include pure metal such as aluminum (Al), silver (Ag), gold (Au), or copper (Cu), or an alloy containing these as main components.

Materials and the like constituting the reflector 71_{B}, the optical adjustment layer 72_{B}, and the first electrode 121_{B} used for the light-emitting element 12_{B} are similar to those described in the first example, and thus the description thereof will be omitted.

### 10. Example of Leak Suppression Structure

The OLED layers 122W of the display devices 101, 102, 103, 104, and 105 according to the first, second, third, fourth, and fifth embodiments and the display devices 101, 102A, 103A, 104A, and 105A (hereinafter, referred to as a “display device 101 and the like according to the first embodiment”) according to modifications thereof are connected between the light-emitting elements 12W adjacent in the in-plane direction of the first surface of the drive substrate 11, and are layers common to the plurality of light-emitting elements 12W. Therefore, in the display device 101 and the like according to the first embodiment, there is a possibility that current leakage occurs between the adjacent light-emitting elements 12W. Hereinafter, an example of a leakage suppression structure for suppressing current leakage between the light-emitting elements 12W will be described.

As described in the first embodiment, the OLED layer 122W may be an OLED layer having a single-layer light-emitting unit U as illustrated in FIG. 74A, or may be an OLED layer (tandem structure) having two-layer light-emitting units U1 and U2 as illustrated in FIG. 74B, or may be an OLED layer having a structure other than these. The OLED layer 122W including a single-layer light-emitting unit U has, for example, a configuration in which a hole injection layer 1221, a hole transport layer 1222, a red light-emitting layer 1220R, a light emission separation layer 1223, a blue light-emitting layer 1220B, a green light-emitting layer 1220G, an electron transport layer 1224, and an electron injection layer 1225 are stacked in this order from the first electrode 121 toward the second electrode 123. The OLED layer including two light-emitting units U1 and U2 has, for example, a configuration in which a hole injection layer 1221, a hole transport layer 1222, a blue light-emitting layer 1220B, an electron transport layer 1226, a charge generation layer 1227, a hole transport layer 1228, a yellow light-emitting layer 1220Y, an electron transport layer 1224, and an electron injection layer 1225 are stacked in this order from the first electrode 121 toward the second electrode 123. Note that, in the following first to seventh examples, an example in which the OLED layer 122W includes the two-layer light-emitting units U1 and U2 will be described.

### Leak Suppression Structure: First Example

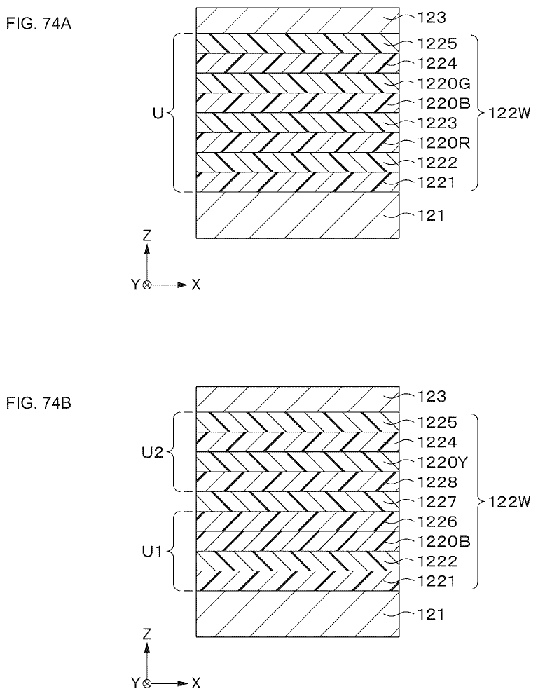

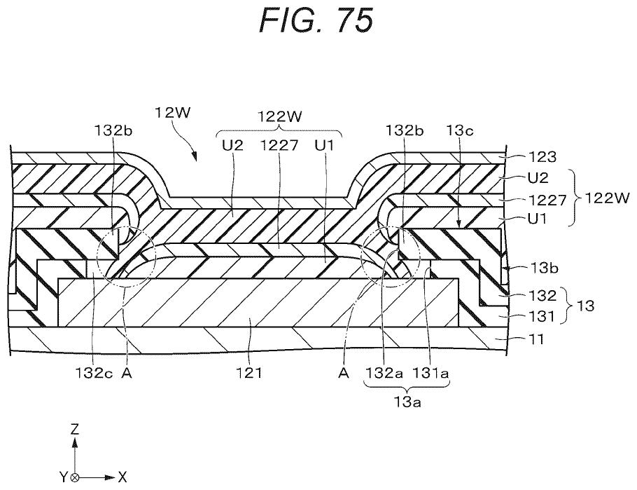

FIG. 75 is a cross-sectional view of a first example of the leak suppression structure. Note that, in FIG. 75, illustration of a layer above the second electrode 123 is omitted. Similarly, in the cross-sectional views for describing the leak suppression structures of the second example to the ninth example, illustration of the layer above the second electrode 123 is omitted.

The insulating layer 13 has an opening 13a on each of the first electrodes 121, and covers from the peripheral edge portion of the first surface of the first electrode 121 to the side surface (end surface) of the first electrode 121. Specifically, the insulating layer 13 includes a side wall portion 13b and an extension portion 13c. The side wall portion 13b is erected perpendicularly to the first surface of the drive substrate 11 and covers the side surface of the first electrode 121. The extension portion 13c extends from an upper end of an inner peripheral surface of the side wall portion 13b toward the center of the first surface of the first electrode 121 and covers the peripheral edge portion of the first surface of the first electrode 121.

An inner peripheral portion of the opening 13a of the insulating layer 13 has a protruding portion 132b having an eaves shape protruding toward the center of the opening 13a. The protruding portion 132b is separated from the first surface of the first electrode 121. The protruding portion 132b is preferably provided over the entire circumference of the peripheral edge portion of the opening 13a, but may be provided on a part of the entire circumference of the peripheral edge portion of the opening 13a.

The light-emitting unit U1 and the charge generation layer 1227 included in the OLED layer 122W are cut or increased in resistance by the protruding portion 132b (region A illustrated in FIG. 75). Thus, current leakage between the adjacent light-emitting elements 12W can be suppressed. Here, the increase in resistance means that the light-emitting unit U1 and the charge generation layer 1227 have an ultra-thin film thickness at the protruding portion 132b to thereby increase the resistance. Cutting or an increase in resistance of the light-emitting unit U1 and the charge generation layer 1227 by the protruding portion 132b can occur due to a shadowing effect of the protruding portion 132b at the time of forming the OLED layer 122W. A gap 132c may be formed between the protruding portion 132b and the first electrode 121.

The insulating layer 13 has a first insulating layer 131 and a second insulating layer 132 in order on the first surface of the drive substrate 11 and the first surface of the first electrode 121. The first insulating layer 131 has a plurality of first openings 131a. The second insulating layer 132 has a plurality of second openings 132a. The opening 13a includes a first opening 131a and a second opening 132a that overlap each other. An inner peripheral portion of the second opening 132a of the second insulating layer 132 protrudes toward the inside of the opening 13a more than an inner peripheral portion of the first opening 131a of the first insulating layer 131 to form the protruding portion 132b.

### Leak Suppression Structure: Second Example

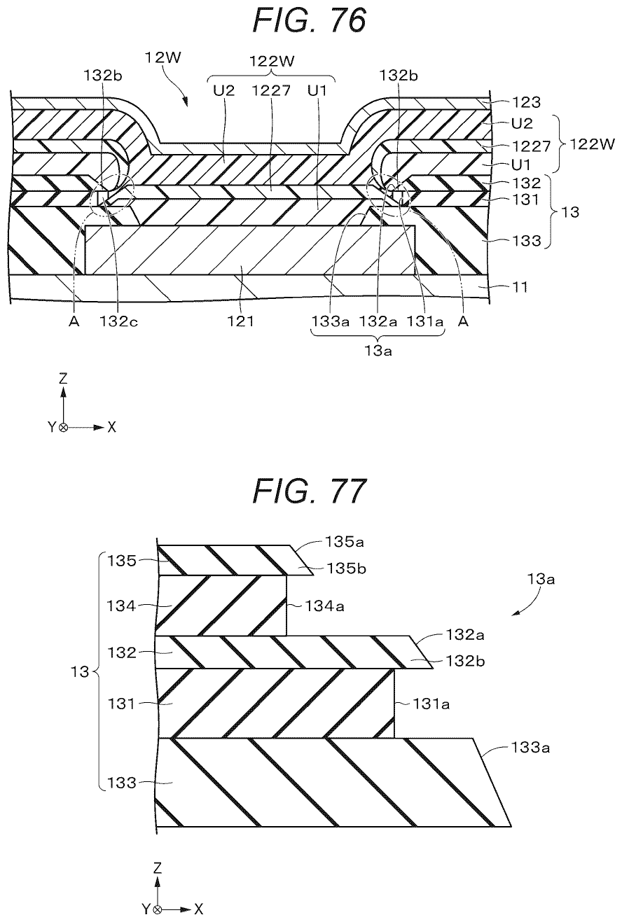

FIG. 76 is a cross-sectional view of a second example of the leak suppression structure. The second example is different from the first example in that the insulating layer 13 includes a third insulating layer 133 in addition to the first insulating layer 131 and the second insulating layer 132.

The third insulating layer 133 is provided between the drive substrate 11 and the first insulating layer 131 and between the first electrode 121 and the first insulating layer 131. The third insulating layer 133 has a third opening 133a on the first surface of the first electrode 121. In the second example, the opening 13a is constituted by the first opening 131a, the second opening 132a, and the third opening 133a overlapping each other. An inner peripheral portion of the third opening 133a protrudes toward the inside of the opening 13a more than the inner peripheral portion of the first opening 131a. The gap 132c may be formed between the protruding portion 132b and the third insulating layer 133.

### Leak Suppression Structure: Third Example and Fourth Example

In the first example and the second example, an example in which the inner peripheral portion of the opening 13a of the insulating layer 13 has one protruding portion 132b has been described. However, the number of protruding portions included in the inner peripheral portion of the opening 13a of the insulating layer 13 is not limited to these examples, and the inner peripheral portion of the opening 13a of the insulating layer 13 may include two or more protruding portions. Hereinafter, an example (third example) in which the inner peripheral portion of the opening 13a of the insulating layer 13 has two protruding portions and an example (fourth example) in which the inner peripheral portion of the opening 13a of the insulating layer 13 has three protruding portions will be described.

FIG. 77 is a cross-sectional view of a third example of the leak suppression structure. The third example is different from the second example in that the insulating layer 13 has a fourth insulating layer 134 and a fifth insulating layer 135 in this order on the first surface of the second insulating layer 132, and the inner peripheral portion of the opening 13a of the insulating layer 13 has two protruding portions 132b and 135b each having an eaves shape.

The light-emitting unit U1 and the charge generation layer 1227 included in the OLED layer 122W are cut or increased in resistance by the protruding portion 132b and the protruding portion 135b. The protruding portion 135b is provided at a position higher than the protruding portion 132b with reference to the first surface of the first electrode 121, and is separated from the first surface of the second insulating layer 132. The protruding portion 135b retreats in a direction away from the center of the opening 13a with respect to the protruding portion 132b.

The fourth insulating layer 134 has a fourth opening 134a. The fifth insulating layer 135 has a fifth opening 135a. In the third example, the opening 13a is constituted by the first opening 131a, the second opening 132a, the third opening 133a, the fourth opening 134a, and the fifth opening 135a that overlap each other. An inner peripheral portion of the fourth opening 134a retreats in a direction away from the center of the opening 13a more than the inner peripheral portion of the second opening 132a and an inner peripheral portion of the fifth opening 135a. The inner peripheral portion of the fifth opening 135a protrudes more toward the inside of the opening 13a than the fourth opening 134a to form the protruding portion 135b.

FIG. 78 is a cross-sectional view of a fourth example of the leak suppression structure. The fourth example is different from the third example in that the insulating layer 13 sequentially includes a sixth insulating layer 136 and a seventh insulating layer 137 on the first surface of the fifth insulating layer 135, and the inner peripheral portion of the opening 13a of the insulating layer 13 includes three protruding portions 132b, 135b, and 137b each having an eaves shape.

The light-emitting unit U1 and the charge generation layer 1227 included in the OLED layer 122W are cut or increased in resistance by the protruding portion 132b, the protruding portion 135b, and the protruding portion 137b. The protruding portion 137b is provided at a position higher than the protruding portion 135b with reference to the first surface of the first electrode 121, and is separated from the first surface of the fifth insulating layer 135. The protruding portion 137b retreats in a direction away from the center of the opening 13a with respect to the protruding portion 135b.

The sixth insulating layer 136 has a sixth opening 136a. The seventh insulating layer 137 has a seventh opening 137a. In the fourth example, the opening 13a includes the first opening 131a, the second opening 132a, the third opening 133a, the fourth opening 134a, the fifth opening 135a, the sixth opening 136a, and the seventh opening 137a that overlap each other. An inner peripheral portion of the sixth opening 136a retreats in a direction away from the center of the opening 13a more than an inner peripheral portion of the fifth opening 135a and an inner peripheral portion of the seventh opening 137a. The inner peripheral portion of the seventh opening 137a protrudes from the sixth opening 136a toward the inside of the opening 13a to form the protruding portion 137b.

### Leak Suppression Structure: Fifth Example

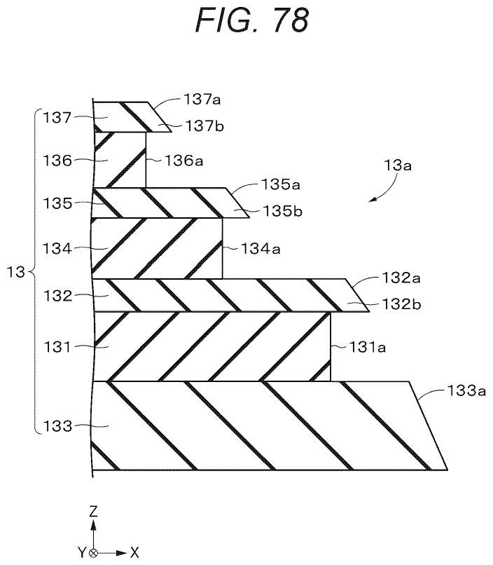

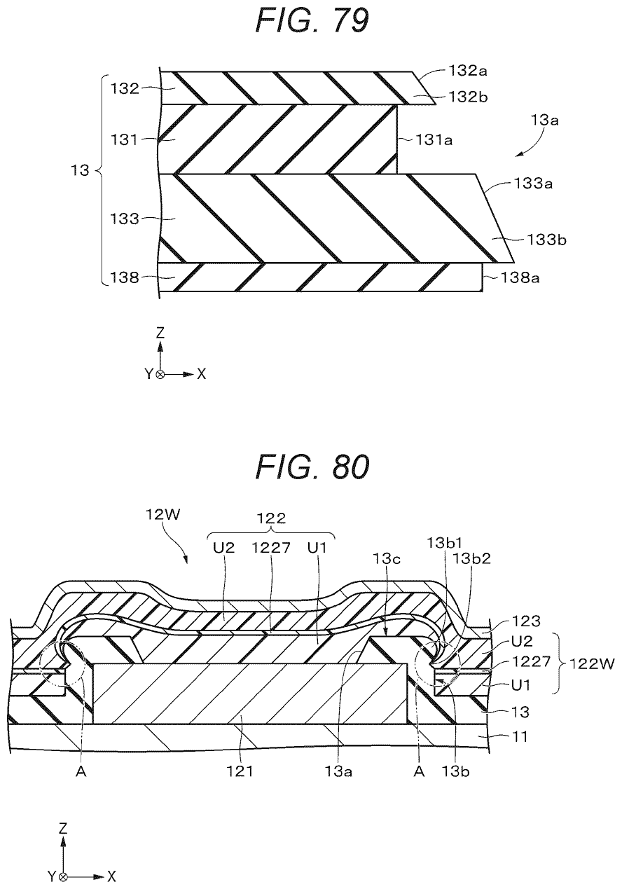

FIG. 79 is a cross-sectional view of a fifth example of the leak suppression structure. The fifth example is different from the second example in that the insulating layer 13 has an eighth insulating layer 138 in addition to the first insulating layer 131, the second insulating layer 132, and the third insulating layer 133, and the inner peripheral portion of the opening 13a of the insulating layer 13 has two protruding portions 132b and 133b each having an eaves shape.

The light-emitting unit U1 and the charge generation layer 1227 included in the OLED layer 122W are cut or increased in resistance by the protruding portion 132b and the protruding portion 133b. The protruding portion 133b projects more toward the inside of the opening 13a than the protruding portion 132b. The protruding portion 133b is provided at a position lower than the protruding portion 132b with reference to the first surface of the first electrode 121. The protruding portion 133b is separated from the first surface of the first electrode 121.

The eighth insulating layer 138 is provided between the drive substrate 11 and the third insulating layer 133 and between the first electrode 121 and the third insulating layer 133. The eighth insulating layer 138 has an eighth opening 138a. In the fifth example, the opening 13a is constituted by the first opening 131a, the second opening 132a, the third opening 133a, and the eighth opening 138a that overlap each other. The inner peripheral portion of the third opening 133a of the third insulating layer 133 projects more toward the inside of the opening 13a than an inner peripheral portion of the eighth opening 138a of the eighth insulating layer 138 to form a protruding portion 133b.

### Leak Suppression Structure: Sixth Example

FIG. 80 is a cross-sectional view of a sixth example of the leak suppression structure. The sixth example is different from the first example in that the insulating layer 13 has a protruding portion 13b1 on an outer peripheral portion of the side wall portion 13b instead of having the protruding portion 132b on the inner peripheral portion of the opening 13a. FIG. 80 illustrates an example in which the insulating layer 13 has a single-layer structure, but may have a stacked structure of two or more layers.

The protruding portion 13b1 projects outward from the outer peripheral portion of the side wall portion 13b. A recess 13b2 is provided at a position separated downward by a predetermined distance from an upper end of the outer peripheral portion of the side wall portion 13b. By providing the recess 13b2 in the outer peripheral portion of the side wall portion 13b in this manner, the protruding portion 13b1 is configured at an upper end portion of the outer peripheral portion of the side wall portion 13b. The protruding portion 13b1 and the recess 13b2 are preferably provided over the entire circumference of the outer peripheral portion of the side wall portion 13b, but may be provided on a part of the entire circumference of the outer peripheral portion of the side wall portion 13b.

The light-emitting unit U1 and the charge generation layer 1227 included in the OLED layer 122W are cut or increased in resistance by the protruding portion 132b (region A illustrated in FIG. 80). Thus, current leakage between the adjacent light-emitting elements 12W can be suppressed.

In the sixth example, an example in which the outer peripheral portion of the side wall portion 13b has one protruding portion 13b1 and one recess 13b2 has been described. However, the number of the protruding portions 13b1 and the number of the recesses 13b2 included in the outer peripheral portion of the side wall portion 13b are not limited to this example, and the outer peripheral portion of the side wall portion 13b may include two or more protruding portions 13b1 and two or more recesses 13b2. In this case, two or more recesses 13b2 may be provided in order from the upper end to the lower end of the outer peripheral portion of the side wall portion 13b while being separated from each other by a predetermined distance.

### Leak Suppression Structure: Seventh Example

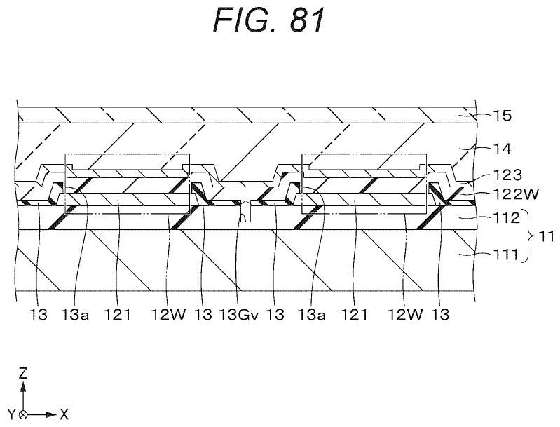

FIG. 81 is a cross-sectional view of a seventh example of the leak suppression structure. A groove 13Gv is provided between adjacent light-emitting elements 12W. The groove 13Gv may be provided between the light-emitting elements 12W adjacent in a predetermined direction (for example, the Y-axis direction), or may be provided so as to surround the light-emitting elements 12W. The groove 13Gv is formed over the insulating layer 13 and the insulating layer 112.

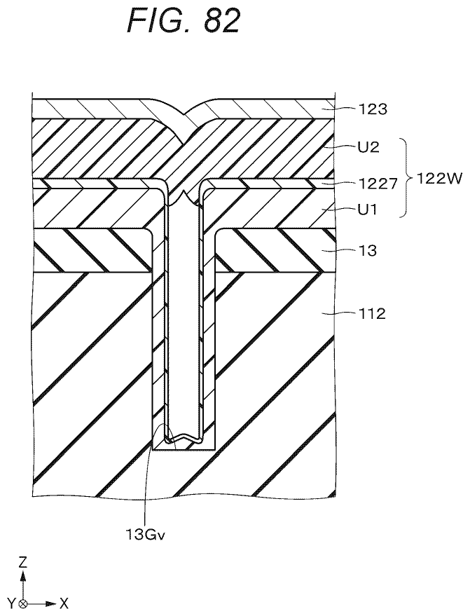

The light-emitting unit U1 and the charge generation layer 1227 included in the OLED layer 122W are cut or increased in resistance by the groove 13Gv. Thus, current leakage between the adjacent light-emitting elements 12W can be suppressed. Here, the increase in resistance means that, as illustrated in FIG. 82, the light-emitting unit U1 and the charge generation layer 1227 have an ultra-thin film thickness in the groove 13Gv to thereby increase the resistance. Among the layers included in the OLED layer 122W, the light-emitting unit U2 located above the charge generation layer 1227 straddles the groove 13Gv.

### Leak Suppression Structure: Eighth Example

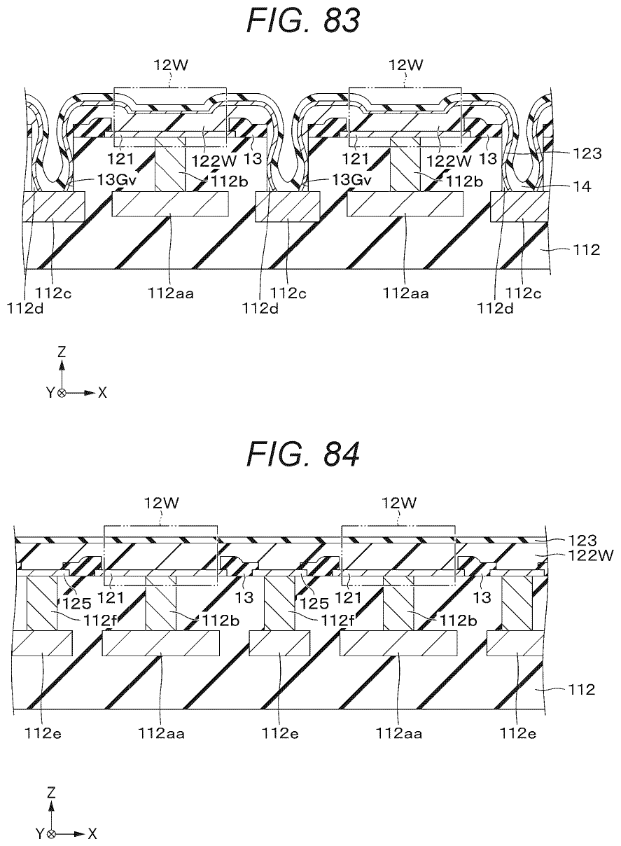

FIG. 83 is a cross-sectional view of an eighth example of the leak suppression structure. A plurality of wirings 112aa, a plurality of contact plugs 112b, and a plurality of contact electrodes 112c are provided in the insulating layer 112. Each contact plug 112b electrically connects the first electrode 121 and the wiring 112aa. A groove 13Gv is provided between adjacent light-emitting elements 12W. A bottom surface of the groove 13Gv is constituted by the first surface of the contact electrode 112c. An auxiliary electrode 112d is provided on a side surface of each groove 13Gv. The auxiliary electrode 112d is in contact with the first surface of the contact electrode 112c.

The OLED layer 122W is cut by the groove 13Gv. Although FIG. 83 illustrates an example in which the second electrode 123 is also cut by the groove 13Gv, the second electrode 123 may not be cut by the groove 13Gv and may be connected between the adjacent light-emitting elements 12W. The second electrode 123 is in contact with the auxiliary electrode 112d on the side surface of the groove 13Gv. Furthermore, the second electrode 123 is in contact with the contact electrode 112c on the bottom surface of the groove 13Gv.

In the eighth example, a leakage current can be drawn to the auxiliary electrode 112d and the contact electrode 112c between the adjacent light-emitting elements 12W. Therefore, current leakage between the adjacent light-emitting elements 12W can be suppressed.

### Leak Suppression Structure: Ninth Example

FIG. 84 is a cross-sectional view of a ninth example of the leak suppression structure. In the ninth example, the display device 101 includes a plurality of third electrodes 125. Similarly to the plurality of first electrodes 121, the plurality of third electrodes 125 is provided on the second surface side of the OLED layer 122W. Each of the third electrodes 125 is disposed between the adjacent first electrodes 121.

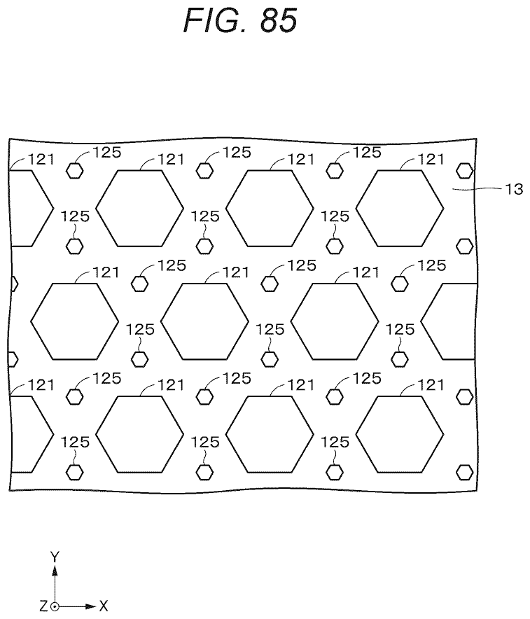

FIG. 85 is a plan view for describing the arrangement of the first electrode 121 and the third electrode 125. The plurality of third electrodes 125 is an island-shaped electrode group having a smaller area than the first electrode 121. The plurality of third electrodes 125 is regularly arranged at equal intervals from the first electrodes 121 adjacent to each other in plan view. From another point of view, the plurality of third electrodes 125 is arranged so as to be separated from and surround each of the first electrodes 121 by a predetermined distance in plan view.

A plurality of wirings 112aa, a plurality of wirings 112e, a plurality of contact plugs 112b, and a plurality of contact plugs 112f are provided in the insulating layer 112. Each contact plug 112b electrically connects the first electrode 121 and the wiring 112aa. Each contact plug 112f electrically connects the third electrode 125 and the wiring 112e.

The plurality of third electrodes 125 is connected to an internal circuit of the display device 101 via the contact plugs 112f, the wirings 112e, and the like, and are commonly set to a constant potential. Specifically, when a voltage is applied to the OLED layer 122W, the potential of the third electrode 125 is set to be smaller than a value obtained by adding a threshold voltage for the OLED layer 122W to the potential of the second electrode 123. Thus, even in a case where a voltage is applied to the OLED layer 122W by the first electrode 121 and the second electrode 123, and a leakage current is generated from the first electrode 121 due to this, the leakage current preferentially flows through the third electrode 125. Therefore, the leakage current is prevented from flowing from the first electrode 121 to the adjacent first electrode 121.

### Leak Suppression Structure: Other Examples

In the first example to the seventh example, the example in which the OLED layer 122W includes the two-layer light-emitting units U1 and U2 has been described. However, the configuration of the OLED layer 122W is not limited to this example, and the OLED layer 122W may have a single-layer light-emitting unit U or may have three or more layers of light-emitting units U.

In the first example to the seventh example, an example has been described in which the light-emitting unit U1 and the charge generation layer 1227 included in the OLED layer 122W are cut or increased in resistance by the protruding portions 132b, 133b, 135b, 137b, and 13bl and the grooves 13Gv (hereinafter referred to as protruding portion 132b, groove 13Gv, and the like). However, the layer cut or increased in resistance by the protruding portion 132b, the groove 13Gv, and the like is not limited to this example. For example, the hole injection layer 1221 or the hole transport layer 1222 included in the OLED layer 122W may be cut or increased in resistance by the protruding portion 132b, the groove 13Gv, and the like, and both the hole injection layer 1221 and the hole transport layer 1222 included in the OLED layer 122W may be cut or increased in resistance by the protruding portion 132b, the groove 13Gv, and the like. In a case where the OLED layer 122W includes three or more light-emitting units U, two or more light-emitting units U and two or more charge generation layers 1227 included in the OLED layer 122W may be cut or increased in resistance by the protruding portion 132b, the groove 13Gv, and the like.

### 11. Application Examples

### Electronic Apparatus

The display devices 101 according to the above-described first embodiment and modifications thereof may be provided in various electronic apparatuses. Similarly, the display devices 102, 103, 104, 105, 102A, 103A, 104A, and 105A (hereinafter referred to as a “display device 102 and the like according to the second embodiment”) according to the second to fifth embodiments and the modifications thereof may be provided in various electronic apparatuses. The display devices 101 according to the above-described first embodiment and modifications thereof are suitable for an apparatus that is particularly required to have high resolution and is enlarged and used near the eyes, such as an eyewear device such as a head-mounted display, or an electronic viewfinder of a video camera or a single-lens reflex camera. Similarly, the display device 102 and the like according to the second embodiment are suitable for the above-described electronic apparatus.

### Specific Example 1

FIGS. 53A and 53B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by a photographer on the front left side.

A monitor 314 is provided at a position shifted to the left side from the center of the back surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. The electronic viewfinder 315 includes any of the display devices 101 according to the above-described first embodiment and modifications thereof. The electronic viewfinder 315 may include any of the display device 102 and the like according to the second embodiment.

### Specific Example 2

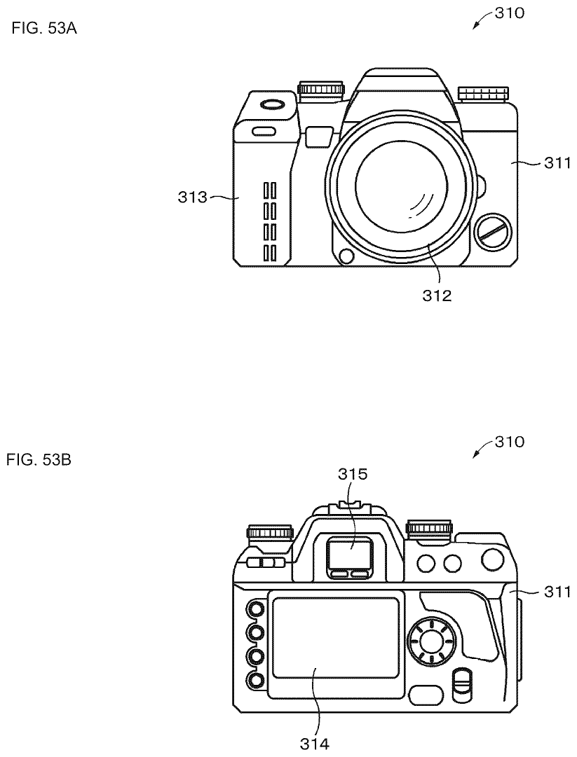

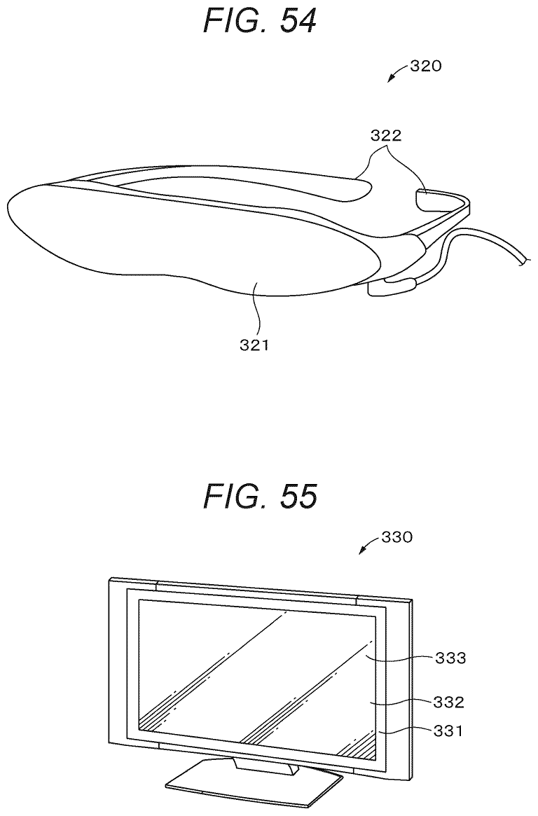

FIG. 54 illustrates an example of an external appearance of a head-mounted display 320. The head-mounted display 320 is an example of an eyewear device. The head-mounted display 320 includes, for example, ear hooking portions 322 for a user to wear the head-mounted display on the head, on both sides of a display unit 321 having a shape of eyeglasses. The display unit 321 includes any of the display devices 101 according to the above-described first embodiment and modifications thereof. The display unit 321 may include any of the display device 102 and the like according to the second embodiment.

### Specific Example 3

FIG. 55 illustrates an example of an external appearance of a television apparatus 330. The television apparatus 330 includes, for example, a video display screen unit 331 including a front panel 332 and a filter glass 333, and the video display screen unit 331 includes any of the display devices 101 according to the above-described first embodiment and modifications thereof. The video display screen unit 331 may include any of the display device 102 and the like according to the second embodiment.

### Specific Example 4

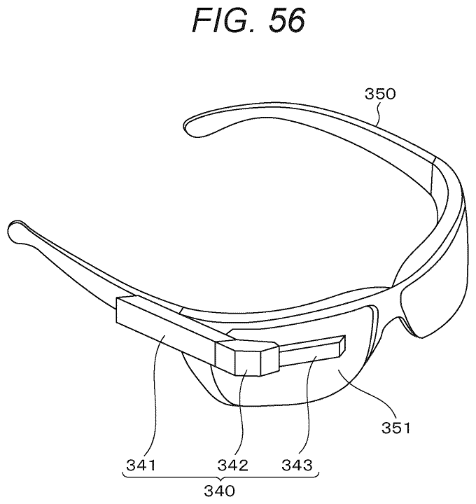

FIG. 56 illustrates an example of an external appearance of a see-through head-mounted display 340. The see-through head-mounted display 340 is an example of an eyewear device. The see-through head-mounted display 340 includes a main body 341, an arm 342, and a lens barrel 343.

The main body 341 is connected to the arm 342 and eyeglasses 350. Specifically, an end portion of the main body 341 in a long side direction is coupled to the arm 342, and one side of a side surface of the main body 341 is coupled to the eyeglasses 350 via a connecting member. Note that the main body 341 may be mounted directly on the head of the human body.

The main body 341 incorporates a control board for controlling operation of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In the see-through head-mounted display 340, the display unit of the main body 341 includes any of the display devices 101 according to the above-described first embodiment and modifications thereof. The display unit of the main body 341 may include any of the display device 102 and the like according to the second embodiment.

### Specific Example 5

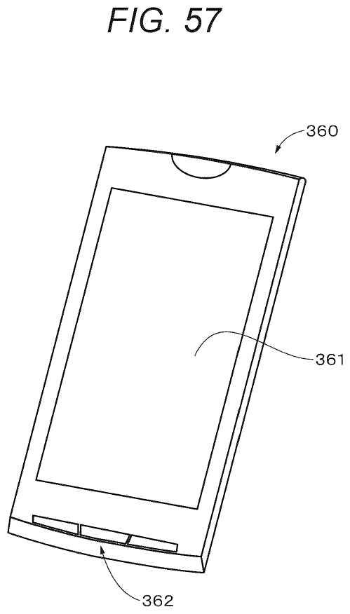

FIG. 57 illustrates an example of an external appearance of a smartphone 360. The smartphone 360 includes a display unit 361 that displays various kinds of information, an operation unit 362 including a button for receiving operation input from the user, and the like. The display unit 361 includes any of the display devices 101 according to the above-described first embodiment and modifications thereof. The display unit 361 may include any of the display device 102 and the like according to the second embodiment.

### Specific Example 6

The display devices 101 according to the above-described first embodiment and modifications thereof may be included in a vehicle or in various displays. Similarly, the display device 102 and the like according to the second embodiment may be included in a vehicle or in various displays.

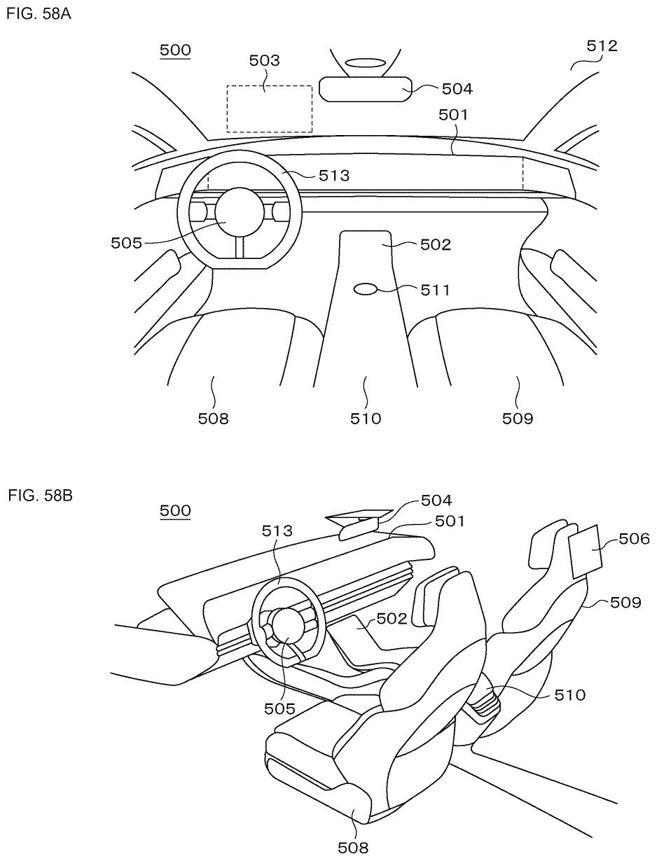

FIGS. 58A and 58B are diagrams illustrating an example of an internal configuration of a vehicle 500 provided with various displays. Specifically, FIG. 58A is a diagram illustrating an example of an internal state of the vehicle 500 from the rear to the front of the vehicle 500, and FIG. 58B is a diagram illustrating an example of an internal state of the vehicle 500 from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the display devices 101 according to the above-described first embodiment and modifications thereof. For example, all of these displays may include any of the display devices 101 according to the above-described first embodiment and modifications thereof. At least one of these displays may include any of the display device 102 and the like according to the second embodiment. For example, all of these displays may include any of the display device 102 and the like according to the second embodiment.

The center display 501 is disposed on the dashboard at a location facing a driver's seat 508 and a passenger's seat 509. FIGS. 58A and 58B illustrate an example of the center display 501 having a horizontally elongated shape extending from the driver's seat 508 side to the passenger's seat 509 side, but the screen size and placement location of the center display 501 are determined as appropriate. The center display 501 can display information sensed by various sensors. As a specific example, the center display 501 can display an image captured by an image sensor, an image of a distance to an obstacle present in front of or on a side of the vehicle 500, the distance being measured by a ToF sensor, a body temperature of the occupant detected by an infrared sensor, or the like. The center display 501 can be used to display at least one of safety-related information, operation-related information, lifelogs, health-related information, authentication/identification-related information, or entertainment-related information, for example.

The safety-related information is information such as doze sensing, looking-away sensing, sensing of mischief of a child riding together, and presence or absence of wearing of a seat belt, sensing of leaving of an occupant, and is information sensed by, for example, a sensor arranged on the back surface side of the center display 501 in an overlapping manner. The operation-related information detects gestures related to operations by the occupant by using the sensor. The sensed gestures may include operations of various types of equipment in the vehicle 500. For example, operations of air conditioning equipment, a navigation device, an audiovisual (AV) device, a lighting device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information is information obtained by estimating the health condition of the occupant on the basis of the body temperature of the occupant sensed by a sensor such as a temperature sensor. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information regarding a keyless entry function of performing face authentication by using a sensor, a function of automatically adjusting a seat height and position through face identification, and the like. The entertainment-related information includes information regarding a function of detecting, by using a sensor, operation information about an AV device being used by the occupant, and a function of recognizing the face of the occupant by using the sensor and providing content suitable for the occupant through the AV device.

The console display 502 can be used to display lifelog information, for example. The console display 502 is disposed near a shift lever 511 of a center console 510 between the driver's seat 508 and the passenger's seat 509. The console display 502 can also display information detected by various sensors. Furthermore, the console display 502 may display an image of the surroundings of the vehicle captured with an image sensor, or may display a distance image to an obstacle present in the surroundings of the vehicle.

The head-up display 503 is virtually displayed behind a windshield 512 in front of the driver's seat 508. The head-up display 503 can be used to display at least one of the safety-related information, the operation-related information, the lifelogs, the health-related information, the authentication/identification-related information, or the entertainment-related information, for example. Being virtually arranged in front of the driver's seat 508 in many cases, the head-up display 503 is suitable for displaying information directly related to the operations of the vehicle 500, such as the speed, the remaining amount of fuel (battery), and the like of the vehicle 500.

The digital rearview mirror 504 can not only display the rear of the vehicle 500 but can also display the state of the occupant in the rear seat, and thus, can be used to display, for example, lifelog information obtained by a sensor arranged on the back surface side of the digital rearview mirror 504 in an overlapping manner.

The steering wheel display 505 is arranged near the center of a steering wheel 513 of the vehicle 500. The steering wheel display 505 can be used to display at least one of the safety-related information, the operation-related information, the lifelogs, the health-related information, the authentication/identification-related information, or the entertainment-related information, for example. In particular, being located close to the driver's hands, the steering wheel display 505 is suitable for displaying lifelog information such as the body temperature of the driver, or for displaying information regarding operations of the AV device, the air conditioning equipment, or the like.

The rear entertainment display 506 is attached to the back surface side of the driver's seat 508 or the passenger's seat 509, and is for the occupant in the rear seat to enjoy viewing/listening. The rear entertainment display 506 can be used to display at least one of the safety-related information, the operation-related information, the lifelogs, the health-related information, the authentication/identification-related information, or the entertainment-related information, for example. In particular, being located in front of the occupant in the rear seat, the rear entertainment display 506 displays information related to the occupant in the rear seat. For example, information regarding the operation of the AV device or the air conditioning equipment may be displayed, or a result of measurement of the body temperature or the like of the occupant in the rear seat with a temperature sensor may be displayed on the display.

A sensor may be arranged on the back surface side of the display device 101 and the like in an overlapping manner, so that the distance to an object present in the surroundings can be measured. Optical distance measurement methods are roughly classified into a passive type and an active type. By the method of the passive type, distance measurement is performed by receiving light from an object, without projecting light from a sensor to the object. The methods of the passive type include a lens focus method, a stereo method, a monocular vision method, and the like. By the method of the active type, distance measurement is performed by projecting light to an object, and receiving reflected light from the object with a sensor to measure the distance. The methods of the active type include an optical radar method, an active stereo method, an illuminance difference stereo method, a moire topography method, an interference method, and the like. The display devices 101 according to the above-described first embodiment and modifications thereof can be applied to any of these methods of distance measurement. With a sensor arranged on the back surface side of the above-described display device 101 in an overlapping manner, distance measurement of the passive type or the active type described above can be performed. Similarly, any of the display device 102 and the like according to the second embodiment can be used in distance measurement by any of these methods.

### REFERENCE SIGNS LIST

10R, 10G, 10B, 10W Subpixel
10Px Pixel
11 Drive substrate
12R, 12G, 12B, 12W Light-emitting element
13 Insulating layer
14 Multilayer body
14L1 First lens portion
14LU1 First protrusion
14L2 Second lens portion
14LU2 Second protrusion
14L3 Third lens portion
15 Color filter
15FR Red filter portion
15FG Green filter portion
15FB Blue filter portion
16 Protective layer
17 Partition wall
18 Lens array
101, 102, 103, 104, 105, 102A, 103A, 104A, 105A Display device
11a Pad
20, 20a Optical system
20Ax Optical axis
21 Imaging lens
121 First electrode
122R, 122G, 122B, 122W OLED layer
123 Second electrode
124 Reflection layer
141 First layer
142 Second layer
143 Third layer
181 Lens
310 Digital still camera
320 Head-mounted display
330 Television apparatus
340 See-through head-mounted display
360 Smartphone
500 Vehicle
A1 Light-emitting region
A21 Formation region of first lens portion 14L1
A22 Non-formation region of first lens portion 14L1
A31 Formation region of second lens portion 14L2
A32 Non-formation region of second lens portion 14L2
RE1 Effective pixel region
RE2 Peripheral region

1. A display device comprising:
a plurality of light-emitting elements; and
a multilayer body covering the plurality of light-emitting elements, wherein
the multilayer body includes, in order, a first layer having a first refractive index n₁, a second layer having a second refractive index n₂ different from the first refractive index n₁, and a third layer having a third refractive index n₃ different from the second refractive index n₂,
the second layer includes a plurality of first lens portions and a plurality of second lens portions,
the plurality of first lens portions and the plurality of second lens portions are provided on different surfaces of the second layer,
the first lens portions are provided in one of a central portion and a peripheral portion of pixels, and the second lens portions are provided in another of the central portion and the peripheral portion of the pixels.

2. The display device according to claim 1, wherein
the plurality of first lens portions is provided on a first surface on a side of the first layer, the first lens portions each include at least one annular first protrusion and are located in the peripheral portion of the pixels,
the plurality of second lens portions is provided on a second surface on a side of the third layer, and
the second lens portions each include at least one annular second protrusion and are located in the central portion of the pixels.

3. The display device according to claim 2, wherein
the at least one annular first protrusion includes a plurality of annular first protrusions, and
the plurality of annular first protrusions is concentrically arranged.

4. The display device according to claim 2, wherein
the first lens portions are a concentric prism lens array, and
the second lens portions are a Fresnel lens, a spherical lens, or a frustum lens.

5. The display device according to claim 2, wherein
the second layer further includes a plurality of third lens portions,
the plurality of third lens portions is provided on the first surface, and each of the third lens portions is located in the central portion of the pixels.

6. The display device according to claim 1, wherein
the first lens portions and the second lens portions included in adjacent pixels among the pixels are parallel to an optical axis of the light-emitting element and symmetric with respect to a center line passing through a midpoint between the adjacent pixels.

7. The display device according to claim 1, wherein
the first refractive index n₁, the second refractive index n2, and the third refractive index n₃ satisfy n₁ and n₃<n₂.

8. The display device according to claim 1, wherein
a distance from a geometric center of each of the pixels to a boundary between a formation region of the first lens portions and a formation region of the second lens portions in an in-plane direction is equal to or less than 1 μm.

9. The display device according to claim 1, wherein
a formation region of the first lens portions and a formation region of the second lens portions overlap each other.

10. The display device according to claim 1, wherein
the multilayer body is configured to be capable of condensing incident light from the plurality of light-emitting elements toward an optical axis.

11. The display device according to claim 2, wherein
a width of a portion located on a center side of an effective pixel region in a formation region of the first lens portions decreases from a center toward an outer periphery of the effective pixel region.

12. The display device according to claim 2, wherein
the plurality of first lens portions includes a first lens portion in which a center of the first lens portion is shifted in a direction from an outer periphery toward a center of an effective pixel region with reference to a center of a light-emitting region of the pixel, and
a shift amount between the center of the light-emitting region of the pixel and the center of the first lens portion increases from the center toward the outer periphery of the effective pixel region.

13. The display device according to claim 2, wherein
the plurality of second lens portions includes a second lens portion in which a center of the second lens portion is shifted in a direction from an outer periphery toward a center of an effective pixel region with reference to a center of a light-emitting region of the pixel, and
a shift amount between the center of the light-emitting region of the pixel and the center of the second lens portion increases from the center toward the outer periphery of the effective pixel region.

14. The display device according to claim 2, wherein
a width of a formation region of the second lens portions decreases from an outer periphery toward a center of an effective pixel region, and a center of the second lens portions shifts in a direction from the outer periphery toward the center of the effective pixel region with reference to a center of a light-emitting region of the pixel.

15. The display device according to claim 1, wherein
the multilayer body is configured to be capable of spreading incident light from the plurality of light-emitting elements with respect to an optical axis.

16. The display device according to claim 2, wherein
a width of a portion located on an outer peripheral side of an effective pixel region in a formation region of the first lens portions decreases from a center toward an outer periphery of the effective pixel region.

17. The display device according to claim 2, wherein
the plurality of first lens portions includes a first lens portion in which a center of the first lens portion is shifted in a direction from a center toward an outer periphery of an effective pixel region with reference to a center of a light-emitting region of the pixel, and
a shift amount between the center of the light-emitting region of the pixel and the center of the first lens portion increases from the center toward the outer periphery of the effective pixel region.

18. The display device according to claim 2, wherein
the plurality of second lens portions include a second lens portion in which a center of the second lens portion is shifted in a direction from a center toward an outer periphery of an effective pixel region with reference to a center of a light-emitting region of the pixel, and
a shift amount between the center of the light-emitting region of the pixel and the center of the second lens portion increases from the center toward the outer periphery of the effective pixel region.

19. The display device according to claim 2, wherein
a width of a formation region of the second lens portions decreases from a center toward an outer periphery of an effective pixel region, and a center of the second lens portions shifts in a direction from the center toward the outer periphery of the effective pixel region with reference to a center of a light-emitting region of the pixel.

20. A display device comprising:
a plurality of light-emitting elements; and
a multilayer body covering the plurality of light-emitting elements, wherein
the multilayer body includes, in order, a first layer having a first refractive index n₁ and a second layer having a second refractive index n₂ different from the first refractive index n₁,
the second layer includes a plurality of first lens portions,
the plurality of first lens portions is provided on a first surface on a side of the first layer, and the first lens portions are located in one of a central portion and a peripheral portion of pixels.

21. A display device comprising:
a plurality of light-emitting elements; and
a multilayer body covering the plurality of light-emitting elements, wherein
the multilayer body includes, in order, a second layer having a second refractive index n₂ and a third layer having a third refractive index n₃ different from the second refractive index n₂,
the second layer includes a plurality of second lens portions,
the plurality of second lens portions is provided on a second surface on a side of the third layer, and the second lens portions are located in one of a central portion and a peripheral portion of pixels.

22. The display device according to claim 10, wherein
the second layer includes a plurality of metamaterials, and
the metamaterials are located in another of the central portion and the peripheral portion of the pixels.

23. The display device according to claim 10, wherein
the second layer includes a plurality of through holes,
the first lens portions are located in the peripheral portion of the pixels, and
the through holes are located in the central portion of the pixels.

24. An electronic apparatus comprising the display device according to claim 1.
